(19) United States
(12) Patent Application Publication
(10) Pub. No.: US 2026/0235956 A1
(43) Pub. Date: Aug. 13, 2026

(54) COATING AGENT COMPOSITION FOR NITROGEN-ATOM-CONTAINING SUBSTRATE

(71) Applicant: NISSAN CHEMICAL CORPORATION, Tokyo (JP)

(72) Inventors: Hikaru TOKUNAGA, Toyama-shi (JP); Ken ISHIBASHI, Toyama-shi (JP)

(73) Assignee: NISSAN CHEMICAL CORPORATION, Tokyo (JP)

(21) Appl. No.: 19/123,210

(22) PCT Filed: Nov. 13, 2023
(86) PCT No.: PCT/JP2023/040668

§ 371 Date: Apr. 22, 2025

(30) Foreign Application Priority Data
Nov. 15, 2022 (JP) 2022-182485
May 17, 2023 (JP) 2023-081555

(51) Int. Cl. G03F 7/11; C08G 8/04; C08G 10/00; C08G 10/02; C08G 12/26; C08G 14/02; C08G 61/12; C08G 73/06

(52) U.S. Cl. CPC G03F 7/11; C08G 8/04; C08G 10/00; C08G 10/02; C08G 12/26; C08G 14/02; C08G 61/124; C08G 73/0672

(57) ABSTRACT

A coating agent composition includes a novolac resin and a solvent, in which the novolac resin contains a unit structure A having, as at least a partial structure thereof, a carbazole backbone or a phenol/phenoxy backbone, the nitrogen-atom-containing substrate is a substrate formed from a compound having a bond between a metal atom or a semi-metal atom and a nitrogen atom or a substrate having a nitrogen-atom-containing film formed from a compound having a bond between a metal atom or a semi-metal atom and a nitrogen atom; a resist underlayer film to be formed on a nitrogen-atom-containing substrate, the resist underlayer film being a burned product of a coating film formed from the composition; and a method for producing a semiconductor device using the composition.

### TECHNICAL FIELD

The present invention relates to a coating composition suitable as a composition for forming a resist underlayer film suitable for lithography in semiconductor substrate processing, a resist underlayer film obtained from this composition, a method for forming a resist pattern using this composition, and a method for manufacturing a semiconductor device using this composition.

### BACKGROUND ART

The semiconductor manufacturing process has been drastically advancing, and improvements of quality and properties of a resist underlayer film have been strongly demanded with the advance. For example, it has been found that, when a substrate used as a base of the resist underlayer film contains a nitrogen atom, diffusion of an amine component inhibits resolution of the resist (Patent Literatures 1 to 3). Typically, the resist film formed is immediately subjected to an exposure step and then a development treatment, but for convenience of the manufacturing process, the development treatment may be performed, long time after formation of the resist film. It has been found that such a process causes the problem of changing the resolution of the resist from that in a case of exposure immediately after the coating. Furthermore, when the resist underlayer film is applied in the existing process in order to suppress the diffusion of the amine component, it has been required to form a resist underlayer film as thin as possible, taking a process in resist resolution or after resolution into consideration. The reasons for this are because formation of the resist underlayer film changes reflectance to result in a poor pattern shape or an increased load during pattern processing.

### CITATION LIST

### Patent Literature

Patent Literature 1: JP 2008-39811 A
Patent Literature 2: JP 2008-39815 A
Patent Literature 3: IP 2010-134437 A

### SUMMARY OF INVENTION

### Technical Problem

Accordingly, an object to be achieved by the present invention is to provide a coating composition suitable for a nitrogen-atom-containing substrate, wherein the coating composition is used for forming a thin resist underlayer film and can thus retain stable resolution so as not to affect the reflectance and pattern processing even when the resist film is stored for a long time after its formation. This composition can reduce the processing load.

### Solution to Problem

The present invention includes the following aspects.

[1]

A coating composition for a nitrogen-atom-containing substrate, comprising:
a novolac resin and a solvent,
the novolac resin has a unit structure A, the unit structure A has a carbazole skeleton or a phenol/phenoxy skeleton at least as a partial structure, and
the nitrogen-atom-containing substrate is: a substrate formed of a compound having a bond between a metal atom or a semimetal atom and a nitrogen atom; or a substrate having a nitrogen-atom-containing film formed of a compound having a bond between a metal atom or a semimetal atom and a nitrogen atom.
   [2]

The coating composition for a nitrogen-atom-containing substrate according to the [1], wherein the composition is for forming a resist underlayer film.

[3]

The coating composition for a nitrogen-atom-containing substrate according to the [2], wherein the resist underlayer film is a resist underlayer thin film having a film thickness of less than 10 nm.

[4]

The coating composition for a nitrogen-atom-containing substrate according to any one of the [1] to [3], wherein the nitrogen-atom-containing film is an outermost layer of the nitrogen-atom-containing substrate.

[5]

The coating composition for a nitrogen-atom-containing substrate according to any one of the [1] to [4], wherein the metal atom or the semimetal atom is:
(i) silicon;
(ii) titanium; or
(iii) tungsten, hafnium, zirconium, chromium, germanium, copper, silver, gold, aluminum, indium, gallium, arsenic, palladium, iron, tantalum, iridium, cobalt, manganese, molybdenum, or an alloy thereof.
   [6]

The coating composition for a nitrogen-atom-containing substrate according to any one of the [1] to [5], wherein the compound having the bond between the metal atom or the semimetal atom and the nitrogen atom is SiON, SiN, TiON, or TiN.

[7]

The coating composition for a nitrogen-atom-containing substrate according to any one of the [1] to [6], wherein the unit structure A having the carbazole skeleton or the phenol/phenoxy skeleton at least as a partial structure is a structural unit derived from one or more compounds selected from the following structural formulae (A-1) to (A-9):

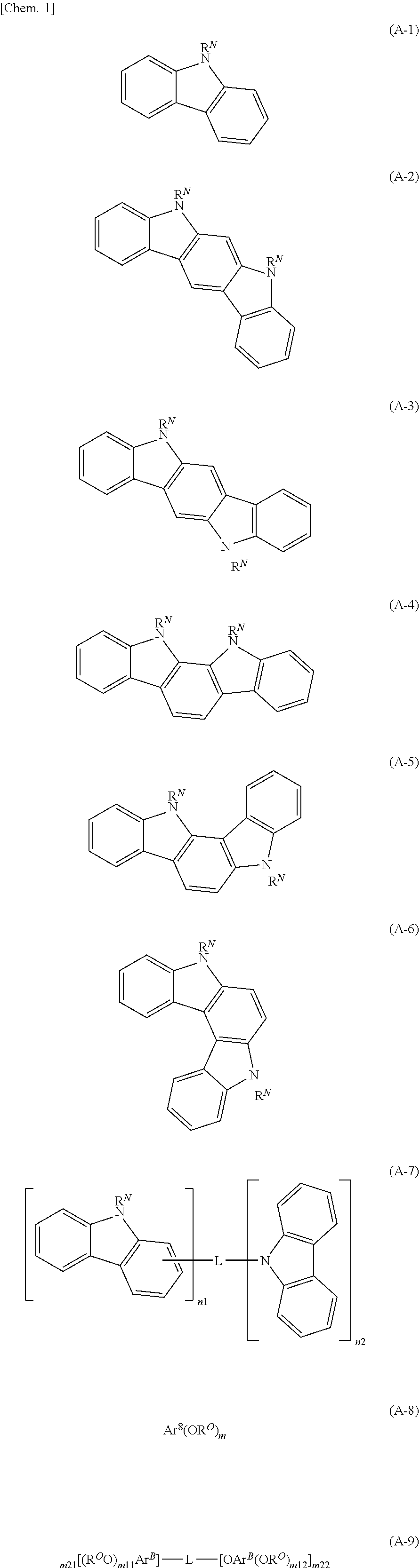

in the formulae (A-1) to (A-9),
R^{N} and R^{O} each independently represent:
(i) a hydrogen atom or a methylol group;
(ii) an aryl group having 6 to 30 carbon atoms; or
(iii) a linear, branched, or cyclic alkoxymethyl group having 2 to 20 carbon atoms; a linear, branched, or cyclic alkyl group having 1 to 20 carbon atoms; an alkenyl group having 2 to 10 carbon atoms; or an alkynyl group having 2 to 10 carbon atoms,
provided that R^{N} is bonded to a nitrogen atom on the carbazole skeleton, and R^{O} is bonded to an aryloxy oxygen atom in the Ar^{B} ring,
in the (ii) and (iii), a hydrogen atom in these groups is optionally further substituted with an oxygen-atom-containing substituent, a sulfur-atom-containing substituent, a nitrogen-atom-containing substituent, an aryl group, or a halo group, and in the (iii), a hydrocarbon chain moiety is optionally further interrupted by an oxygen-atom-containing substituent, a sulfur-atom-containing substituent, a nitrogen-atom-containing substituent, or an arylene group,
in the formula (A-8) to (A-9),
Ar^{B} each independently represents a benzene ring, a naphthalene ring, or a condensed ring having one or more benzene rings,
in the formula (A-8), “m” represents a number of R^{O}O groups and is 1 or more,
in the formulae (A-7) and (A-9),
L represents a single bond or a polyvalent linking group, wherein the polyvalent linking group is a divalent to octavalent linking group,
in the formula (A-7),
n1 represents a number of carbazole skeletons in which a carbon atom on an aromatic ring of the carbazole skeleton is bonded to L, n2 represents a number of carbazole skeletons in which a nitrogen atom on the carbazole skeleton is bonded to L, and n1 and n2 each are 0 or more; provided that a sum of n1 and n2 is an integer of 2 to 8, and the sum of n1 and n2 is 2 when L represents a single bond,
in the formula (A-9),
m21 represents a number of (R^{O}O)ₘ₁₁Ar^{B} groups in which a carbon atom on the Ar^{B} ring is bonded to L, and m11 each independently represents a number of R^{O}O groups,
m22 represents a number of OAr^{B}(OR^{O})ₘ₁₂ groups in which an aryloxy oxygen atom in the Ar^{B} ring is bonded to L, m12 each independently represents a number of R^{O}O groups, m11, m21, m12, and m22 each represent 0 or more; provided that a sum of the number “m21” of mils and m22 is 1 or more, a sum of m21 and m22 is 2 to 8, and the sum of m21 and m22 is 2 when L represents a single bond, and
each aromatic ring in these formulae (A-1) to (A-9) optionally further has a substituent.
   [8]

The coating composition for a nitrogen-atom-containing substrate according to the [7], wherein
the L is selected from the group consisting of a single bond, —O—, —S—, —SO₂—, —CO—, —CONH—, —COO—, —NH—, —(CR¹R²)ₘ₁—, —(Ar)ₘ₂—, —CH₂—(Ar)ₘ₂—CH₂—, and -(cyclo-R)—,
R¹ and R² are the same or different from each other and each independently represent a hydrogen atom, a hydrocarbon group having 1 to 5 carbon atoms, or an aryl group having 6 to 30 carbon atoms, and m1 represents an integer of 1 to 10,
Ar represents an arylene group having 6 to 30 carbon atoms, and m2 is an integer of 1 to 3 and represents a number of aromatic rings bonded to each other with a single bond, and
cyclo-R represents a five to eight-membered divalent alicyclic hydrocarbon group optionally forming a condensed ring with one or two benzene rings or naphthalene rings.
   [9]

The coating composition for a nitrogen-atom-containing substrate according to the [7] or [8], wherein the R^{N} or R^{O} has as at least part a substituent:

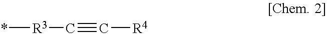

wherein “*” represents a bonding site,
R³ represents a single bond or a divalent organic group having 1 to 20 carbon atoms, and
R⁴ represents a hydrogen atom or a monovalent organic group having 1 to 20 carbon atoms.
   [10]

The coating composition for a nitrogen-atom-containing substrate according to any one of the [1] to [9], wherein the novolac resin has a composite unit structure A-B represented by the following formula (AB):

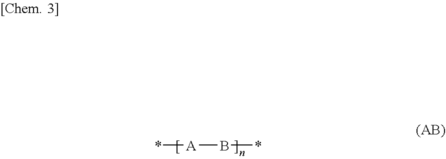

in the formula (AB),
“n” represents a number of the composite unit structure A-B,
a unit structure A is as defined for the unit structure A in [1],
a unit structure B represents one or more unit structures having a structure represented by the following formula (B1), (B2), or (B3), and
“*” represents a bonding site,

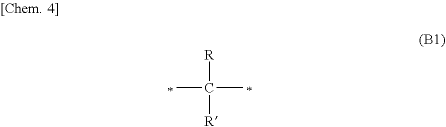

in the formula (B1),
R and R′ each independently represent a hydrogen atom, an aromatic ring residue having 6 to 30 carbon atoms and optionally having a substituent; a heteroring residue having 3 to 30 carbon atoms and optionally having a substituent; a linear, branched, or cyclic alkyl group having 10 or less carbon atoms and optionally having a substituent; or a formyl group, and
“*” represents a bonding site,

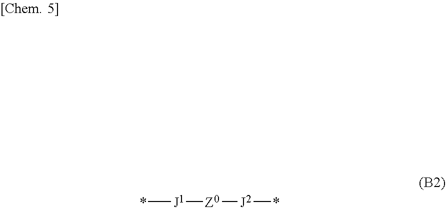

in the formula (B2),
Z⁰ represents an aromatic ring residue or an aliphatic ring residue having 6 to 30 carbon atoms and optionally having a substituent; or an organic group in which two aromatic ring residues or aliphatic ring residues are linked via a single bond,
J¹ and J² each independently represent a direct bond or a divalent organic group optionally having a substituent, and
“*” represents a bonding site,

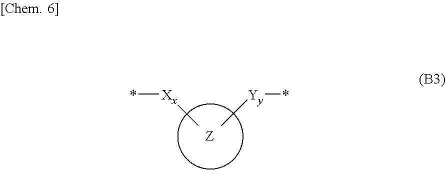

in the formula (B3),
Z represents a single ring or a bicyclic, tricyclic, or tetracyclic condensed ring having 4 to 25 carbon atoms and optionally having a substituent, the single ring being a non-aromatic single ring; at least one single ring constituting the bicyclic, tricyclic, or tetracyclic rings is a non-aromatic single ring while the other single ring or rings may be an aromatic single ring or a non-aromatic single ring; the single ring or the bicyclic, tricyclic, or tetracyclic condensed ring may further form a condensed ring with one or more aromatic rings to form a penta- or higher-cyclic condensed ring,
X and Y are the same or different from each other and represent a —CR³¹R³²— group, R³¹ and R³² are the same or different from each other and represent a hydrogen atom or a hydrocarbon group having 1 to 6 carbon atoms, and
“x” and “y” respectively represent numbers of X and Y, and each independently represent 0 or 1,

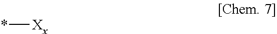

is bonded to any one carbon atom of the non-aromatic single ring of Z (when x=1), which is referred to as a “carbon atom 1”, or extends from the carbon atom 1 (when x=0),

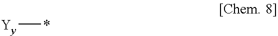

is bonded to any one carbon atom of the non-aromatic single ring of Z (when y=1), which is referred to as a “carbon atom 2”, or extends from the carbon atom 2 (when y=0),
the carbon atom 1 and the carbon atom 2 may be identical or different from each other, and when the carbon atom 1 and the carbon atom 2 are different, the carbon atom 1 and the carbon atom 2 may be contained in an identical non-aromatic single ring or may be contained in different non-aromatic single rings, and
“*” represents a bonding site.
   [11]

The coating composition for a nitrogen-atom-containing substrate according to any one of the [1] to [10], wherein the solvent contains a solvent having a boiling point of 160° C. or higher.

[12]

The coating composition for a nitrogen-atom-containing substrate according to any one of the [1] to [11], further comprising an acid and/or a salt thereof, and/or an acid generator.

[13]

The coating composition for a nitrogen-atom-containing substrate according to any one of the [1] to [12], further comprising a crosslinker.

[14]

The coating composition for a nitrogen-atom-containing substrate according to the [13], wherein the crosslinker is an aminoplast crosslinker or a phenoplast crosslinker.

[15]

The coating composition for a nitrogen-atom-containing substrate according to any one of the [1] to [14], further comprising a surfactant.

[16]

A resist underlayer film on a nitrogen-atom-containing substrate, wherein the resist underlayer film is a baked product of a coating film comprising the coating composition for a nitrogen-atom-containing substrate according to any one of the [1] to [15].

[17]

The resist underlayer film on the nitrogen-atom-containing substrate according to the [16], having a film thickness of less than 10 nm.

[18]

A method for forming a resist pattern used for manufacturing a semiconductor, the method comprising: a step of applying the coating composition for a nitrogen-atom-containing substrate according to any one of the [1] to [15] to a nitrogen-atom-containing semiconductor substrate; and a step of then baking the composition to form a resist underlayer film.

[19]

A method for manufacturing a semiconductor device, the method comprising:
a step of forming a resist underlayer film from the coating composition for a nitrogen-atom-containing substrate according to any one of the [1] to [15] on a nitrogen-atom-containing semiconductor substrate;
a step of forming a resist film on the resist underlayer film; and
a step of forming a resist pattern in the resist film by irradiation with light or electron beam and development.
   [20]

The method for manufacturing a semiconductor device according to the [19], further comprising a step of etching the resist underlayer film through the resist pattern.

[21]

The method for manufacturing a semiconductor device according to the [20], further comprising a step of processing a semiconductor substrate with the patterned resist underlayer film.

[22]

The method for manufacturing a semiconductor device according to any one of the [19] to [21], wherein the step of forming a resist pattern in the resist film is performed by a nanoimprinting method or a directed self-assembly method.

[23]

A composition for forming a resist underlayer thin film, the composition comprising:
a novolac resin and a solvent,
the novolac resin has a repeating unit structure A, the unit structure A has a carbazole skeleton or a phenol/phenoxy skeleton at least as a partial structure, and
a film thickness of the resist underlayer thin film is less than 10 nm.

### Advantageous Effects of Invention

When a novolac resin having a carbazole structure in a skeleton or a novolac resin having a phenol structure or a phenoxy structure in a skeleton is applied to a substrate containing a nitrogen atom, diffusion of an amine component contained in the substrate can be suppressed even when the resulting film is an ultrathin film of less than 10 nm. When a resist film is provided on a resist underlayer film containing such a resin, resolution of the resist film is not impaired and thus a resist pattern having a favorable perpendicular shape can be formed.

In addition, obtaining the perpendicular resist pattern means that diffusion of the amine component from a base film, namely the substrate, is successfully suppressed, and thus, it can be said that excellent resolution is exhibited even when exposure is performed a long time after the resist film formation.

Furthermore, good coatability and sufficient curability are exhibited on various types of the substrate and stepped substrates even when the film formed by coating is an ultrathin film, whereby variation of the film thickness in a single wafer can be reduced.

### DESCRIPTION OF EMBODIMENTS

### [I. Definitions of Terms]

Definitions of major terms herein about the novolac resin in one aspect of the present invention will be described below. Unless otherwise specifically noticed, the following definitions of terms are applied to the novolac resin.

### (I-1) “Novolac Resin”

The “novolac resin” is used not only in a narrow sense to mean a phenol-formaldehyde resin (namely, a novolac-type phenol resin) and an aniline-formaldehyde resin (namely, a novolac-type aniline resin), but also in a broad sense to widely encompass a polymerized polymer typically formed through formation of a covalent bond (such as a substitution reaction, an addition reaction, a condensation reaction, or an addition-condensation reaction) between: an organic compound having a functional group that enables a covalent bond to an aromatic ring [for example, an aldehyde group, a ketone group, an acetal group, a ketal group, a hydroxy group or an alkoxy group bonded to a secondary or a tertiary carbon; a hydroxy group, an alkoxy group, or a halo group bonded to a carbon atom at an α-position of an alkylaryl group (such as a carbon atom at a benzyl position); a carbon-carbon unsaturated bond of divinylbenzene, dicyclopentadiene, or the like]; and an aromatic ring in a compound having an aromatic ring (preferably having a substituent including a heteroatom such as an oxygen atom, a nitrogen atom, and a sulfur atom on the aromatic ring), in the presence of an acid catalyst or under a reaction condition equivalent thereto.

Therefore, the novolac resin referred to herein is a polymer formed in the following manner: the organic compound having a carbon atom derived from the above-described functional group (which may be referred to as “linkage carbon atom”) forms a covalent bond, via the linkage carbon atom, to an aromatic ring in the compound having an aromatic ring so that a plurality of the compounds having an aromatic ring are linked.

Terms “unit structure A”, “unit structure B”, and “unit structure C” are used herein for unit structures to constitute the “novolac resin”. The unit structure A is a unit structure derived from the compound having an aromatic ring. The unit structure B is a unit structure derived from the compound having the functional group that can form a covalent bond to the aromatic ring in the unit structure A. The unit structure C is a single unit structure having a bonding pattern equivalent to that of a composite unit structure A-B, and is a unit structure derived from a compound having an aromatic ring and also having the functional group that can form a covalent bond to the aromatic ring in the unit structure A. Since the bonding pattern is the same, the unit structure C may be replaced for the composite unit structure A-B.

### (I-2) “Residue”

The “residue” refers to an organic group in which a hydrogen atom bonded to a carbon atom or a heteroatom (such as a nitrogen atom, an oxygen atom, or a sulfur atom) is replaced for a bonding site. The organic group may be a monovalent group or a polyvalent group. For example, replacement of one hydrogen atom for one bonding site forms a monovalent organic group, and replacement of two hydrogen atoms for bonding sites forms a divalent organic group.

### (I-3) “Aromatic Ring” (Aromatic Group, Aryl Group, and Arylene Group)

The “aromatic ring” is a concept encompassing an aromatic hydrocarbon ring, an aromatic heteroring, and a residue thereof [which may be referred to as “aromatic group”, “aryl group” (in a case of a monovalent group), or “arylene group” (in a case of a divalent group)], and encompasses not only a monocyclic ring (an aromatic single ring) but also a polycyclic ring (aromatic multiple rings). In the case of the polycyclic ring, at least one single ring is the aromatic single ring, but the other single ring(s) forming a condensed ring with the aromatic single ring may be a monocyclic heterocyclic ring (a hetero single ring) or may be a monocyclic alicyclic hydrocarbon (an alicyclic single ring).

Examples of the aromatic ring include, but not limited to, an aromatic hydrocarbon ring such as benzene, indene, naphthalene, azulene, styrene, toluene, xylene, mesitylene, cumene, anthracene, phenanthrene, triphenylene, benzoanthracene, pyrene, chrysene, fluorene, biphenyl, corannulene, perylene, fluoranthene, benzo[k]fluoranthene, benzo[b]fluoranthene, benzo[ghi]perylene, coronene, dibenzo[g,p]chrysene, acenaphthylene, acenaphthene, naphthacene, pentacene, and cyclooctatetraene, more typically, an aromatic hydrocarbon ring such as benzene, naphthalene, anthracene, and pyrene; and an aromatic heteroring such as furan, pyran, thiophene, pyrrole, an N-alkylpyrrole, an N-arylpyrrole, imidazole, pyridine, pyrimidine, pyrazine, triazine, thiazole, indole, phenylindole, bisindolefluorene, bisindolebenzofluorene, bisindoledibenzofluorene, purine, quinoline, isoquinoline, chromene, thianthrene, phenothiazine, phenoxazine, xanthene, acridine, phenazine, carbazole, and indolocarbazole, more typically, furan, thiophene, pyrrole, indole, phenylindole, bisindolefluorene, phenothiazine, carbazole, indolocarbazole, imidazole, pyran, pyridine, pyrimidine, and pyrazine.

The aromatic ring (for example, a benzene ring and a naphthalene ring) optionally has a substituent. Examples of the substituent include: a halogen atom, a saturated or unsaturated linear, branched, or cyclic hydrocarbon group (—R) (which may be interrupted once or more by an oxygen atom at a middle of the hydrocarbon chain, and which encompasses an alkyl group, an alkenyl group, an alkynyl group, a propargyl group, and the like), an alkoxy group or an aryloxy group (—OR, wherein R represents the hydrocarbon group —R), an alkylamino group [—NHR, or —NR₂ in which two R may be the same or different from each other; wherein R represents the hydrocarbon group —R and encompasses an alkyl group, an alkenyl group, an alkynyl group, a propargyl group and the like optionally interrupted once or more by an oxygen atom at a middle of the hydrocarbon chain], a hydroxy group, an amino group (—NH₂), a carboxyl group, a cyano group, a nitro group, an ester group (—CO₂R or —OCOR, wherein R represents the hydrocarbon group —R), an amide group (—NHCOR, —CONHR, or —NRCOR in which two R may be the same or different from each other, or —CONR₂ in which two R may be the same or different from each other; wherein R represents the hydrocarbon group —R), a sulfonyl-containing group (—SO₂R, wherein R represents the hydrocarbon group —R or a hydroxy group —OH), a thiol group (—SH), a sulfide-containing group (—SR, wherein R represents the hydrocarbon group —R); an organic group having an ether bond [a residue of an ether compound represented by R¹¹—O—R¹¹, wherein R₁₁ each independently represents an alkyl group having 1 to 6 carbon atoms such as a methyl group and an ethyl group, and an aryl group such as a phenyl group, a naphthyl group, an anthranyl group, and a pyrenyl group; for example, an organic group having an ether bond, including a methoxy group, an ethoxy group, or a phenoxy group], and an aryl group.

The aromatic group further includes an organic group having a condensed ring between: one or more aromatic rings (such as benzene, naphthalene, anthracene, and pyrene); and one or more aliphatic rings or heterorings. Examples of the aliphatic ring herein include cyclobutane, cyclobutene, cyclopentane, cyclopentene, cyclohexane, cyclohexene, methylcyclohexane, methylcyclohexene, cycloheptane, and cycloheptene. Examples of the heteroring include furan, thiophene, pyrrole, imidazole, pyran, pyridine, pyrimidine, pyrazine, pyrrolidine, piperidine, piperazine, and morpholine.

The aromatic ring may be an organic group having a structure in which two or more aromatic rings are linked via a divalent linking group such as an alkylene group.

### (I-4) “Heteroring”

The “heteroring” is an concept encompassing both of an aliphatic heteroring and an aromatic heteroring, and encompassing not only a monocyclic ring (a hetero single ring) but also a polycyclic ring (hetero multiple rings). In the case of the polycyclic ring, at least one single ring is a hetero single ring, but the other single ring(s) may be an aromatic hydrocarbon single ring or an alicyclic single ring. As for the aromatic heteroring, the examples in the (I-3) may be referred to. The heteroring may have a substituent, as with the aromatic ring in the (I-3).

### (I-5) “Non-Aromatic Ring” (Aliphatic Ring)

The “non-aromatic single ring” refers to a monocyclic hydrocarbon not belonging to aromatics, and is typically a single ring of an alicyclic compound. The non-aromatic single ring may also be referred to as an aliphatic single ring (which may encompass an aliphatic hetero single ring, and may have an unsaturated bond unless the aliphatic single ring belongs to the aromatic compound). The non-aromatic single ring may have a substituent, as with the aromatic ring in the (I-3).

Examples of the non-aromatic single ring (the aliphatic ring or the aliphatic single ring) include cyclopropane, cyclobutane, cyclobutene, cyclopentane, cyclopentene, cyclohexane, methylcyclohexane, cyclohexene, methylcyclohexene, cycloheptane, and cycloheptene.

The “non-aromatic multiple ring” refers to a polycyclic hydrocarbon not belonging to aromatics, and is typically a multiple ring of an alicyclic compound. The non-aromatic multiple ring may be referred to as an aliphatic multiple ring [which may encompass an aliphatic hetero multiple ring, in which at least one single ring constituting the multiple rings is the aliphatic heteroring, and which may have an unsaturated bond unless the aliphatic multiple ring belongs to aromatics]. The non-aromatic multiple ring encompasses a non-aromatic double ring, a non-aromatic triple ring, and a non-aromatic quadruple ring.

The “non-aromatic double ring” refers to a condensed ring composed of two monocyclic hydrocarbons not belonging to aromatics, and is typically a condensed ring of two alicyclic compounds. The non-aromatic double ring herein may be referred to as an aliphatic double ring (which may encompass an aliphatic hetero double ring and may have an unsaturated bond unless the aliphatic double ring belongs to the aromatic compound). Examples of the non-aromatic double ring include bicyclopentane, bicyclooctane, and bicycloheptene.

The “non-aromatic triple ring” refers to a condensed ring composed of three monocyclic hydrocarbons not belonging to aromatics, and is typically a condensed ring of three alicyclic compounds (each of which may be a heteroring and may have an unsaturated bond unless the aliphatic triple ring belongs to the aromatic compound). Examples of the non-aromatic triple ring include tricyclooctane, tricyclononane, and tricyclodecane.

The “non-aromatic quadruple ring” refers to a condensed ring composed of four monocyclic hydrocarbons not belonging to aromatics, and is typically a condensed ring of four alicyclic compounds (each of which may be a heteroring, and may have an unsaturated bond unless the aliphatic quadruple ring belongs to the aromatic compound). Examples of the non-aromatic quadruple ring include hexadecahydropyrene.

(1-6)

The “carbon atom constituting a ring (portion)” means a carbon atom constituting a hydrocarbon ring (any one of an aromatic ring, an aliphatic ring, and a heteroring) with no substituent.

### (I-7)

The “hydrocarbon group” refers to a group formed by removing one or more hydrogen atoms from a hydrocarbon. The hydrocarbon includes a saturated or unsaturated aliphatic hydrocarbon, a saturated or unsaturated alicyclic hydrocarbon, and an aromatic hydrocarbon.

(1-8)

In chemical structural formulae that represent unit structures of the novolac resin herein, a bonding site (represented by “*”) may be shown for convenience. This bonding site may be on any possible bonding position in the unit structure unless otherwise noticed, and the bonding position in the unit structure is not limited at all.

### [II. Coating Composition for Nitrogen-Atom-Containing Substrate]

The coating composition for a nitrogen-atom-containing substrate of one aspect of the present invention is a coating composition for a nitrogen-atom-containing substrate including: a novolac resin and a solvent; wherein the novolac resin has a unit structure A or a repeating unit structure A, wherein the unit structure A or the repeating unit structure A has a carbazole skeleton or a phenol/phenoxy skeleton at least as a partial structure.

The coating composition for a nitrogen-atom-containing substrate is a coating agent used for forming a coating film on a nitrogen-atom-containing substrate. Preferably, when the coating composition is used for forming a resist underlayer film, resolution of a resist film cannot be impaired to advantageously provide a resist pattern having a favorable perpendicular shape even when exposure is performed a long time after the resist film formation. It is generally considered that a use of a material with a large thickness as the resist underlayer film can suppress diffusion of an amine component from the nitrogen-atom-containing substrate; however, such a use of a material with a large thickness leads to an increased load in a subsequent processing, increase in a material cost, and also a poor resist shape due to deterioration in anti-reflective performance. Therefore, it is significantly important to achieve suppression of the diffusion of the amine component while preventing the above adverse effects. The coating composition for a nitrogen-atom-containing substrate of the present invention can sufficiently provide the above-described advantage even when the coating composition is used for forming a resist underlayer film to give an ultrathin film having a film thickness of less than 10 nm.

Without wishing to be bound by any theory, it is considered that the mechanism for suppressing, by the novolac resin having the carbazole skeleton or the phenol/phenoxy skeleton, the diffusion of the amine component is different from that for inhibition of the diffusion by neutralizing the amine component with an acidic additive, as described in Patent Literatures. It is considered that the novolac resin has, in the skeleton, many aromatic rings with a high carbon content and has high rigidity, and that intermolecular gaps through which the amine component, a contaminant from the substrate, can be diffused is thus remarkably reduced to inhibit the diffusion of the amine component.

### (II-1) Nitrogen-Atom-Containing Substrate

The nitrogen-atom-containing substrate is: a substrate formed of a compound having a bond between a metal atom or a semimetal atom and a nitrogen atom; or a substrate having a nitrogen-atom-containing film formed of a compound having a bond between a metal atom or a semimetal atom and a nitrogen atom.

Examples of the metal atom or the semimetal atom include:
(i) silicon;
(ii) titanium; or
(iii) tungsten, hafnium, zirconium, chromium, germanium, copper, silver, gold, aluminum, indium, gallium, arsenic, palladium, iron, tantalum, iridium, cobalt, manganese, molybdenum, or an alloy thereof.

Typical examples of the compound having a bond between a metal atom or a semimetal atom and a nitrogen atom include SiON, SiN, TiON, and TiN.

The effect of the coating composition of one aspect of the present invention is most effectively exhibited in the following cases: the coating composition is directly applied to the substrate formed of a compound having a bond between a metal atom or a semimetal atom and a nitrogen atom; or the coating composition is applied to a substrate having a nitrogen-atom-containing film formed of the compound having a bond between a metal atom or a semimetal atom and a nitrogen atom, wherein the nitrogen-atom-containing film is the outermost layer of the substrate.

### (II-2) Unit Structure a Having Carbazole Skeleton or Phenol/Phenoxy Skeleton

### (II-2-1)

The repeating unit structure A in the novolac resin, which is a repeating unit structure having the carbazole skeleton or the phenol/phenoxy skeleton at least as a partial structure, includes any unit structure having the carbazole skeleton, or the phenol skeleton or phenoxy skeleton in a part of the structure. Preferable examples of the respective unit structures include the following structural formulae (A-1) to (A-7) and (A-8) to (A-9). Here, the carbazole skeleton means a skeleton formed of twelve carbon atoms and one nitrogen atom that constitute an unsubstituted carbazole ring. The phenol/phenoxy skeleton means a skeleton formed of six carbon atoms that constitute an unsubstituted phenol ring or an unsubstituted phenoxy group, which is a residue formed by removing a hydrogen atom in a phenolic hydroxy group from the phenol ring.

The phrase “having at least as a partial structure” means that it is sufficient to have a skeleton recognized as the carbazole skeleton or the phenol/phenoxy skeleton in a part of a carbon skeleton, including not only a case where the carbon skeleton is provided by a single carbazole skeleton or a single phenol/phenoxy skeleton, but also a case where the carbon skeleton is provided by a condensed ring formed of a carbazole skeleton or a phenol/phenoxy skeleton with another carbon ring or a case where the carbon skeleton is provided by a plurality of the carbazole skeletons or the phenol/phenoxy skeletons bonded via linking groups.

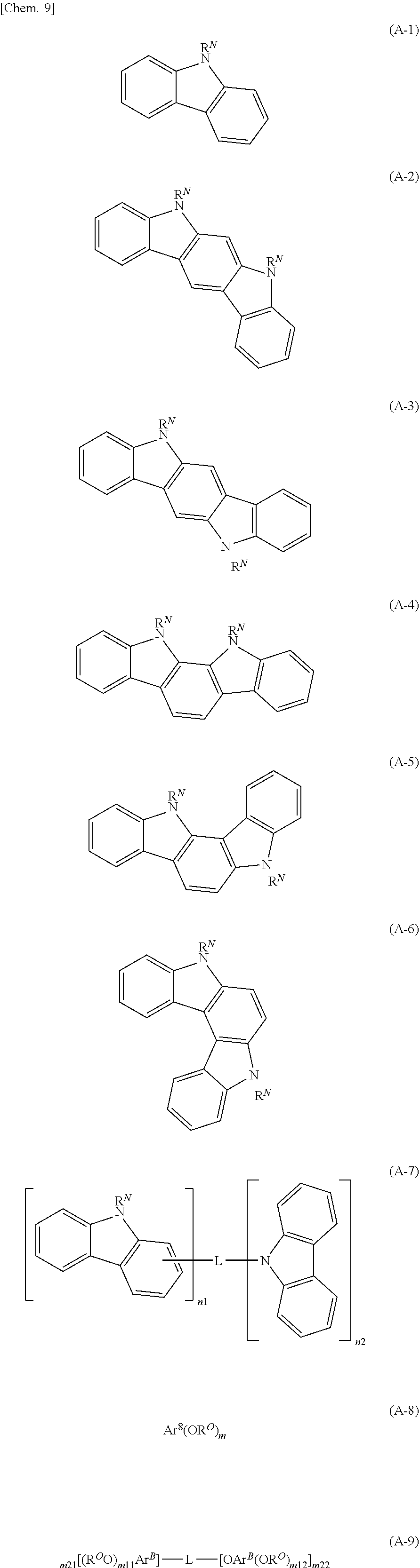

### (II-2-2)

Here, R^{N} in the formulae (A-1) to (A-7) and R^{O} in the formulae (A-8) to (A-9) each independently represent:
(i) a hydrogen atom or a methylol group;
(ii) an aryl group having 6 to 30 carbon atoms; or
(iii) a linear, branched, or cyclic alkoxymethyl group having 2 to 20 carbon atoms; a linear, branched, or cyclic alkyl group having 1 to 20 carbon atoms; an alkenyl group having 2 to 10 carbon atoms; or an alkynyl group having 2 to 10 carbon atoms.

Provided that R^{N} is bonded to a nitrogen atom on the carbazole skeleton, and R^{O} is bonded to an aryloxy oxygen atom in the Ar^{B} ring.

In the (ii) and (iii), a hydrogen atom in the substituent may be further substituted with an oxygen-atom-containing substituent, such as a hydroxy group, an alkoxy group, an aryloxy group, a carboxyl group, and a carbonyl group; a sulfur-atom-containing substituent, such as a sulfonic acid group, a sulfide-containing group, and a sulfonyl-containing group; a nitrogen-atom-containing substituent, such as an amino group, a substituted amino group (such as monosubstituted or disubstituted amino group such as a monoalkylamine and a dialkylamine), an amide group, a nitro group, and a cyano group; an aryl group, preferably an aryl group having 6 to 20 carbon atoms such as a phenyl group; or a halo group. In the (iii), the hydrocarbon chain moiety may be further interrupted by an oxygen-atom-containing substituent, such as —O—, —C(O)—, —C(O)O—, and —OC(O)—; a sulfur-atom-containing substituent, such as —S—; a nitrogen-atom-containing substituent, such as —N(R)C(O)—, —C(O)N(R)—, —OC(O)N(R)—, —N(R)C(O)O—, —N(R)C(O)N(R)—, and —NR—; or an arylene group, such as a phenylene group. In the substituent used for the interruption, R is the same or different from each other, and each independently represents a hydrogen atom or a hydrocarbon group having 1 to 30 carbon atoms.

At least part of R^{N} and R^{O} is preferably an alkynyl group in view of self-crosslinking properties. Examples of the alkynyl group include the following alkynyl substituent.

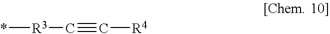

Here, “*” represents a bonding site, R³ represents a single bond or a divalent organic group having 1 to 20 carbon atoms, preferably an alkylene group, and more preferably a methylene group; R⁴ represents a hydrogen atom or a monovalent organic group having 1 to 20 carbon atoms, preferably a hydrogen atom or an alkyl group, and more preferably a hydrogen atom. Here, the organic group means a residue of an organic compound. As for the at least part of R^{N}, 5 to 100% of the number of R^{N} is preferably an alkynyl group. This percentage can be calculated as an introducing rate by, for example, ¹H-NMR measurement or ¹³C-NMR. The percentage may also be calculated by using an internal standard or the like as necessary.

Specific examples of R^{N} and R^{O} include the following substituents. Here, “*” in R^{N} means a bond to a nitrogen atom on the carbazole skeleton, and “*” in R^{O} means a bond to an oxygen atom of the phenolic hydroxy group in the phenol skeleton, which is an aryloxy oxygen atom in the Ar^{B} ring, resulting in formation of the phenoxy skeleton.

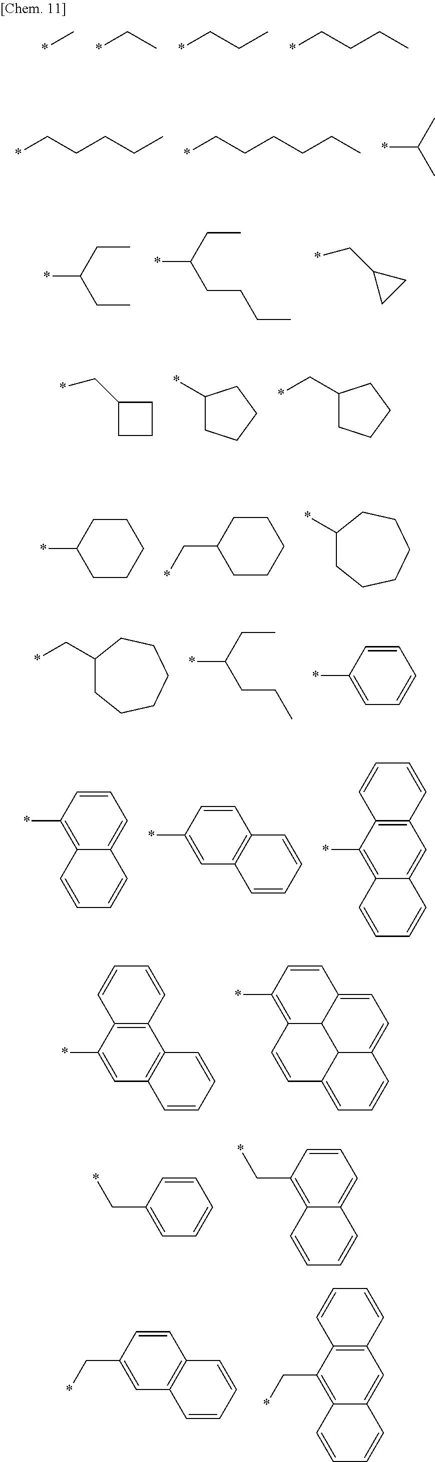

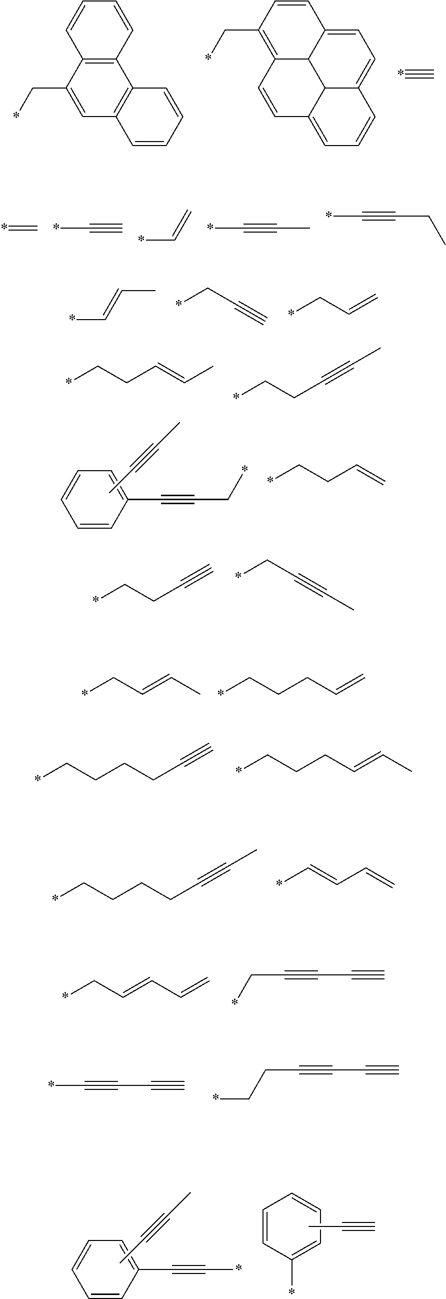

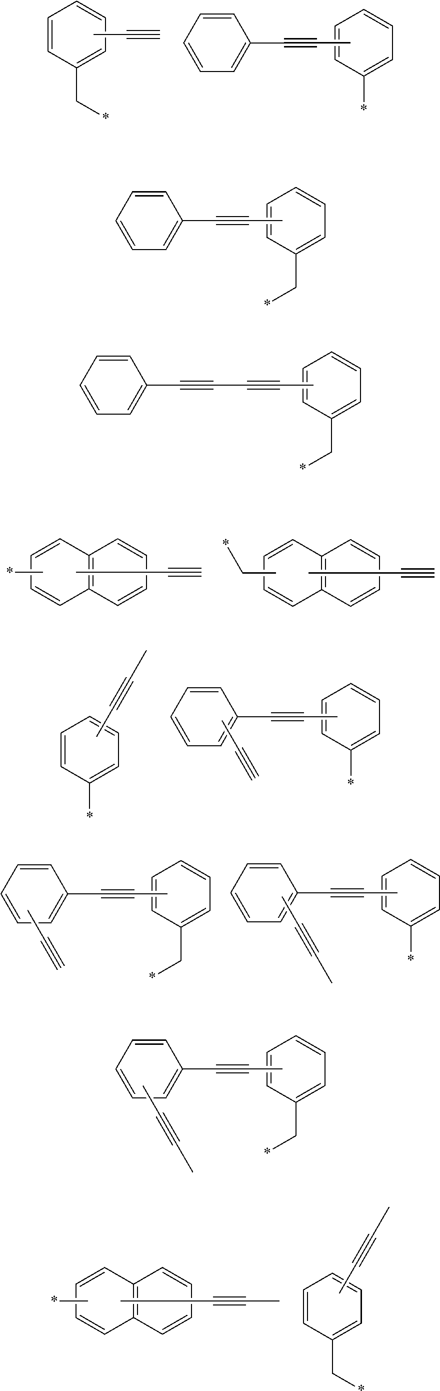

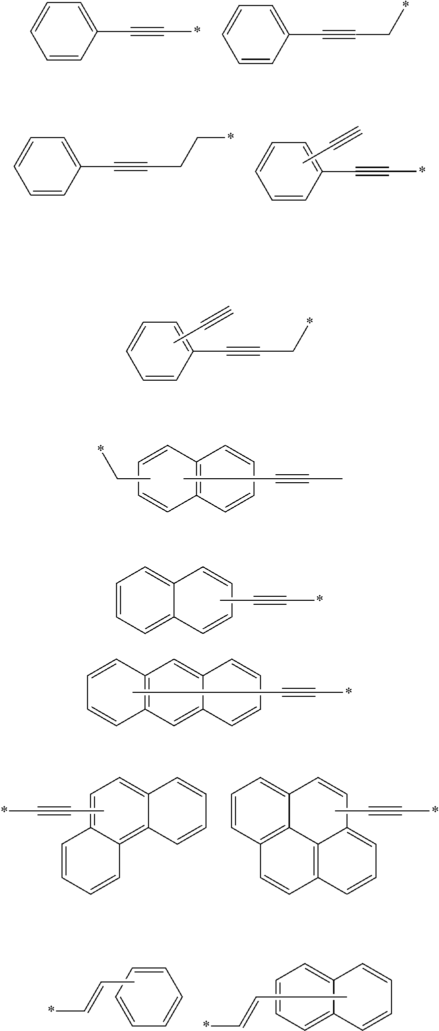

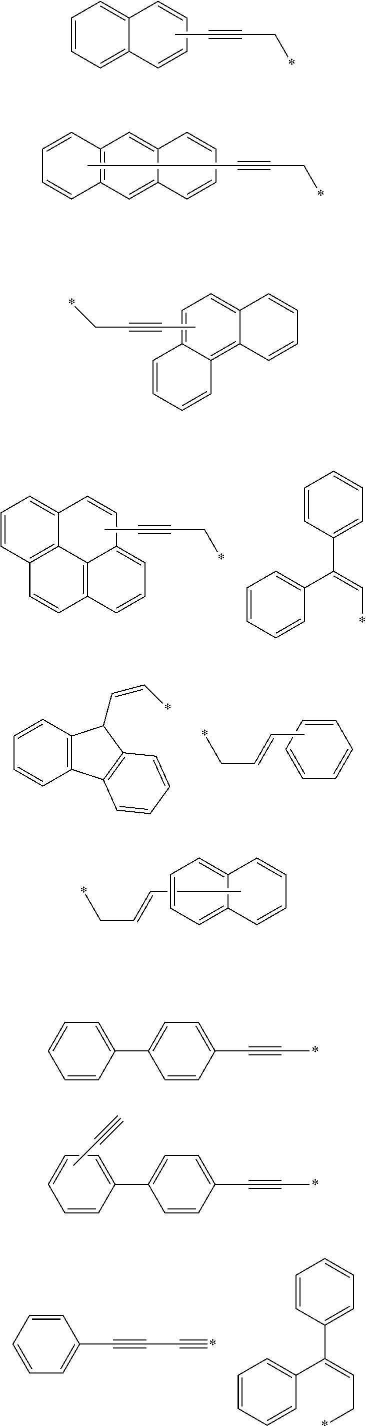

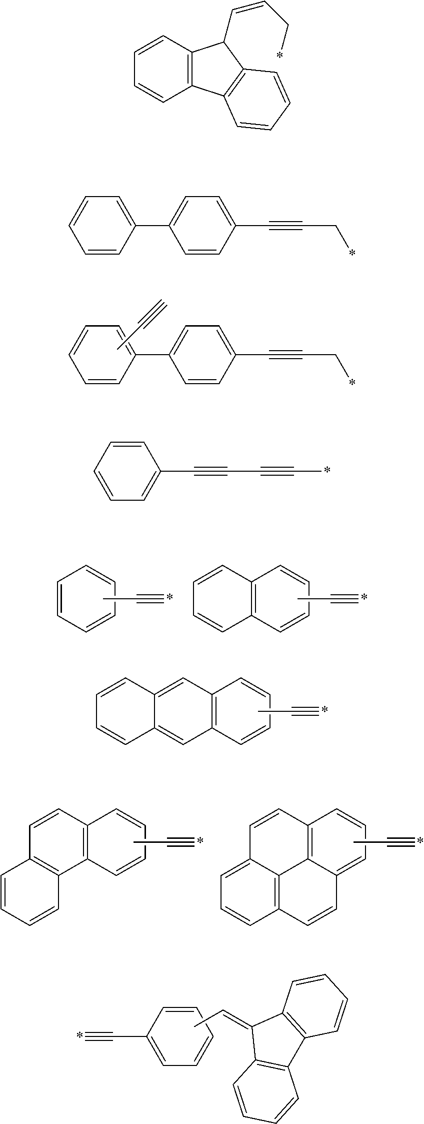

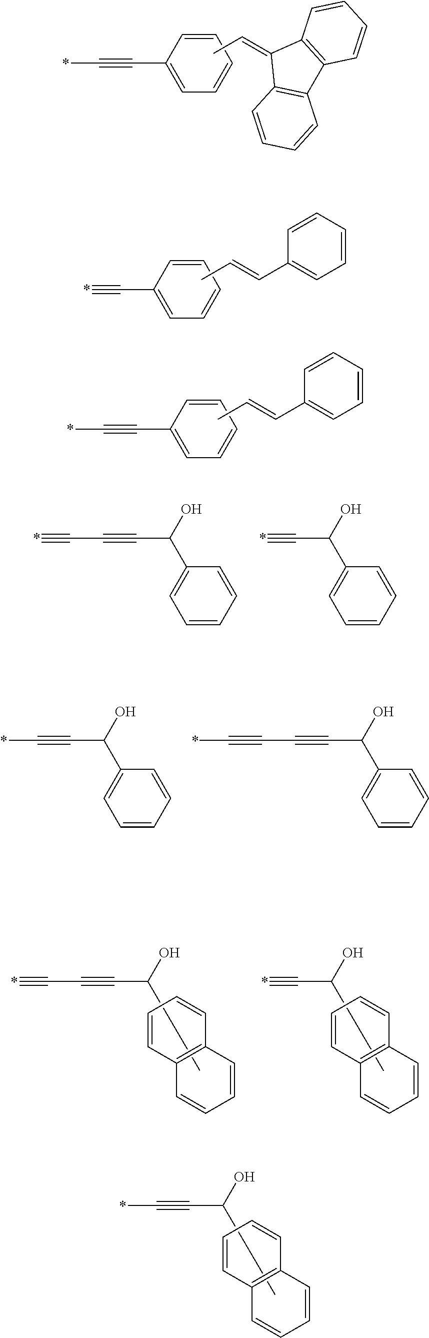

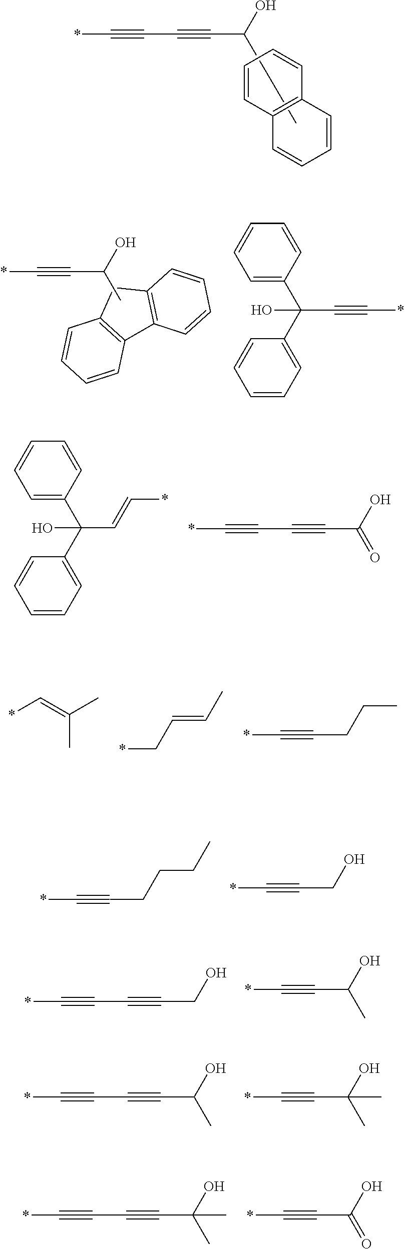

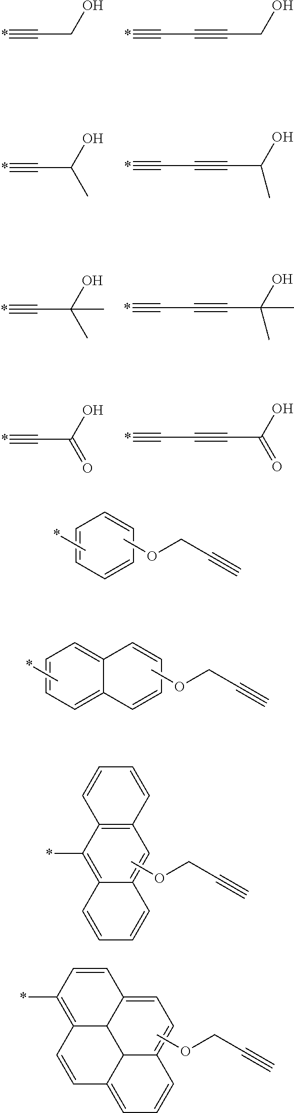

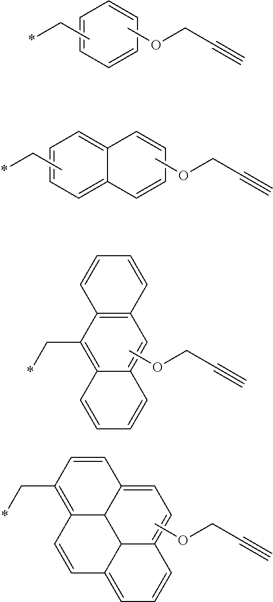

### (II-2-3)

In the formulae (A-8) to (A-9), Ar^{B} each independently represents a benzene ring, a naphthalene ring, or a condensed ring having one or more benzene rings.

When Ar® represents the condensed ring, the condensed ring preferably includes one to eight benzene rings. Examples of the condensed ring include a naphthalene ring, an anthracene ring, and a pyrene ring. Furthermore, Ar^{B} optionally forms a condensed ring with an aliphatic ring other than the benzene ring, and the aliphatic ring may be a saturated aliphatic ring and also have an unsaturated bond unless the ring belongs to aromatic rings, and encompasses an aliphatic heteroring. The aliphatic ring may be sandwiched by a plurality of benzene rings to form a condensed ring. Examples thereof include a 5,6,7,8-tetrahydro-1-naphthol ring, a 9,10-dihydroanthracen-1-ol ring, and a 9,10-dihydroanthracen-2-ol ring.

### (II-2-4)

In the formula (A-7), n1 represents the number of carbazole skeletons bonded to L at a carbon atom on the aromatic ring of the carbazole skeleton; and n2 represents the number of carbazole skeletons bonded to L at a nitrogen atom on the carbazole skeleton. n1 and n2 each represent an integer of 0 or more; provided that “n”, a sum of n1 and n2, represents an integer of 2 to 8, and the sum of n1 and n2 is 2 when L represents the single bond.

In the formula (A-8), “m” represents the number of OR^{O} groups, and is 1 or more. “m” is preferably 1 to 3.

In the formula (A-9), m11 and m12 each independently represent the number of R^{O}O groups on the aromatic ring of Ar^{B}. m11 and m12 are preferably each independently 1 to 3. m21 represents the number of (R^{O}O)ₘ₁₁Ar^{B} groups, in which a carbon atom on the Ar^{B} ring is bonded to L, and m22 represents the number of OAr^{B}(OR^{O})ₘ₁₂ groups, in which an aryloxy oxygen atom in the Ar^{B} ring is bonded to L. Here, the aryloxy oxygen atom means an ether oxygen atom as a substituent on any one benzene ring constituting the Ar^{B} ring. In the formula (A-9), m11, m21, m12, and m22 each independently represent 0 or more; provided that the sum of the number “m21” of m11s and m22 is 1 or more, the sum of m21 and m22 is 2 to 8, and the sum of m21 and m22 is 2 when L represents a single bond.

### (II-2-5)

L in the formula (A-7) and the formula (A-9) represents a single bond or a polyvalent linking group which is “n” valent, wherein “n” represents an integer of 2 to 8.

L in the formula (A-7) links carbon atoms on the aromatic rings of the number “n1” of carbazole skeletons and nitrogen atoms on the number “n2” of carbazole skeletons.

L in the formula (A-9) links carbon atoms on the aromatic rings of the number “m21” of (R^{O}O)ₘ₁₁Ar^{B} groups and aryloxy oxygen atoms on the number “m22” of OAr^{B}(ORO)ₘ₁₂ groups.

The linking group L is preferably selected from the group consisting of a single bond, —O—, —S—, —SO₂—, —CO—, —CONH—, —COO—, —NH—, —(CR¹R²)ₘ₁—, —(Ar)ₘ₂—, —CH₂—(Ar)ₘ₂—CH₂—, and -(cyclo-R)—.

Here, R¹ and R² are the same or different from each other, and each independently represent: a hydrogen atom, a hydrocarbon group having 1 to 5 carbon atoms; or an aryl group having 6 to 30 carbon atoms; and m1 represents an integer of 1 to 10. Ar represents an arylene group having 6 to 30 carbon atoms; and m2 represents the number of aromatic rings bonded to each other via a single bond, and is an integer of 1 to 3. Examples of the Ar include a divalent benzene ring, a divalent naphthalene ring, a divalent anthracene ring, a divalent pyrene ring, a divalent biphenyl ring, or a divalent terphenyl ring. The hydrocarbon group having 1 to 5 carbon atoms is preferably a linear, branched, or cyclic aliphatic hydrocarbon group.

cyclo-R represents a five to eight-membered, preferably six to eight-membered, divalent alicyclic hydrocarbon group which may form a condensed ring with one or two benzene rings or naphthalene rings. The two bonding sites in cyclo-R mean bonding sites each extending from a carbon atom constituting a ring of the alicyclic hydrocarbon group (the carbon atoms for the two bonding sites are preferably identical, and excludes carbon atoms belonging to an optionally contained condensed benzene ring or a condensed naphthalene ring. The alicyclic hydrocarbon group may be a divalent monocyclic hydrocarbon group derived from cyclohexane, cyclopentane, or the like, or may be a divalent polycyclic hydrocarbon group derived from dicyclopentadiene or the like. Examples of the alicyclic hydrocarbon group forming the condensed ring with a benzene ring or a naphthalene ring include a divalent hydrocarbon group derived from tetralin, 9,10-dihydroanthracene, 9,10-dihydrophenanthrene, indan, fluorene, benzocyclobutene, benzofluorene, dibenzofluorene, and acenaphthene. When the alicyclic hydrocarbon group is a five-membered ring, namely the divalent hydrocarbon group derived from cyclopentane, the number of benzene rings or naphthalene rings to form the condensed ring is reasonably preferably 0 to 2.

### (II-2-6)

As the formula (A-7), the following formula (A-7-1), which corresponds to the formula when n2=0, is more preferable.

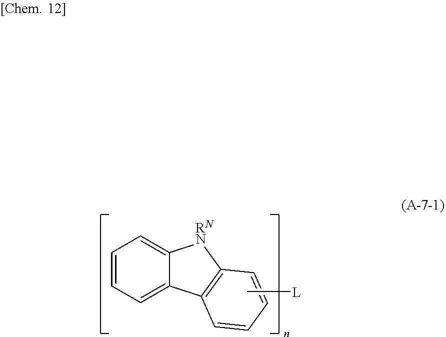

Here, R^{N} and L have the same definition as in the formula (A-7), provided that L is linked with each carbon atom on the aromatic ring of the number “n” of the carbazole skeletons, wherein “n” represents an integer of 2 to 6, and “n” represents 2 when L represents a single bond.

As the formula (A-9), the following formula (A-9-1), which corresponds to the formula when m22=0, is more preferable.

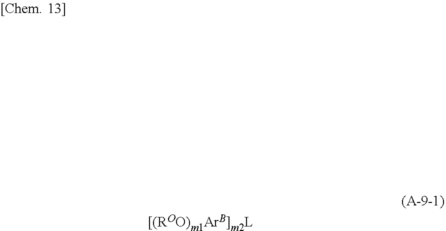

Here, R^{O} and L have the same definitions as in the formula (A-9), provided that L is linked with each of the number “m2” of carbon atoms on the Ar^{B} rings, wherein m2 represents an integer of 2 to 8, and “n” represents 2 when L represents a single bond.

m2 represents the number of the (R^{O}O)ₘ₁Ar^{B} groups, in which a carbon atom on the Ar^{B} ring is bonded to L, and m1 each independently represents the number of the R^{O}O groups and may be 0 or more. m1 each independently preferably represents 1 to 3.

Specific examples of (A-9) when L represents a single bond include biphenyl-4-ol and 4,4′-biphenyldiol.

### (II-2-7)

An additional substituent may be optionally present on the aromatic ring included in each of the carbazole skeletons in the formulae (A-1) to (A-7) or on the aromatic ring included in the formulae (A-8) to (A-9). Examples of the substituent include an oxygen-atom-containing substituent, such as a hydroxy group, an alkoxy group, an aryloxy group, a carboxyl group, a carbonyl group, a formyl group, an ether group, and an ester group; a sulfur-atom-containing substituent, such as a sulfonic acid group, a sulfide-containing group, and a sulfonyl-containing group; a nitrogen-atom-containing substituent, such as an amino group, a substituted amino group (such as monosubstituted or disubstituted amino group such as a monoalkylamine and a dialkylamine), an amide group, a nitro group, and a cyano group; a hydrocarbon group having 1 to 20 carbon atoms, such as an alkyl group, an alkenyl group, an alkynyl group, an aryl group (preferably an aryl group having 6 to 20 carbon atoms such as a phenyl group); and a halo group, such as a fluoro group, a chloro group, a bromo group, an iodo group, and a trifluoromethyl group. The substituents adjacent to each other may be condensed to form a ring. For example, a hydroxyl group and a carboxyl group that are the substituents adjacent to each other or are present in a substituent or substituents may form a lactone ring to result in cyclization. Similarly, an amino group and a carboxyl group may form an amide to result in a lactam ring.

### (II-2-8)

Specific examples of the repeating unit structure A having the carbazole skeleton at least as a partial structure include unit structures derived from the following compounds.

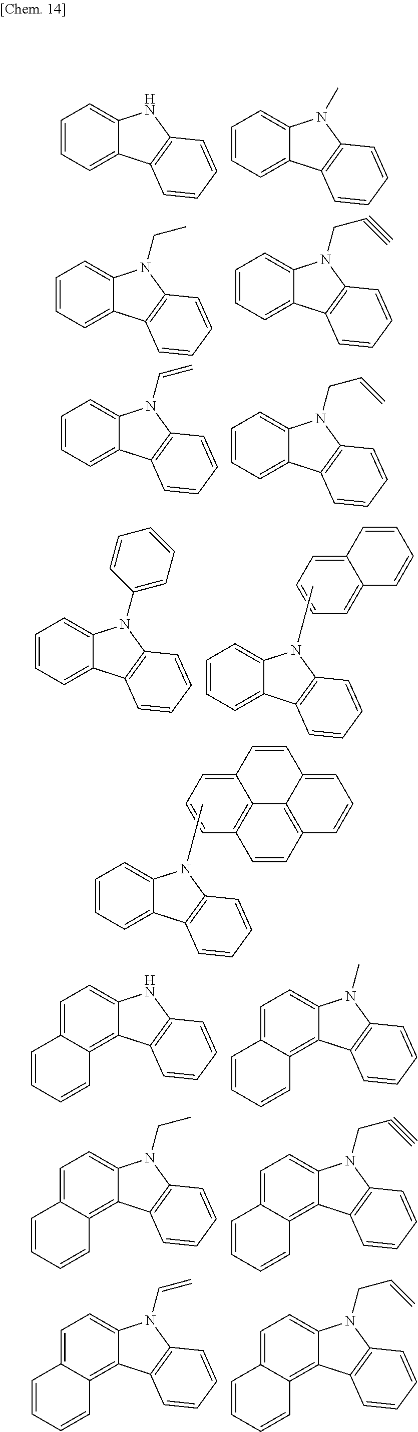

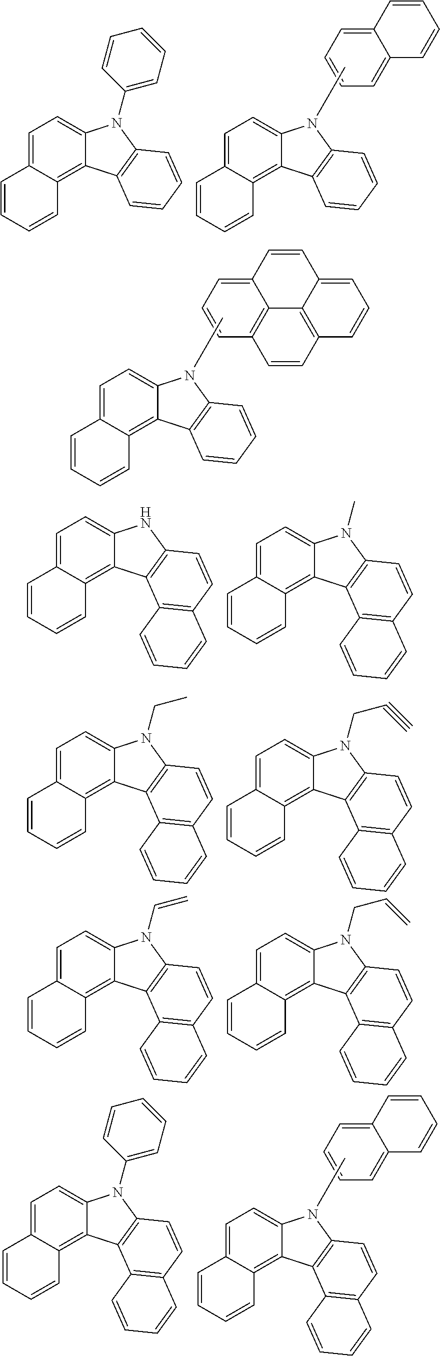

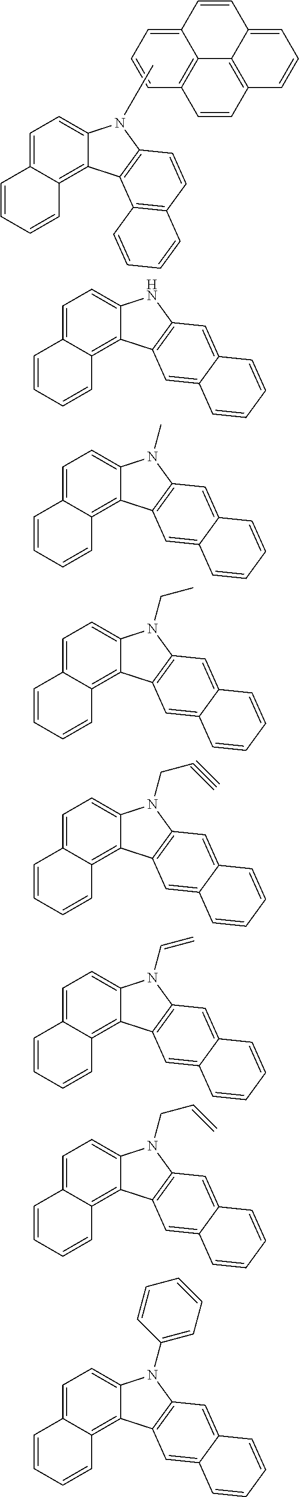

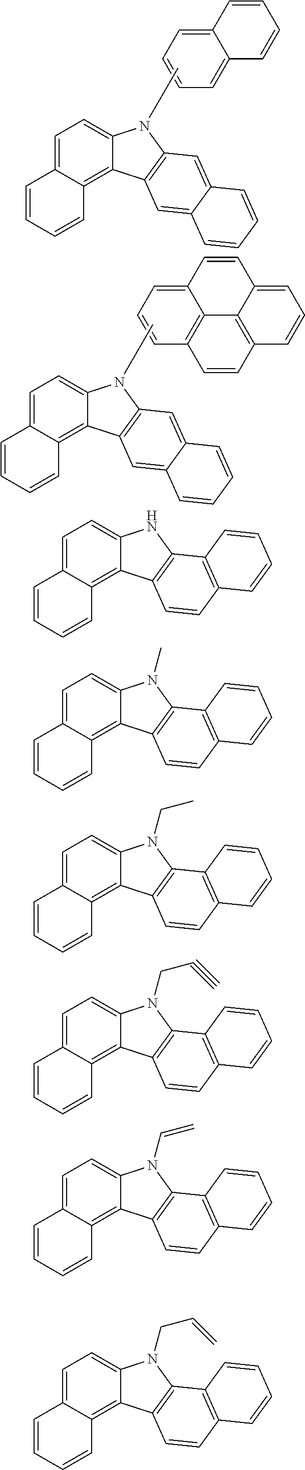

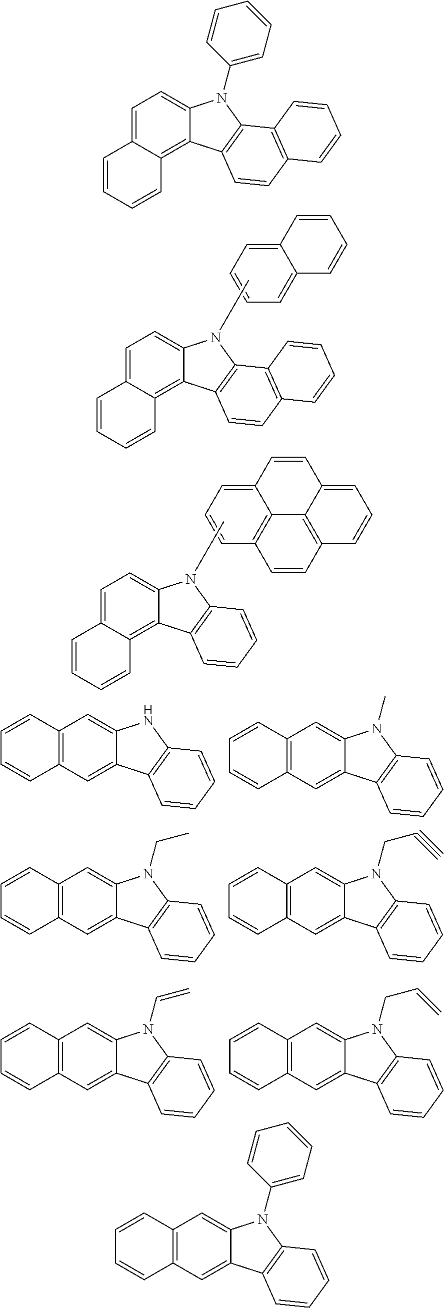

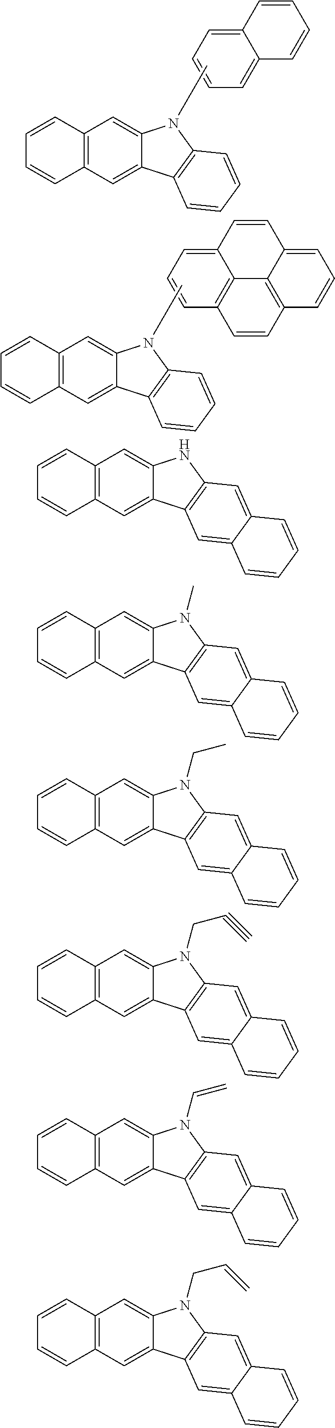

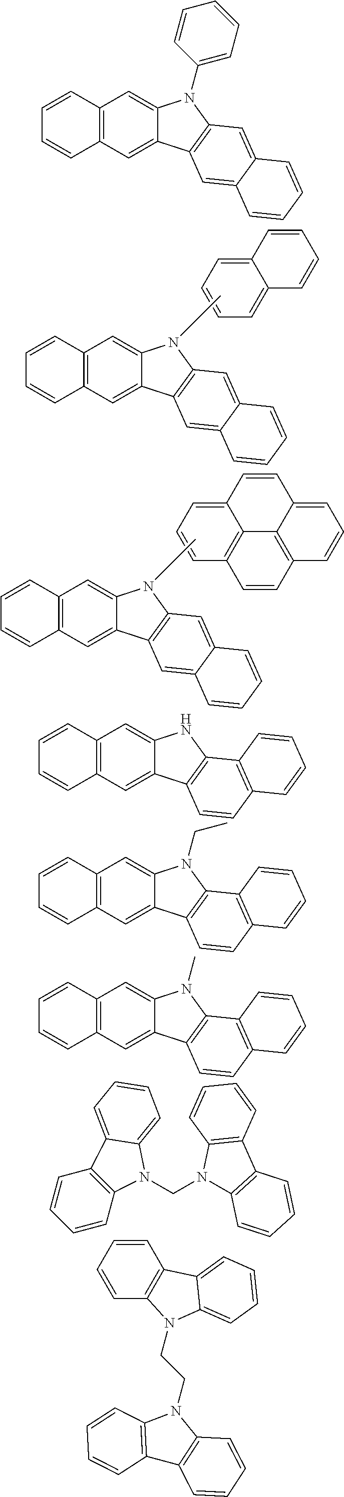

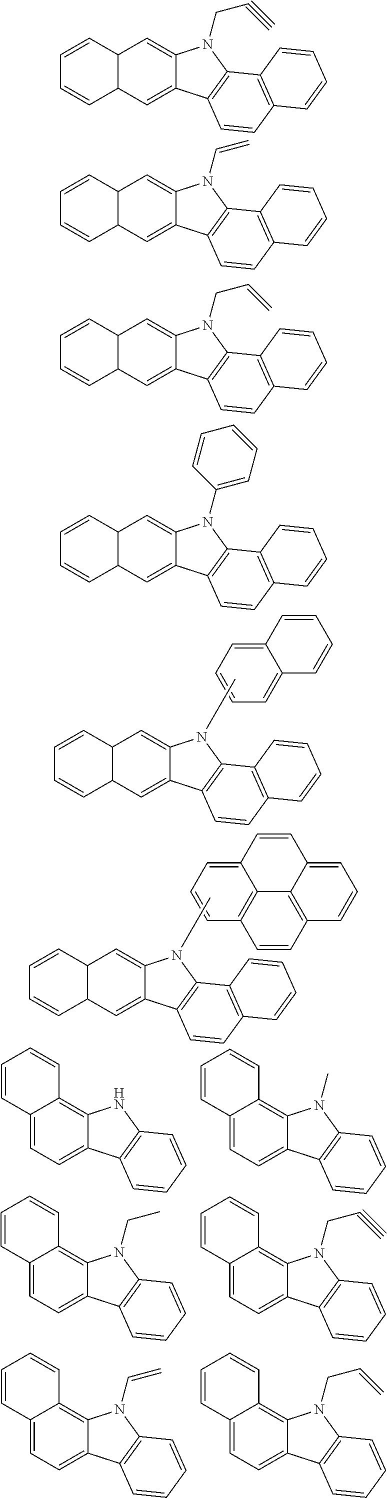

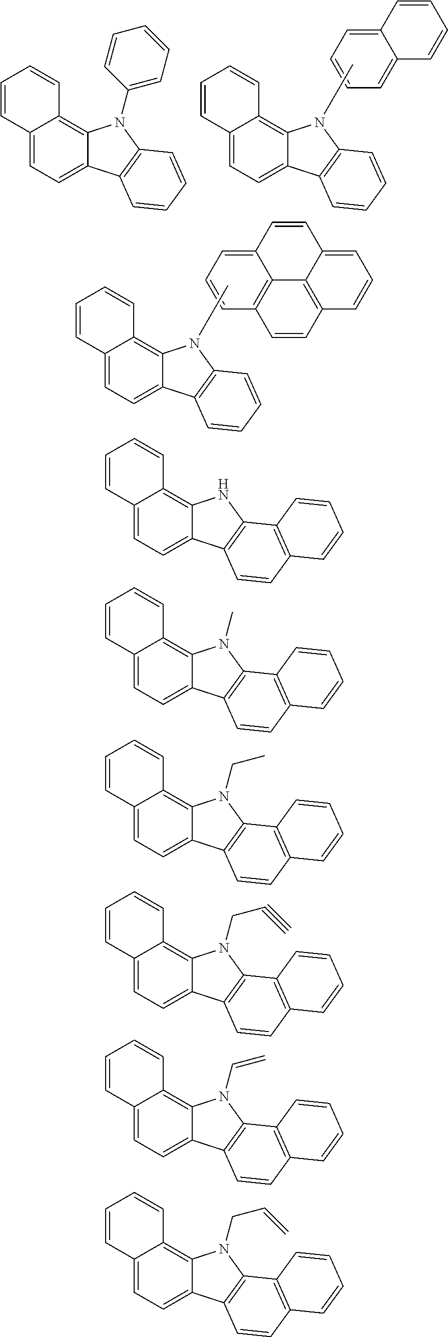

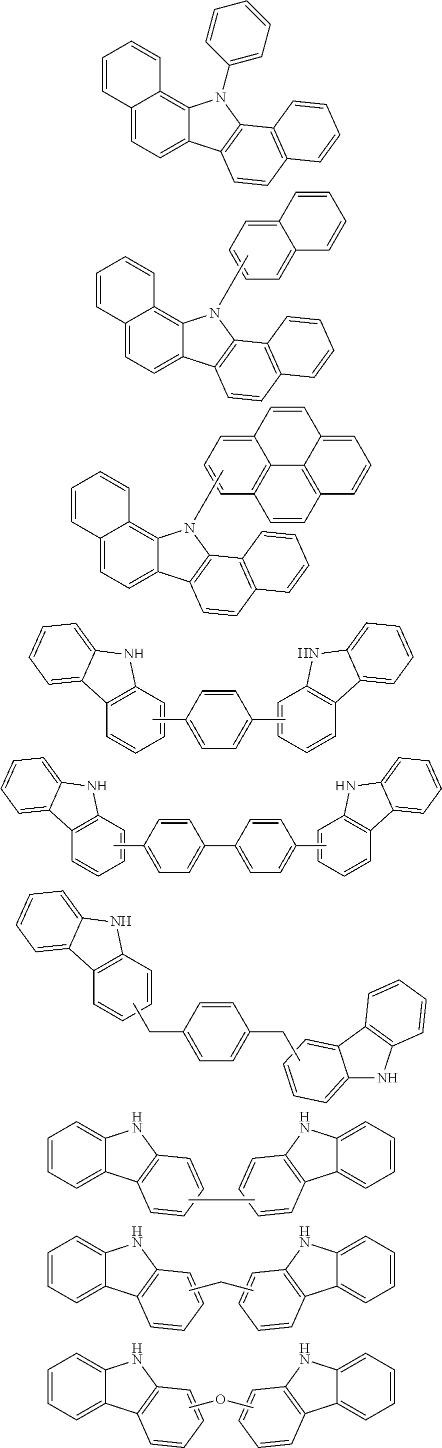

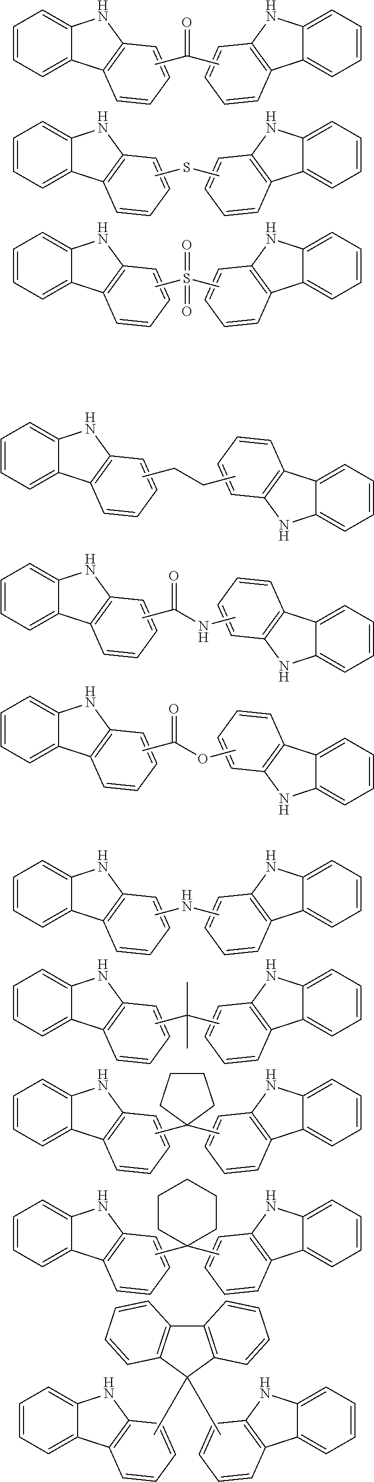

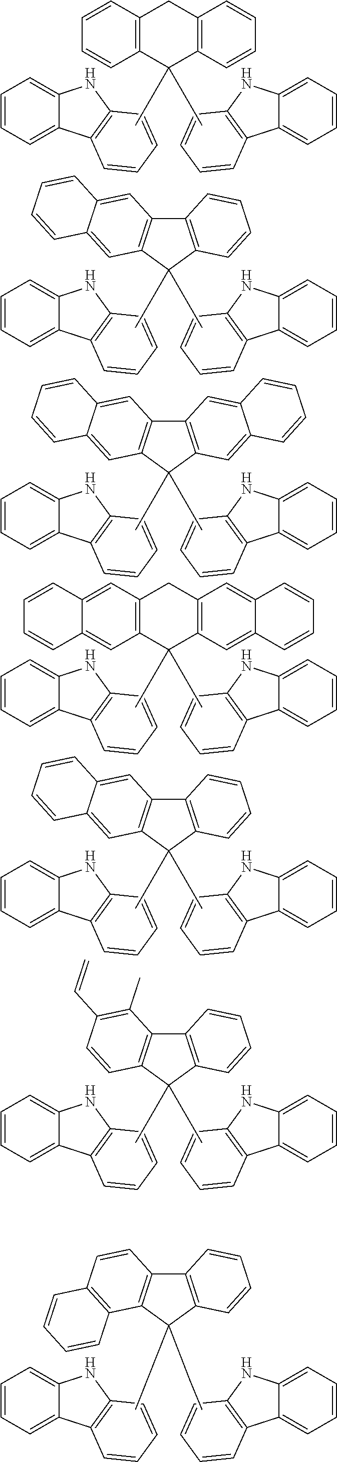

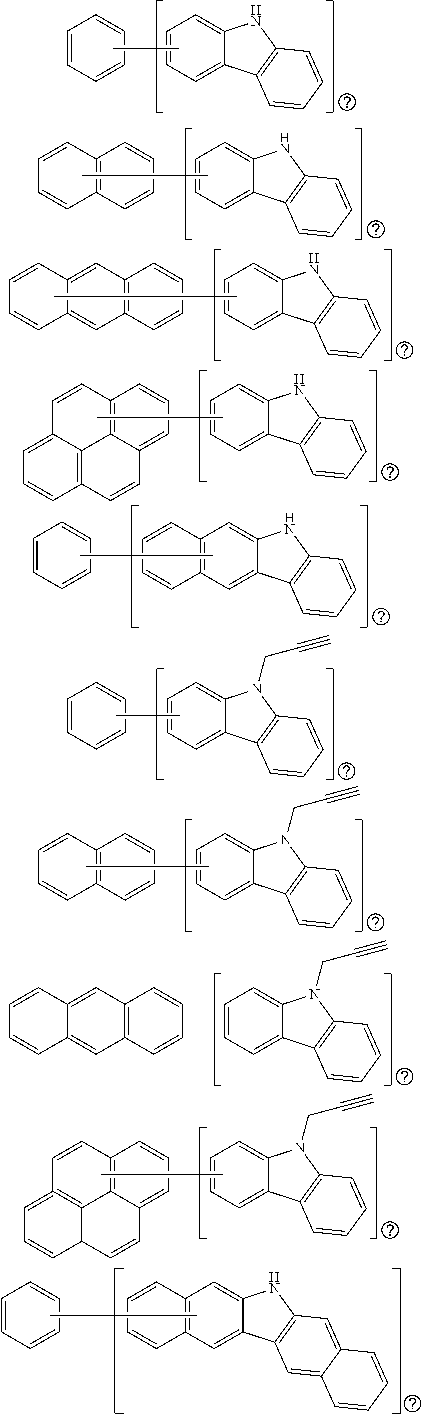

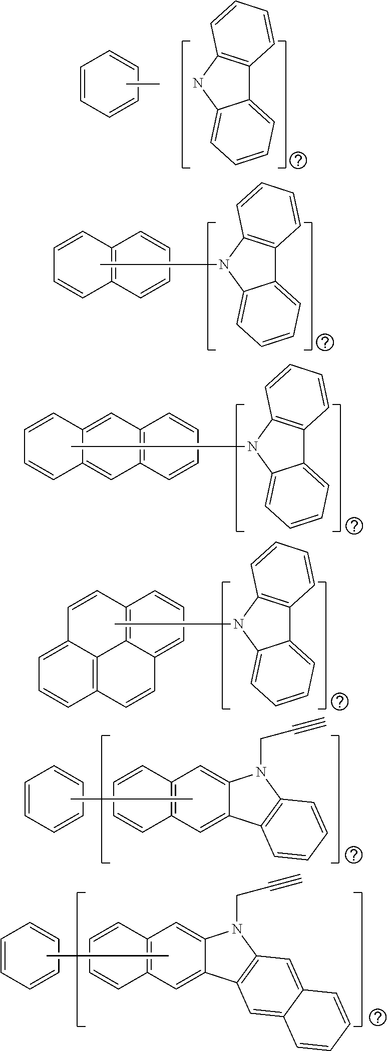

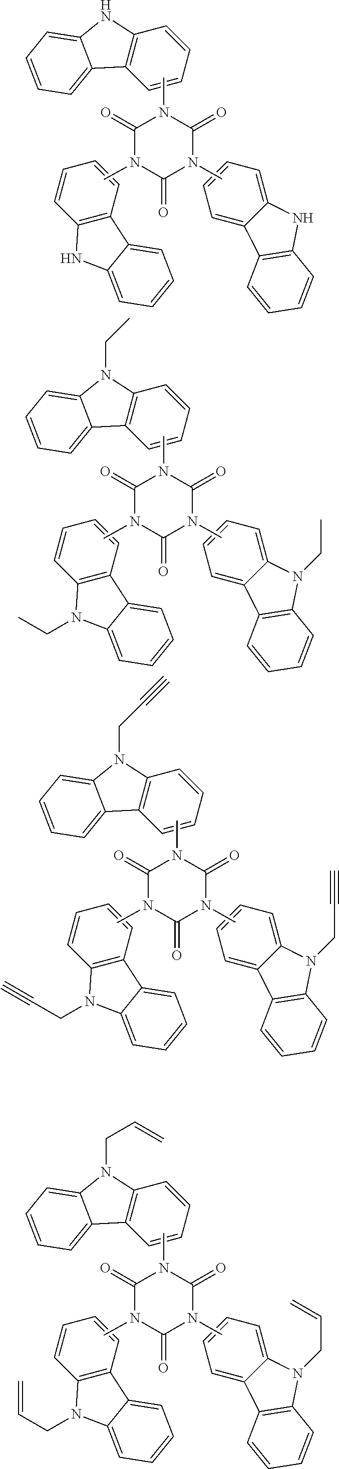

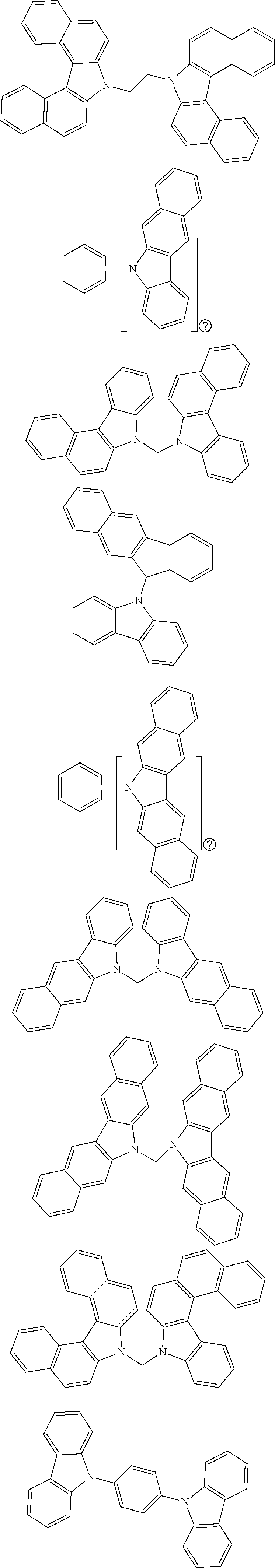

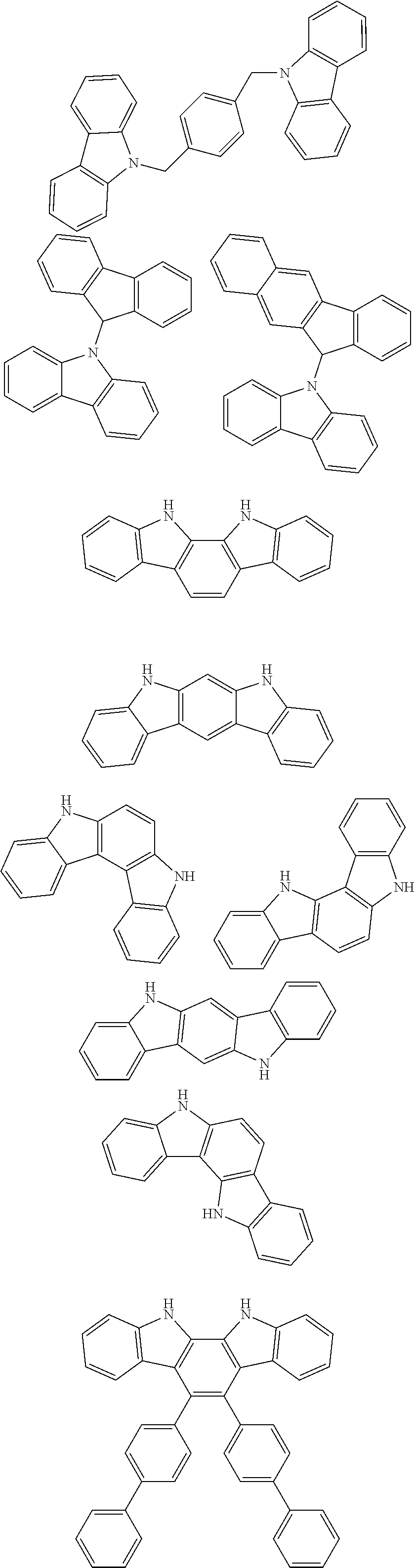

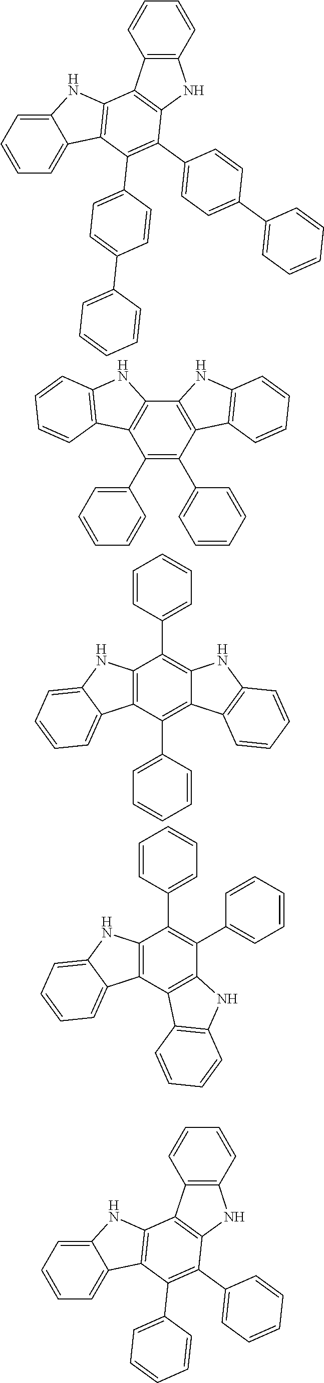

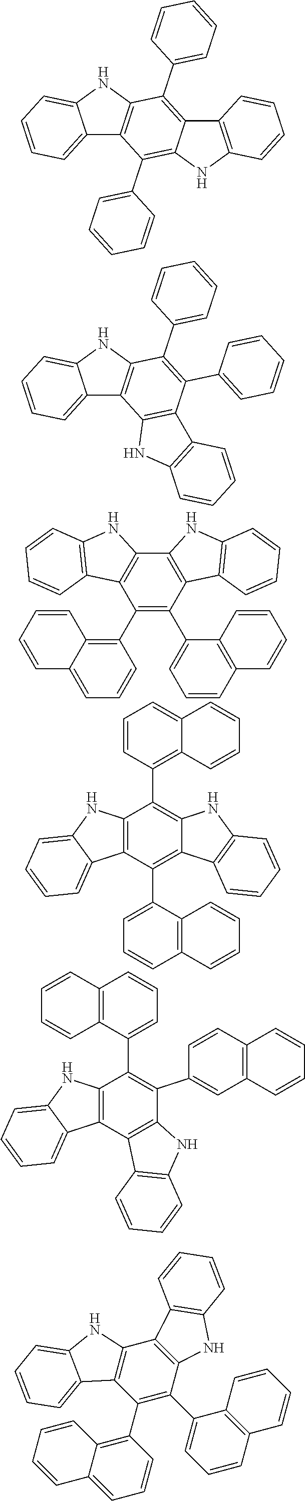

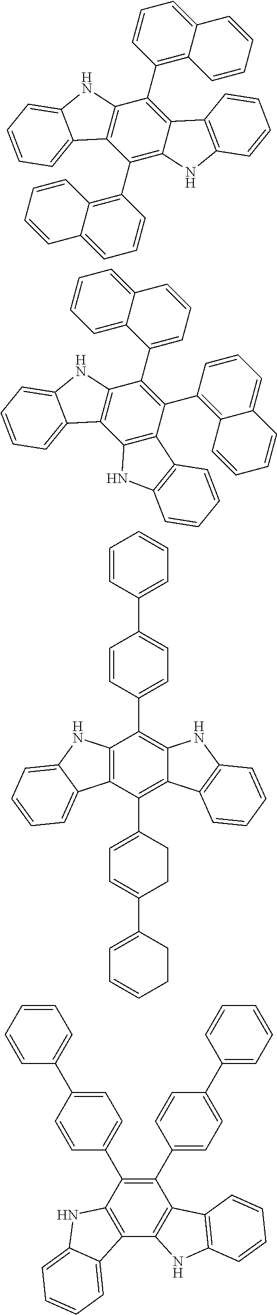

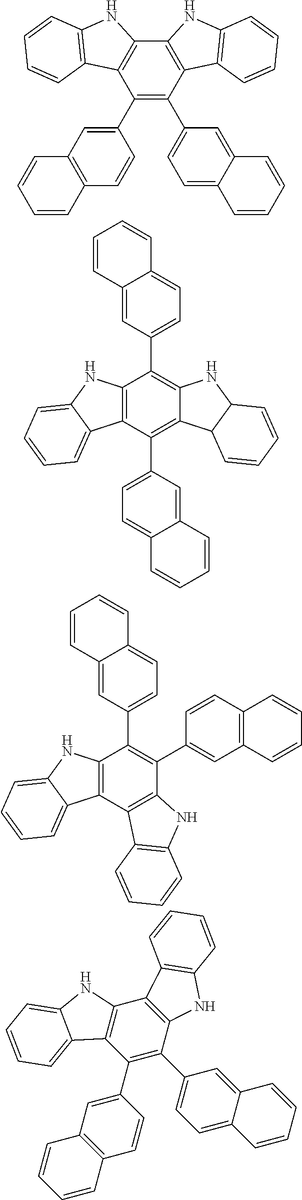

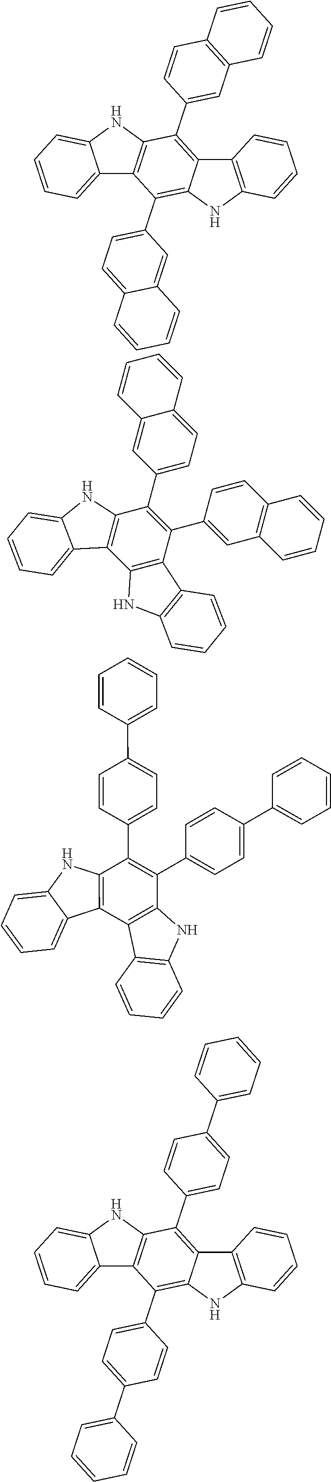

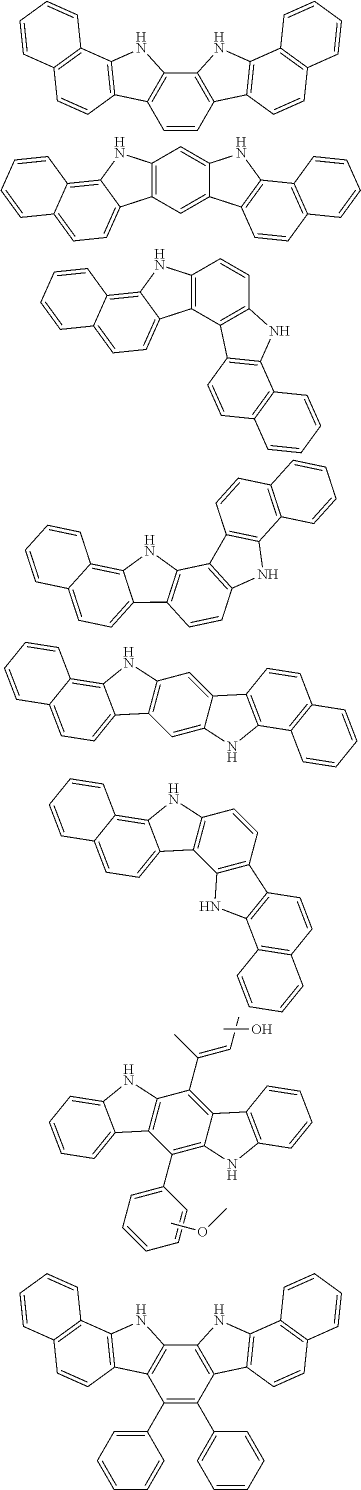

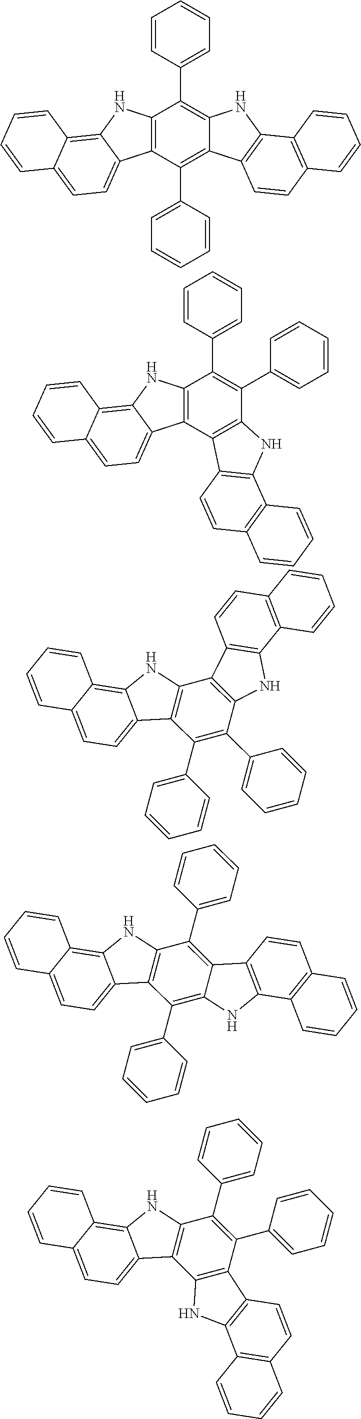

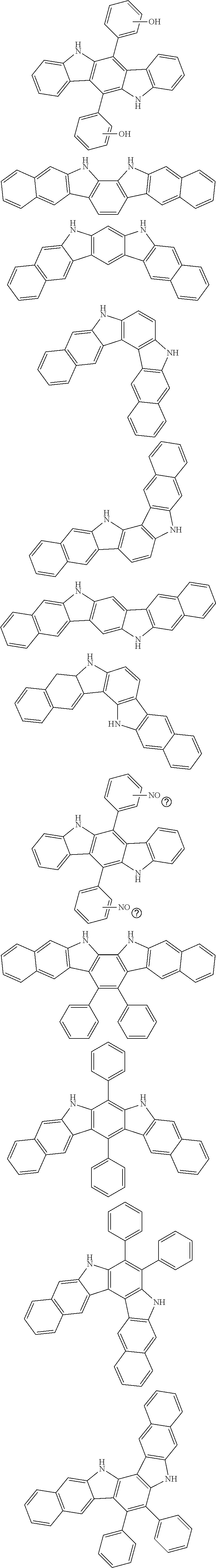

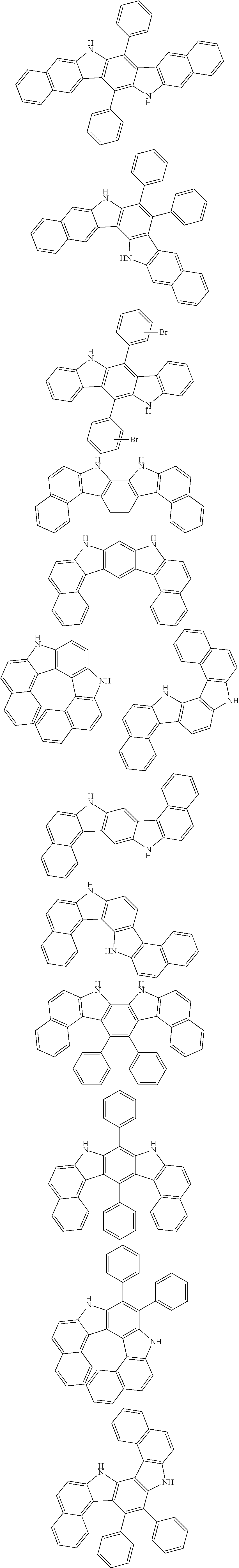

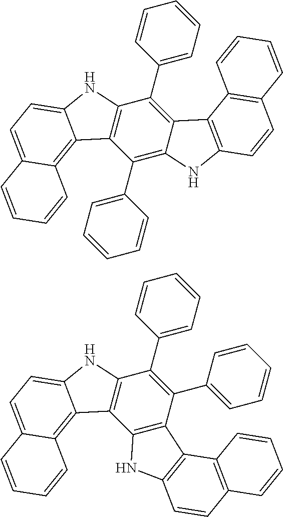

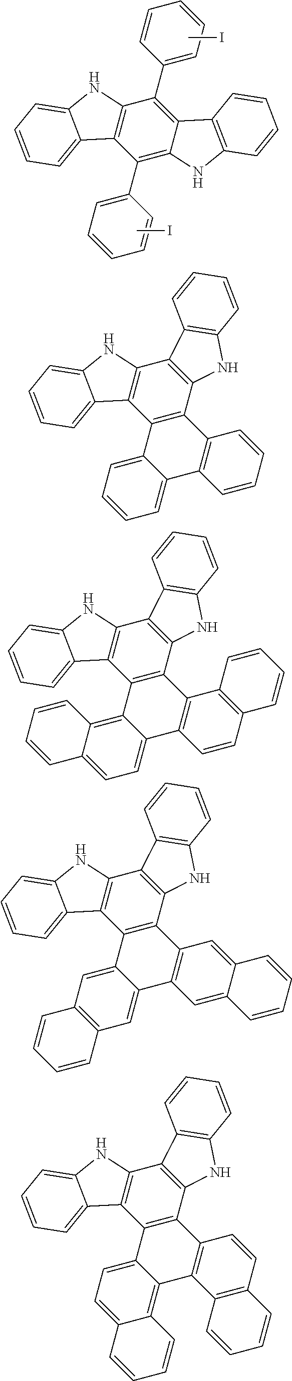

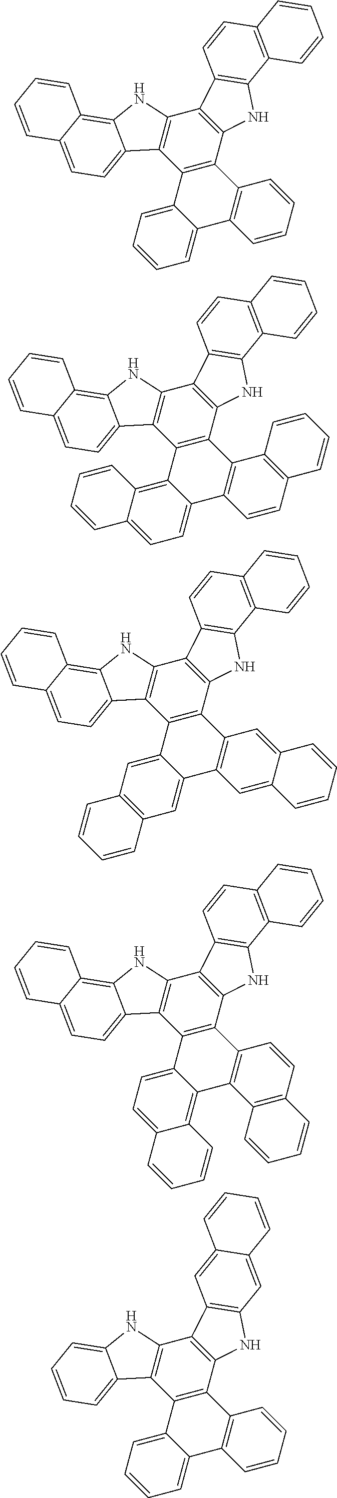

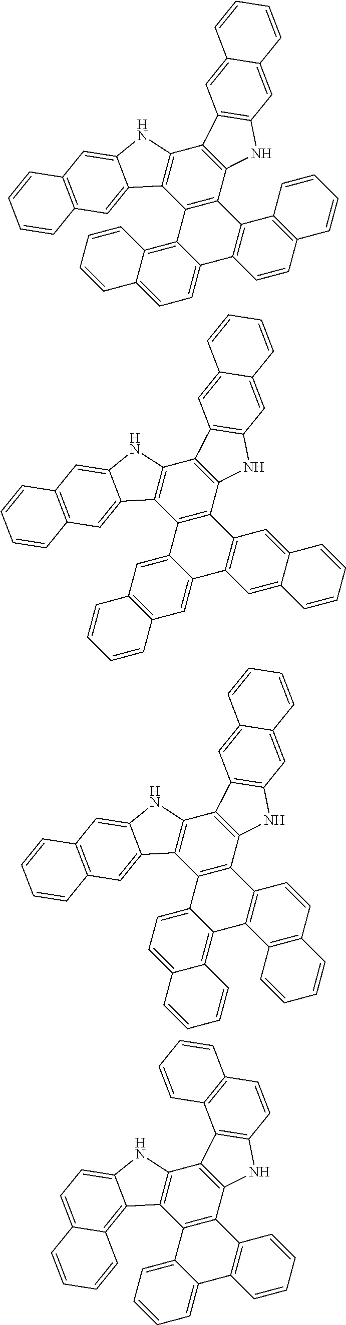

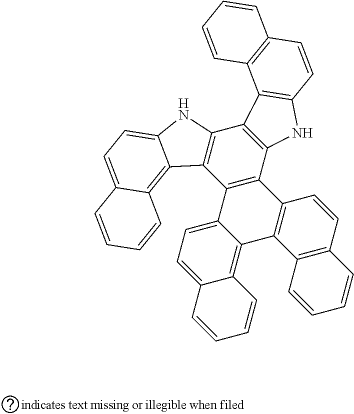

As for the repeating unit structure A having the carbazole skeleton at least as a partial structure, typical unit structures with bonding sites will be shown below.

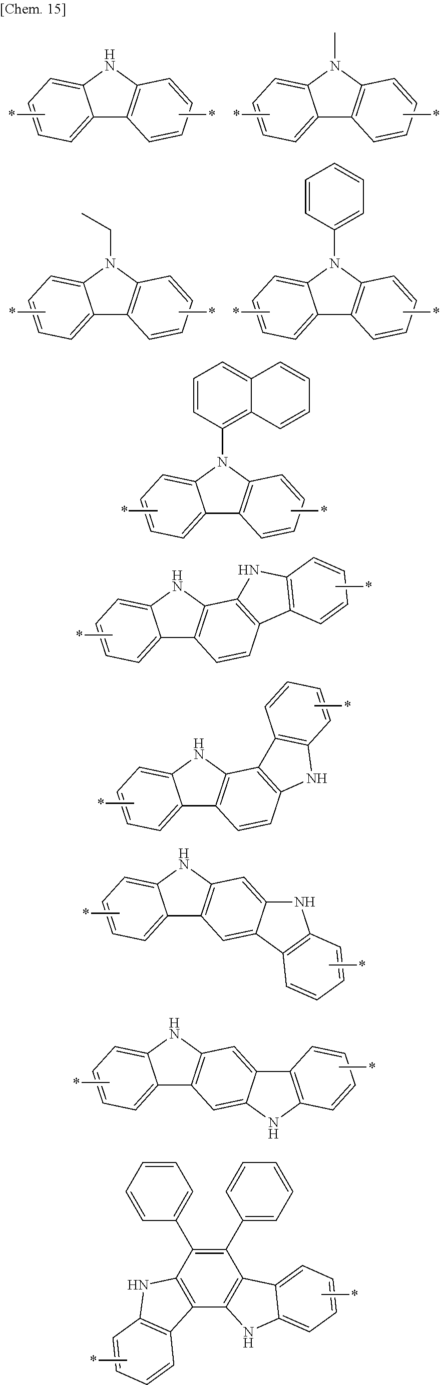

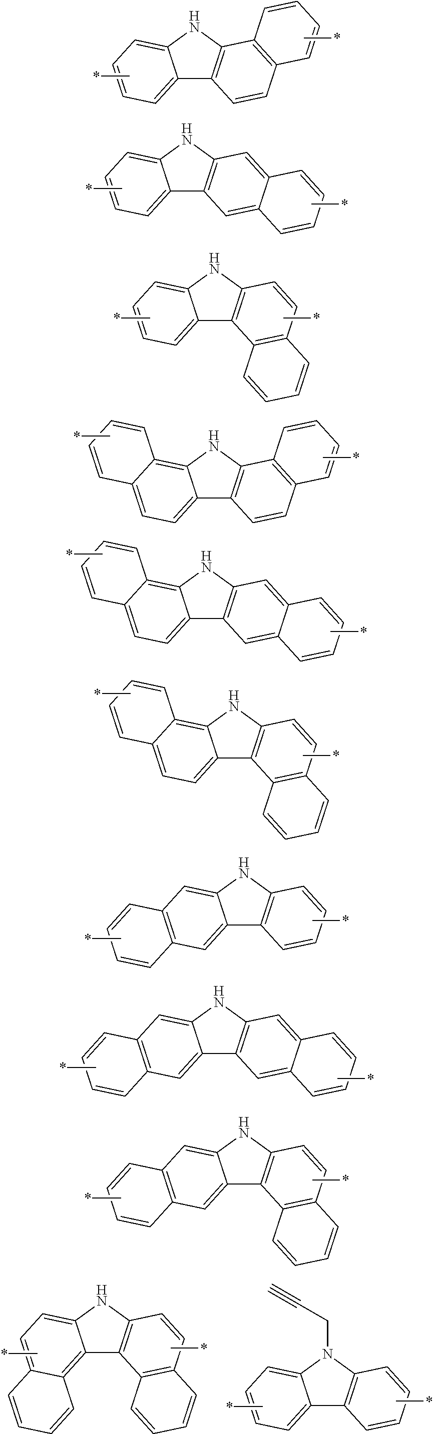

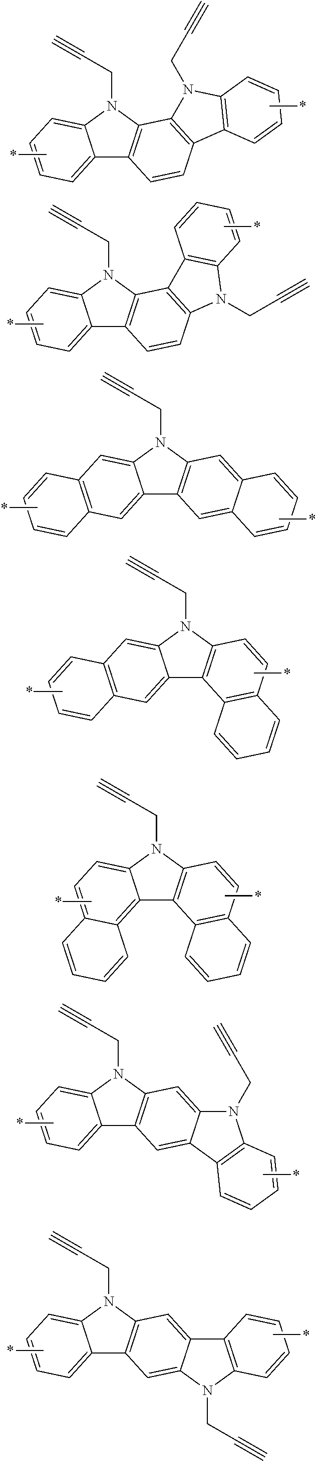

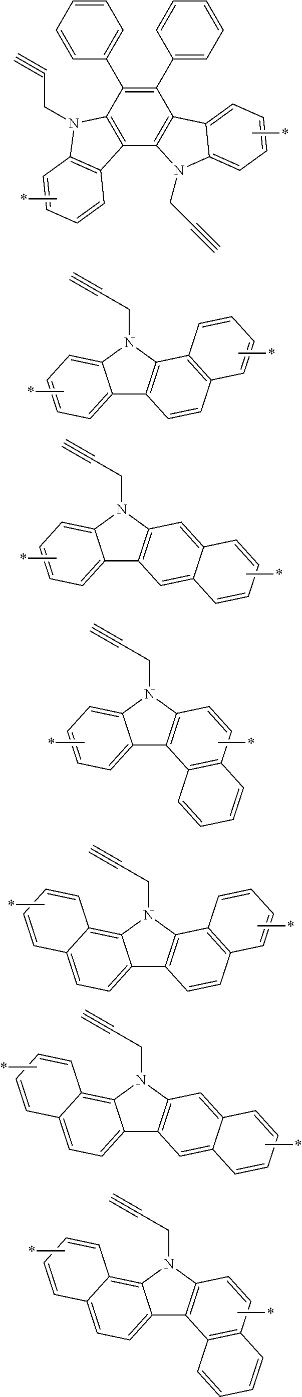

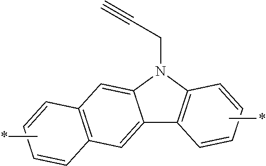

### (II-2-9)

Examples of the repeating unit structure A having the phenol skeleton at least as a partial structure include unit structures derived from the following compounds. A phenolic hydroxy group, which are a hydroxy group on a benzene ring included as at least a partial skeleton, on any of these phenol skeletons exemplified may be substituted with an R^{O}O group (provided that a hydrogen atom is extruded as R^{O}) to form the phenoxy skeleton, whereby unit structures derived from compounds having a phenoxy skeleton can be exemplified.

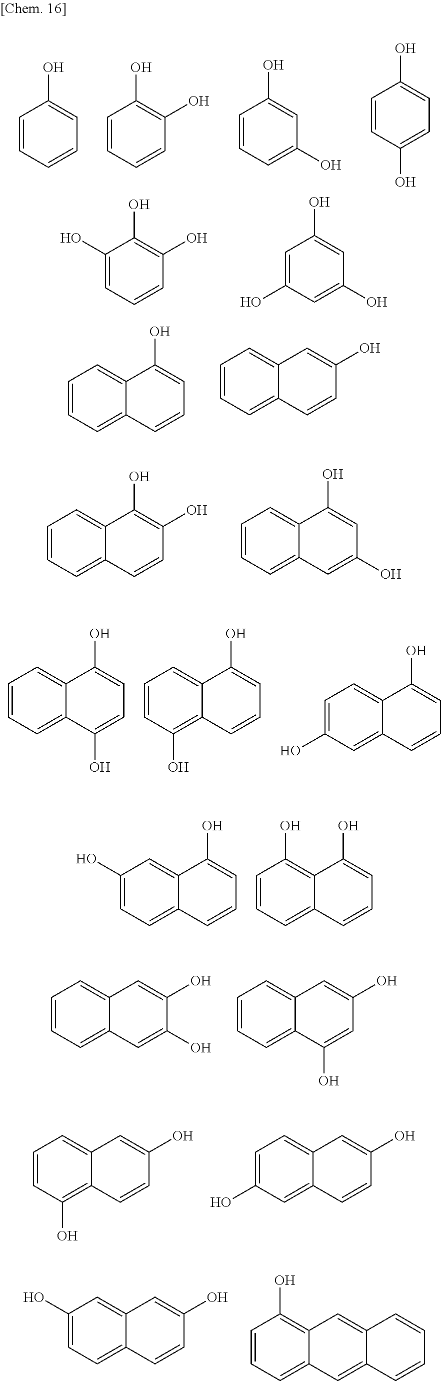

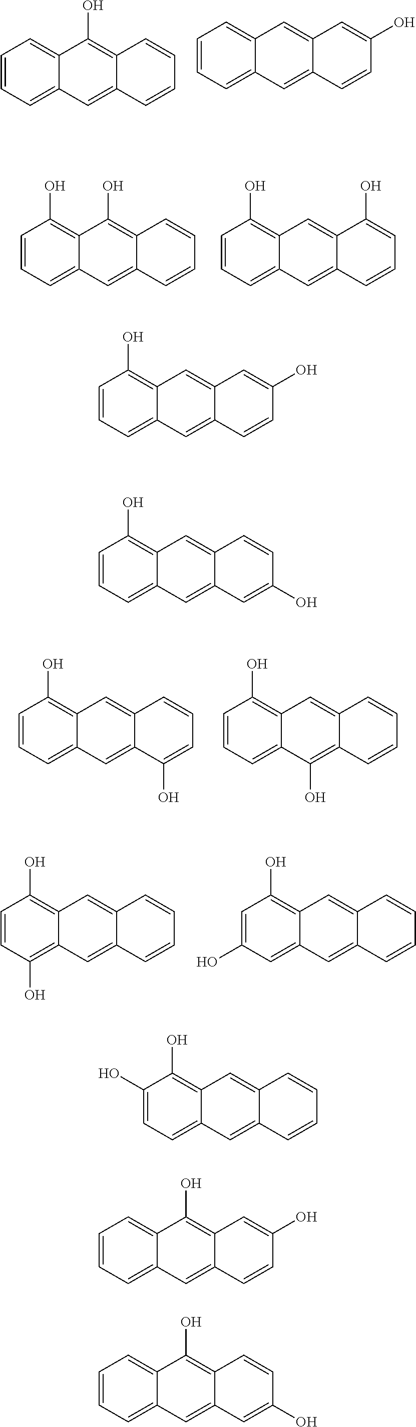

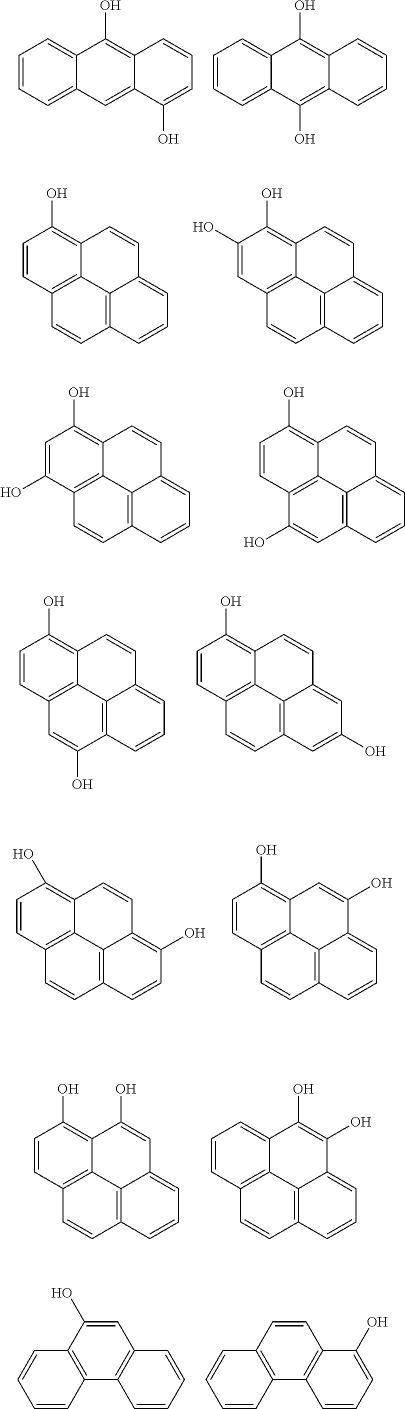

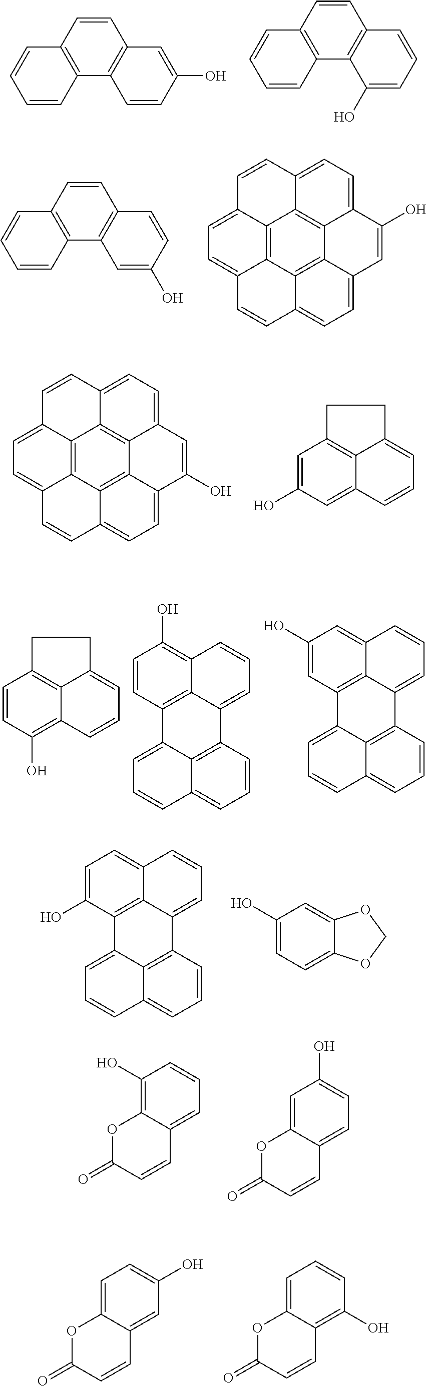

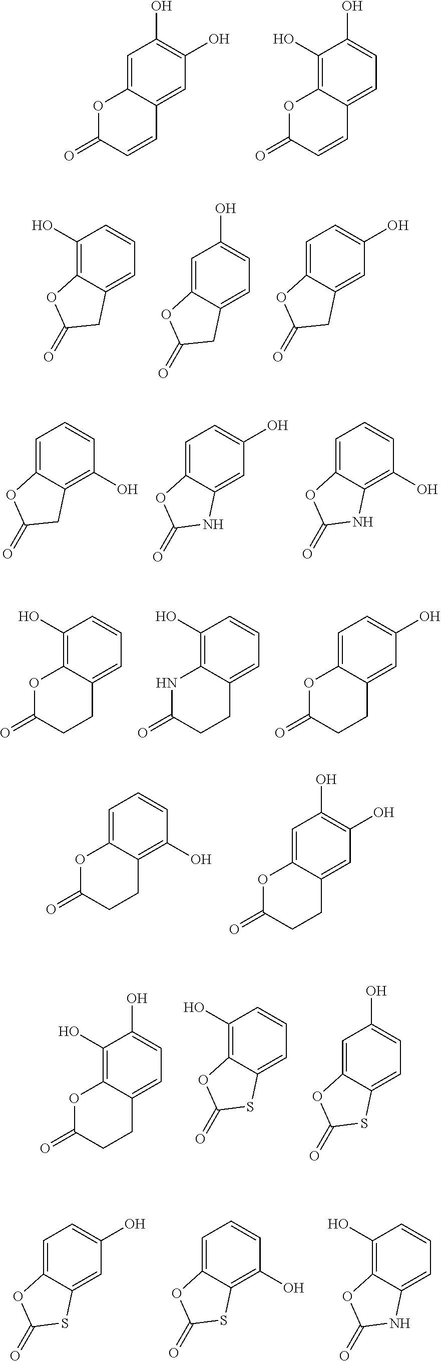

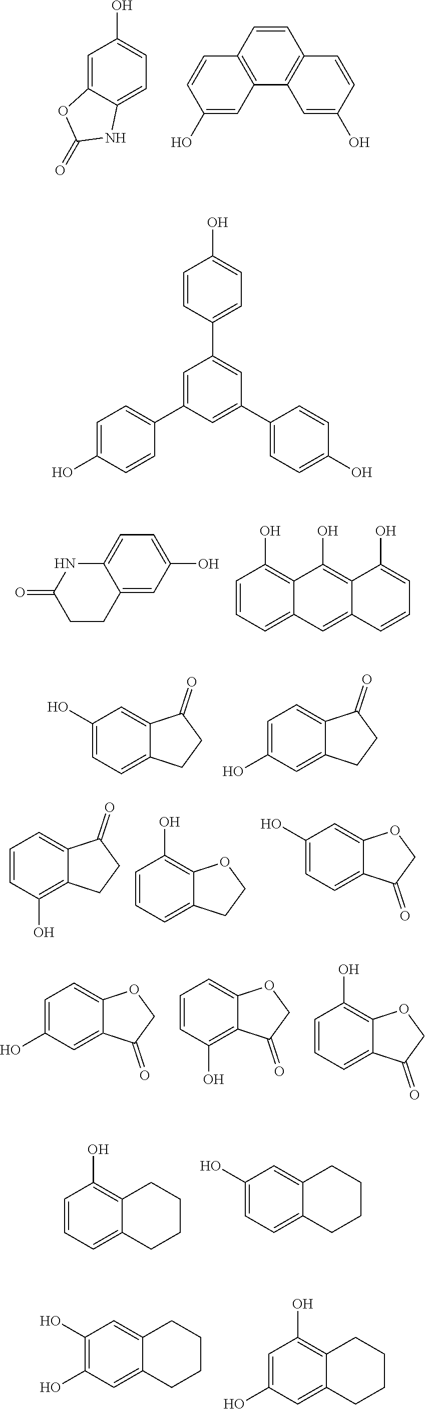

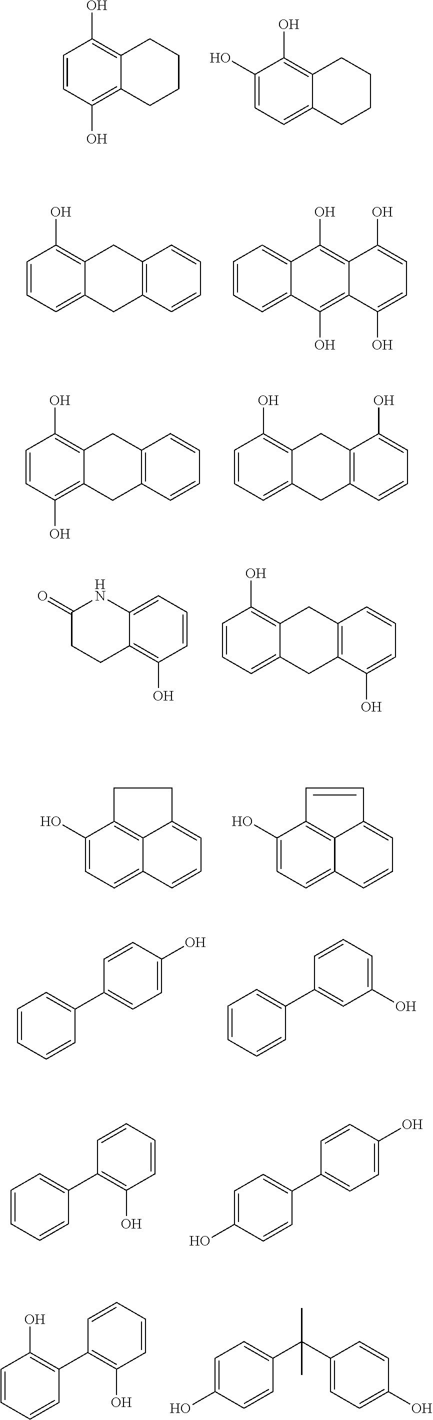

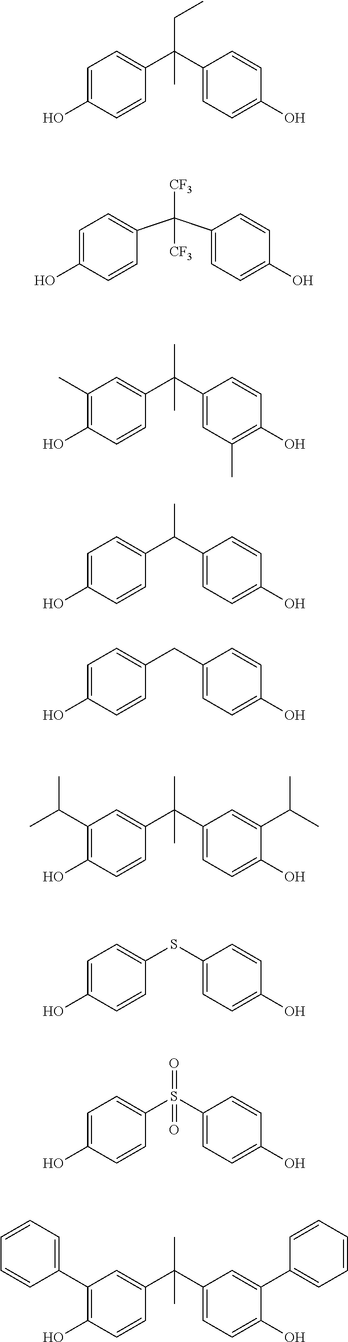

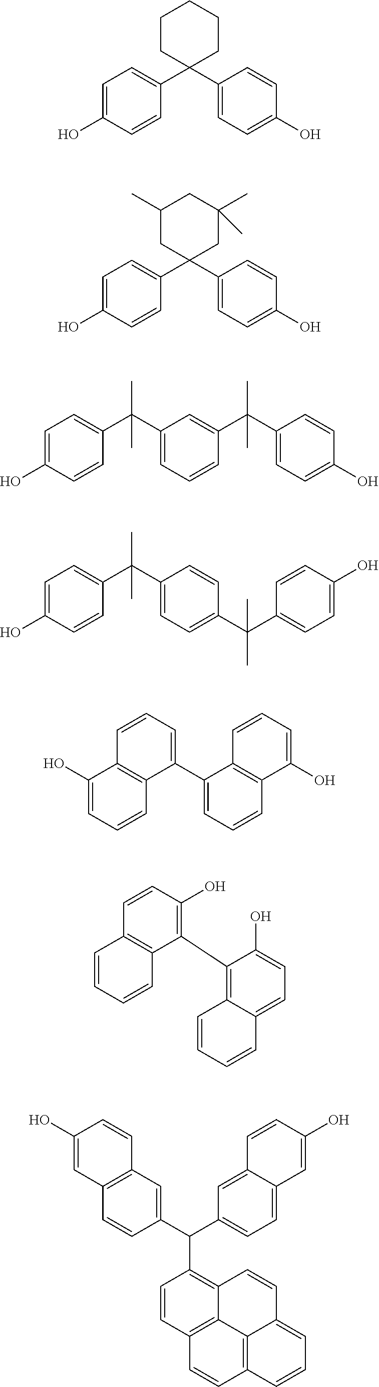

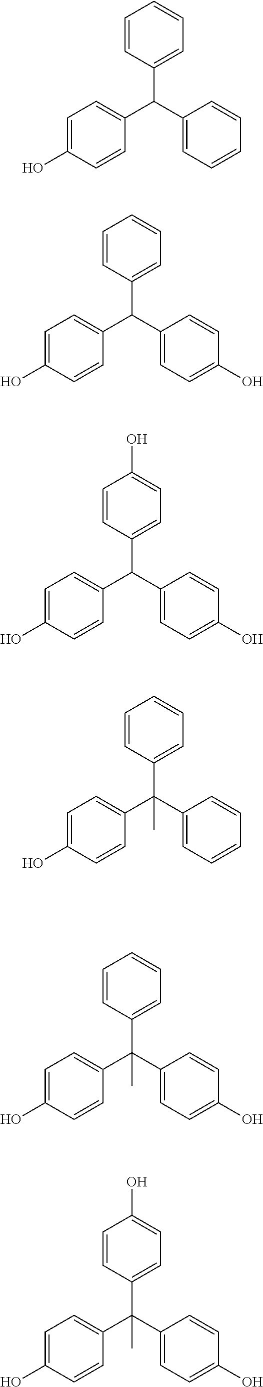 [SMILES: Oc1ccc(C(c2ccccc2)c2ccccc2)cc1 ; Oc1ccc(C(c2ccccc2)c2ccc(O)cc2)cc1 ; Oc1ccc(C(c2ccc(O)cc2)c2ccc(O)cc2)cc1 ; CC(c1ccccc1)(c1ccccc1)c1ccc(O)cc1 ; CC(c1ccccc1)(c1ccc(O)cc1)c1ccc(O)cc1 ; CC(c1ccc(O)cc1)(c1ccc(O)cc1)c1ccc(O)cc1]

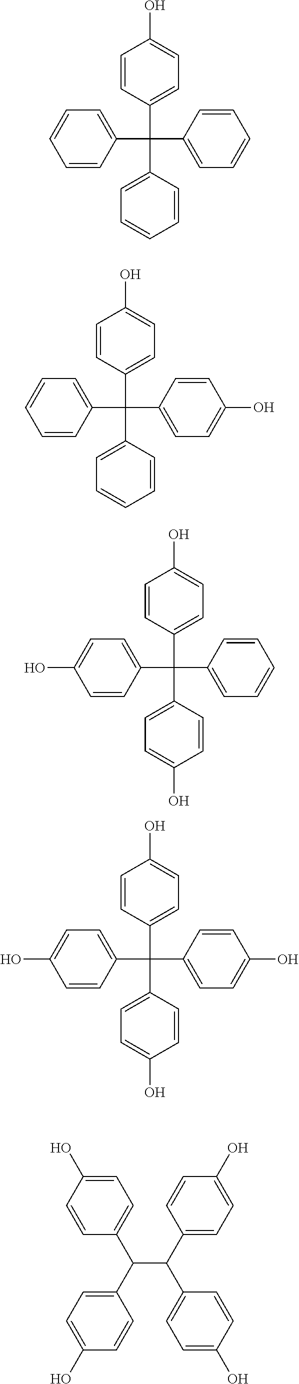

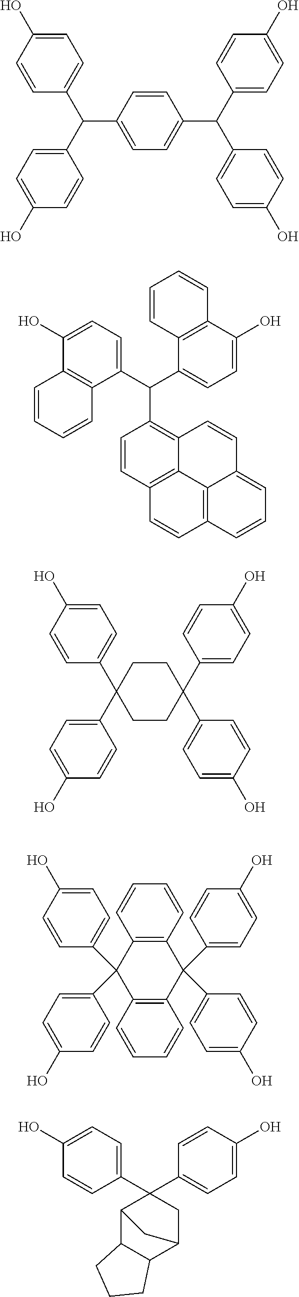

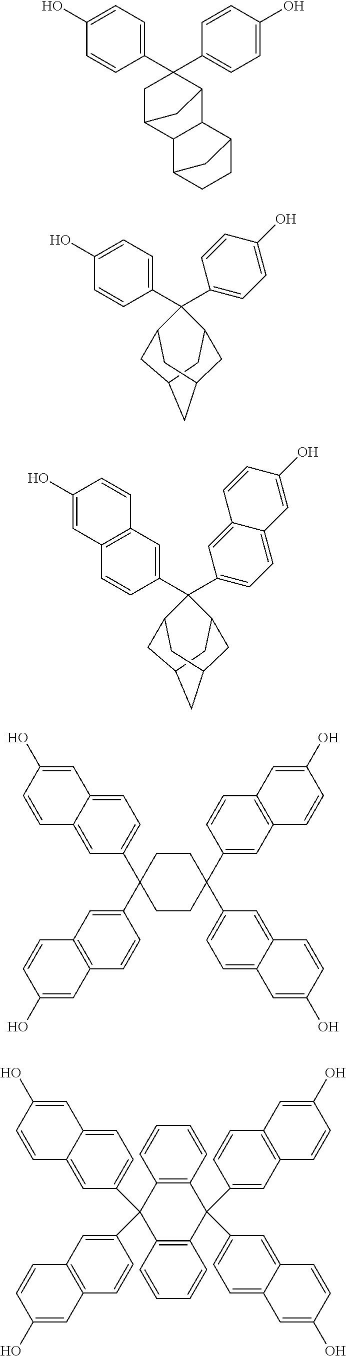 [SMILES: Oc1ccc(C2(c3ccc(O)cc3)CC3CC2C2C4CCC(C4)C32)cc1 ; Oc1ccc(C2(c3ccc(O)cc3)C3CC4CC(C3)CC2C4)cc1 ; Oc1ccc2cc(C3(c4ccc5cc(O)ccc5c4)C4CC5CC(C4)CC3C5)ccc2c1 ; Oc1ccc2cc(C3(c4ccc5cc(O)ccc5c4)CCC(c4ccc5cc(O)ccc5c4)(c4ccc5cc(O)ccc5c4)CC3)ccc2c1 ; Oc1ccc2cc(C3(c4ccc5cc(O)ccc5c4)c4ccccc4C(c4ccc5cc(O)ccc5c4)(c4ccc5cc(O)ccc5c4)c4ccccc43)ccc2c1]

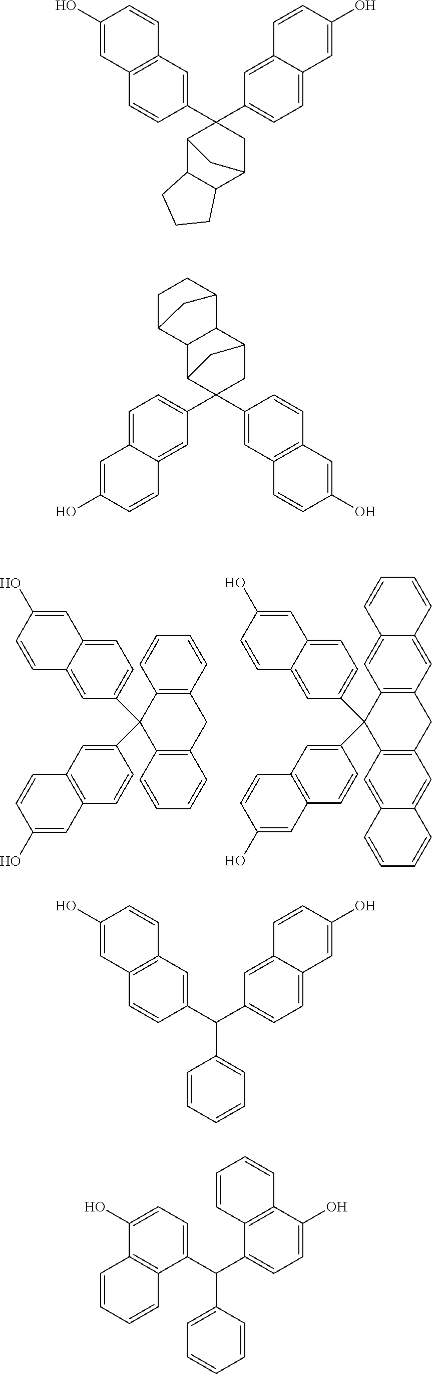

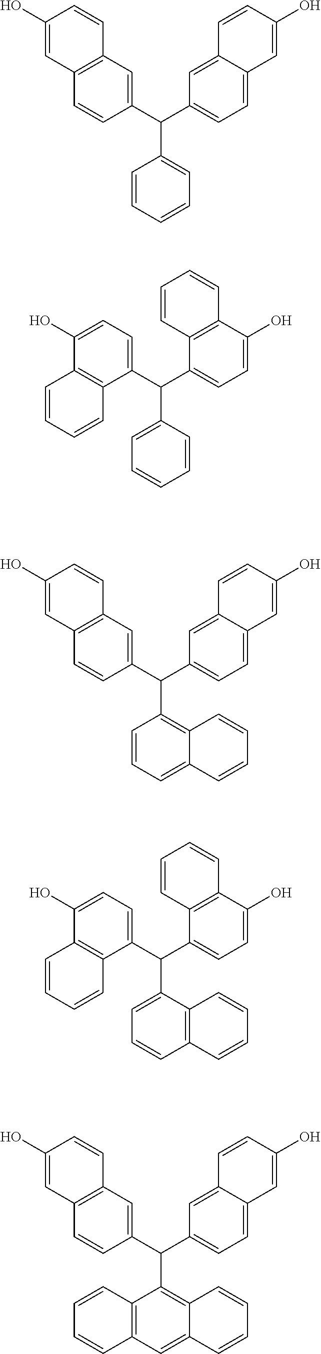 [SMILES: Oc1ccc2cc(C(c3ccccc3)c3ccc4cc(O)ccc4c3)ccc2c1 ; Oc1ccc(C(c2ccccc2)c2ccc(O)c3ccccc23)c2ccccc12 ; Oc1ccc2cc(C(c3ccc4cc(O)ccc4c3)c3cccc4ccccc34)ccc2c1 ; Oc1ccc(C(c2cccc3ccccc23)c2ccc(O)c3ccccc23)c2ccccc12 ; Oc1ccc2cc(C(c3ccc4cc(O)ccc4c3)c3c4ccccc4cc4ccccc34)ccc2c1]

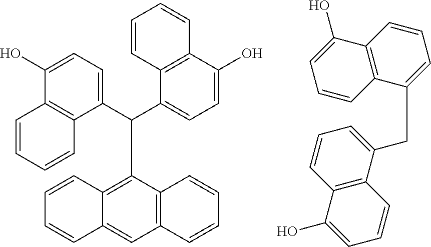 [SMILES: Oc1ccc(C(c2c3ccccc3cc3ccccc23)c2ccc(O)c3ccccc23)c2ccccc12 ; Oc1cccc2c(Cc3cccc4c(O)cccc34)cccc12]

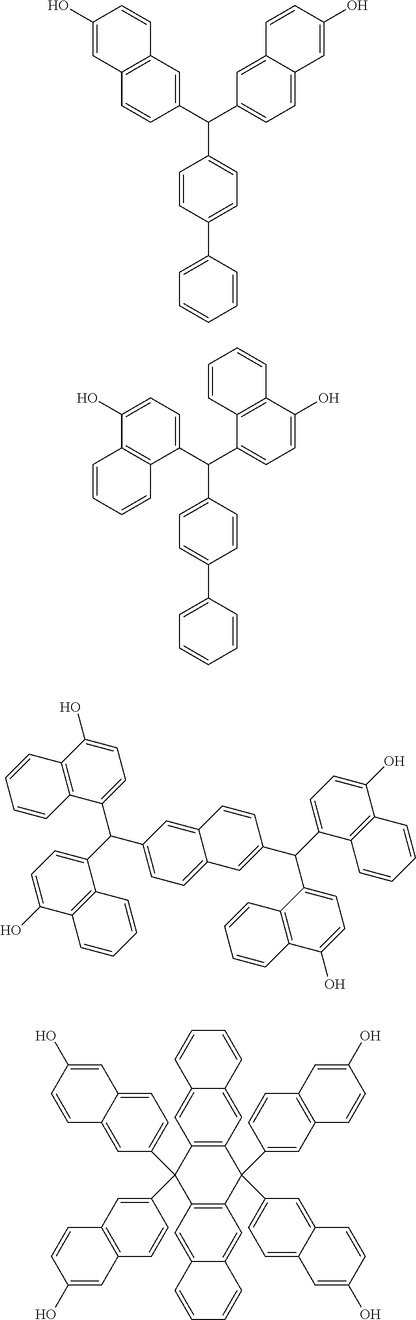

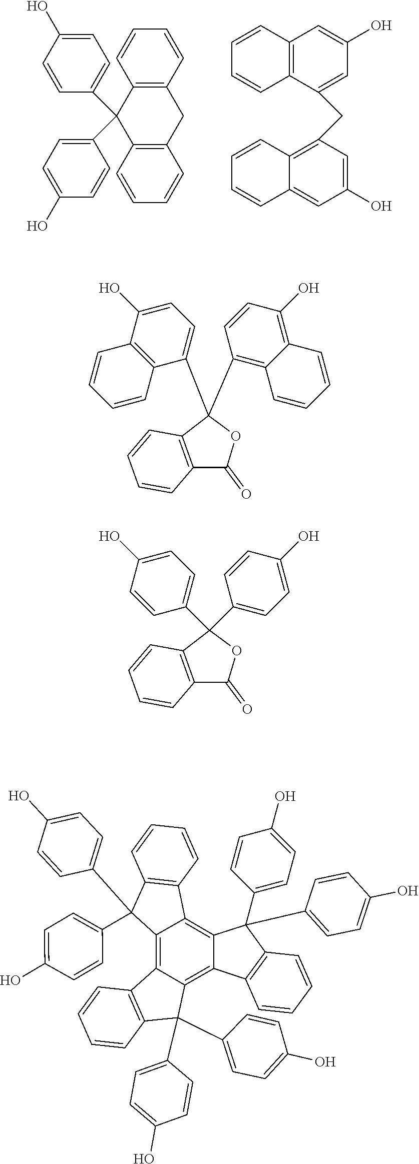

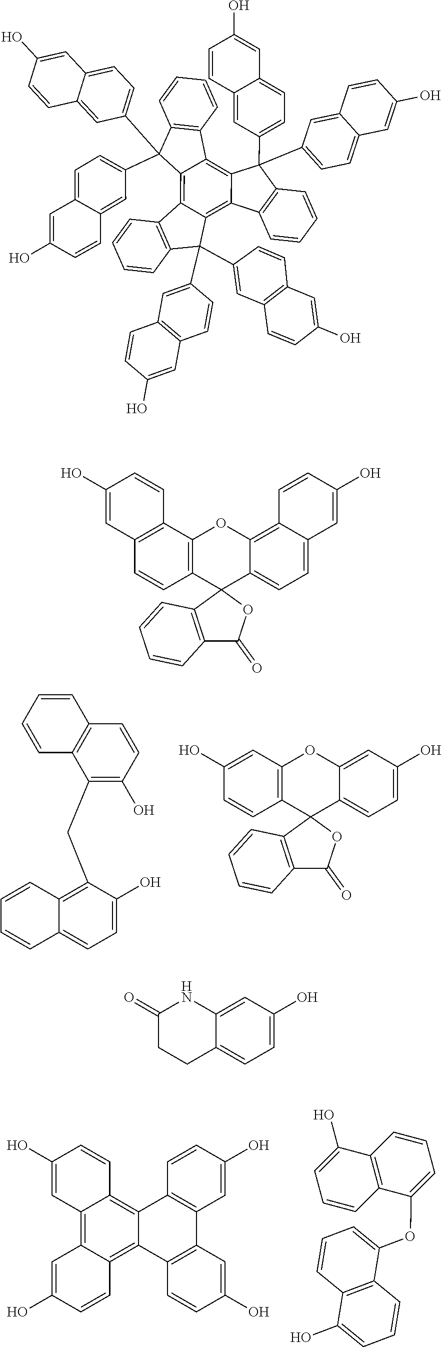

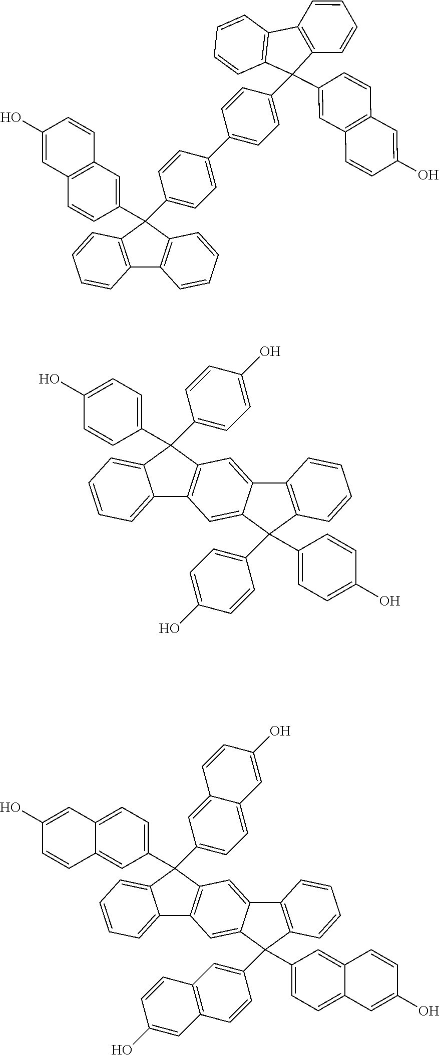 [SMILES: Oc1ccc2cc(C3(c4ccc(-c5ccc(C6(c7ccc8cc(O)ccc8c7)c7ccccc7-c7ccccc76)cc5)cc4)c4ccccc4-c4ccccc43)ccc2c1 ; Oc1ccc(C2(c3ccc(O)cc3)c3ccccc3-c3cc4c(cc32)-c2ccccc2C4(c2ccc(O)cc2)c2ccc(O)cc2)cc1 ; Oc1ccc2cc(C3(c4ccc5cc(O)ccc5c4)c4ccccc4-c4cc5c(cc43)-c3ccccc3C5(c3ccc4cc(O)ccc4c3)c3ccc4cc(O)ccc4c3)ccc2c1]

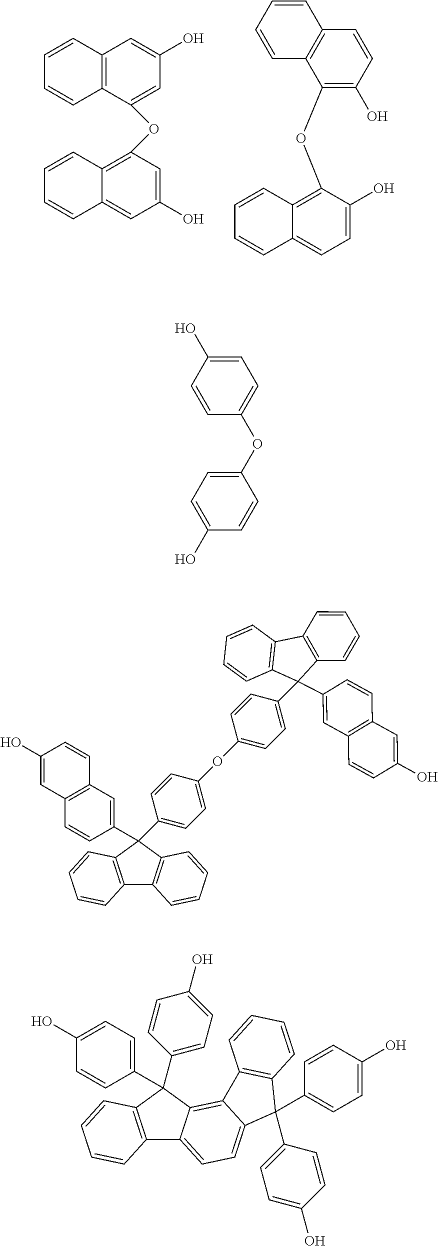 [SMILES: Oc1cc(Oc2cc(O)cc3ccccc23)c2ccccc2c1 ; Oc1ccc2ccccc2c1Oc1c(O)ccc2ccccc12 ; Oc1ccc(Oc2ccc(O)cc2)cc1 ; Oc1ccc2cc(C3(c4ccc(Oc5ccc(C6(c7ccc8cc(O)ccc8c7)c7ccccc7-c7ccccc76)cc5)cc4)c4ccccc4-c4ccccc43)ccc2c1 ; Oc1ccc(C2(c3ccc(O)cc3)c3ccccc3-c3c2ccc2c3C(c3ccc(O)cc3)(c3ccc(O)cc3)c3ccccc3-2)cc1]

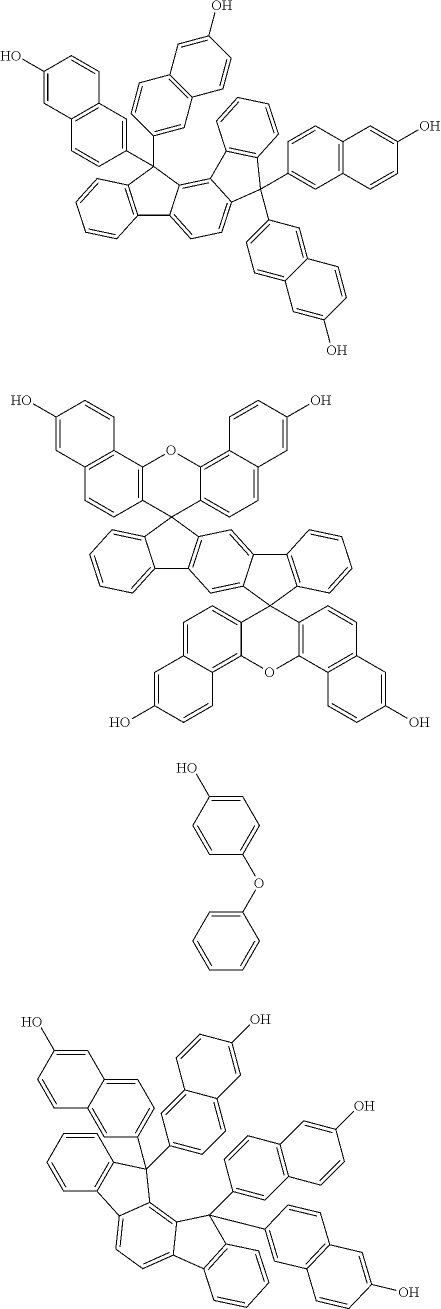

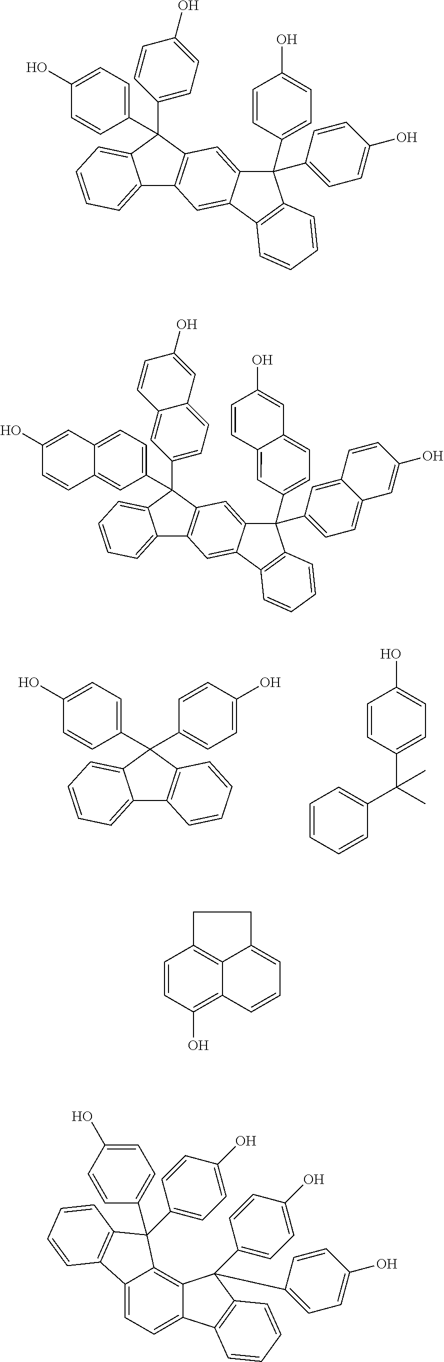 [SMILES: Oc1ccc(C2(c3ccc(O)cc3)c3ccccc3-c3cc4c(cc32)C(c2ccc(O)cc2)(c2ccc(O)cc2)c2ccccc2-4)cc1 ; Oc1ccc2cc(C3(c4ccc5cc(O)ccc5c4)c4ccccc4-c4cc5c(cc43)C(c3ccc4cc(O)ccc4c3)(c3ccc4cc(O)ccc4c3)c3ccccc3-5)ccc2c1 ; Oc1ccc(C2(c3ccc(O)cc3)c3ccccc3-c3ccccc32)cc1 ; CC(C)(c1ccccc1)c1ccc(O)cc1 ; Oc1ccc2c3c(cccc13)CC2 ; Oc1ccc(C2(c3ccc(O)cc3)c3ccccc3-c3ccc4c(c32)C(c2ccc(O)cc2)(c2ccc(O)cc2)c2ccccc2-4)cc1]

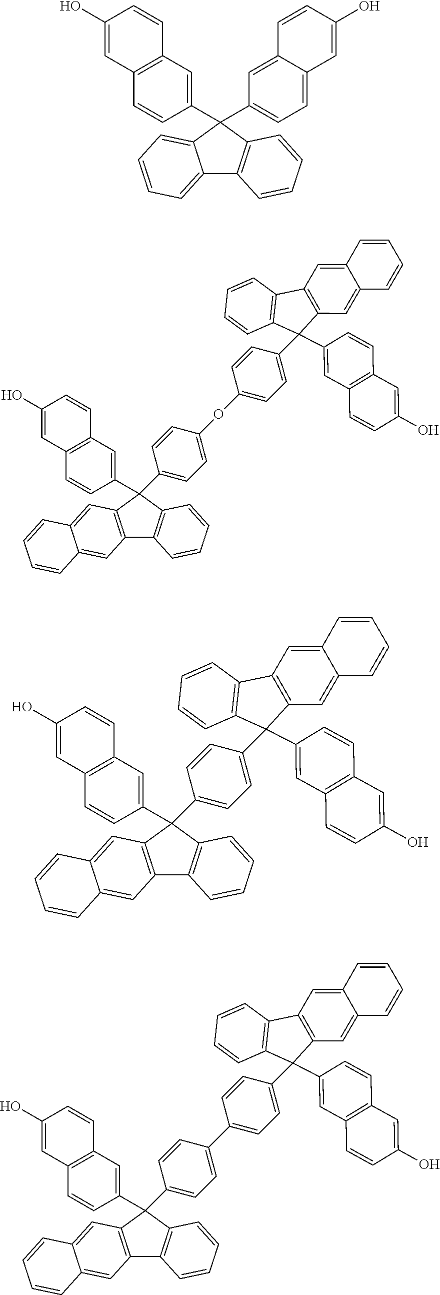 [SMILES: Oc1ccc2cc(C3(c4ccc5cc(O)ccc5c4)c4ccccc4-c4ccccc43)ccc2c1 ; Oc1ccc2cc(C3(c4ccc(Oc5ccc(C6(c7ccc8cc(O)ccc8c7)c7ccccc7-c7cc8ccccc8cc76)cc5)cc4)c4ccccc4-c4cc5ccccc5cc43)ccc2c1 ; Oc1ccc2cc(C3(c4ccc(C5(c6ccc7cc(O)ccc7c6)c6ccccc6-c6cc7ccccc7cc65)cc4)c4ccccc4-c4cc5ccccc5cc43)ccc2c1 ; Oc1ccc2cc(C3(c4ccc(-c5ccc(C6(c7ccc8cc(O)ccc8c7)c7ccccc7-c7cc8ccccc8cc76)cc5)cc4)c4ccccc4-c4cc5ccccc5cc43)ccc2c1]

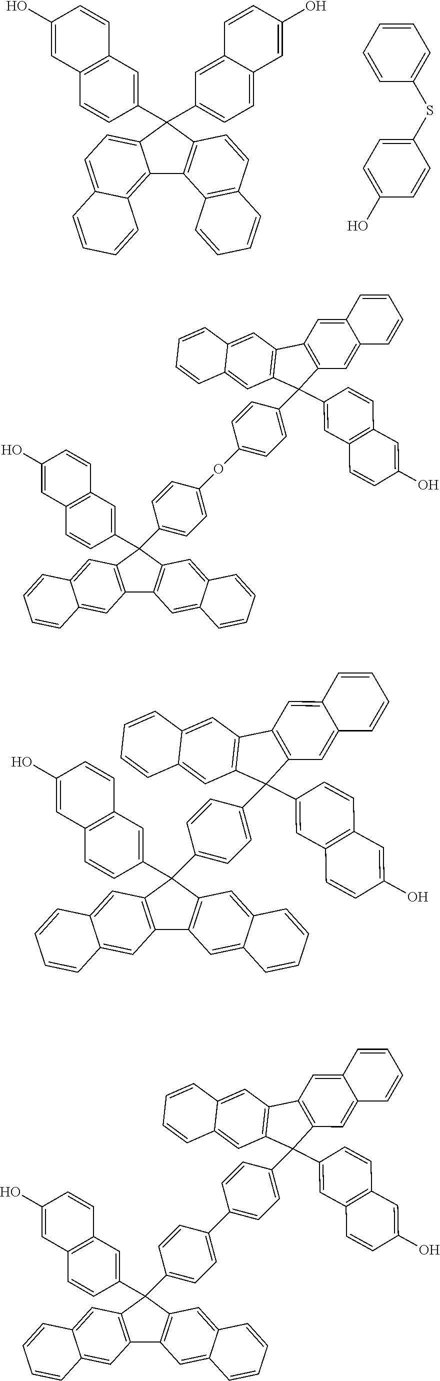 [SMILES: Oc1ccc2cc(C3(c4ccc5cc(O)ccc5c4)c4ccc5ccccc5c4-c4c3ccc3ccccc43)ccc2c1 ; Oc1ccc(Sc2ccccc2)cc1 ; Oc1ccc2cc(C3(c4ccc(Oc5ccc(C6(c7ccc8cc(O)ccc8c7)c7cc8ccccc8cc7-c7cc8ccccc8cc76)cc5)cc4)c4cc5ccccc5cc4-c4cc5ccccc5cc43)ccc2c1 ; Oc1ccc2cc(C3(c4ccc(C5(c6ccc7cc(O)ccc7c6)c6cc7ccccc7cc6-c6cc7ccccc7cc65)cc4)c4cc5ccccc5cc4-c4cc5ccccc5cc43)ccc2c1 ; Oc1ccc2cc(C3(c4ccc(-c5ccc(C6(c7ccc8cc(O)ccc8c7)c7cc8ccccc8cc7-c7cc8ccccc8cc76)cc5)cc4)c4cc5ccccc5cc4-c4cc5ccccc5cc43)ccc2c1]

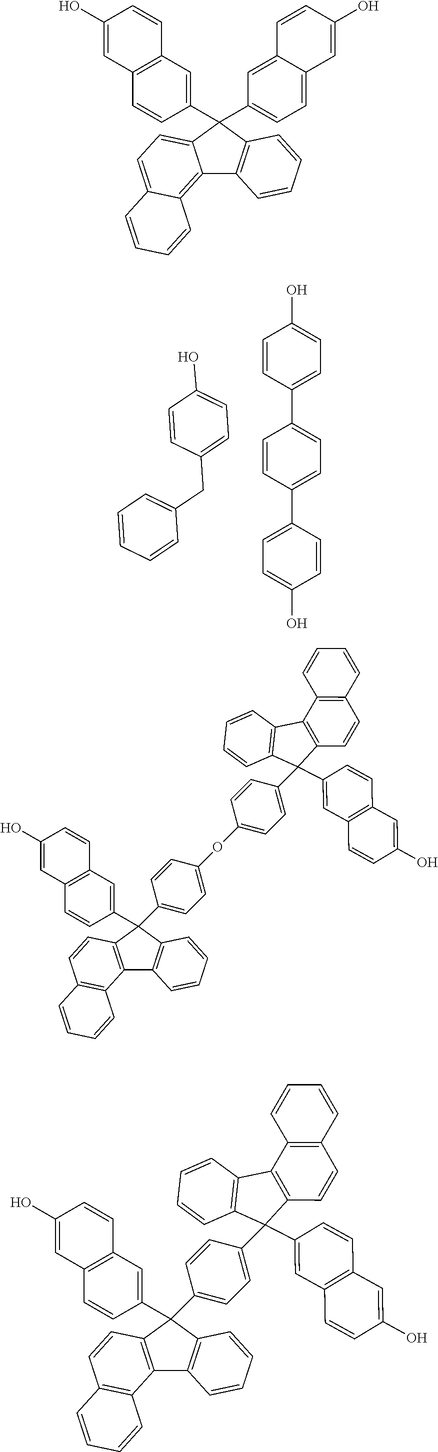

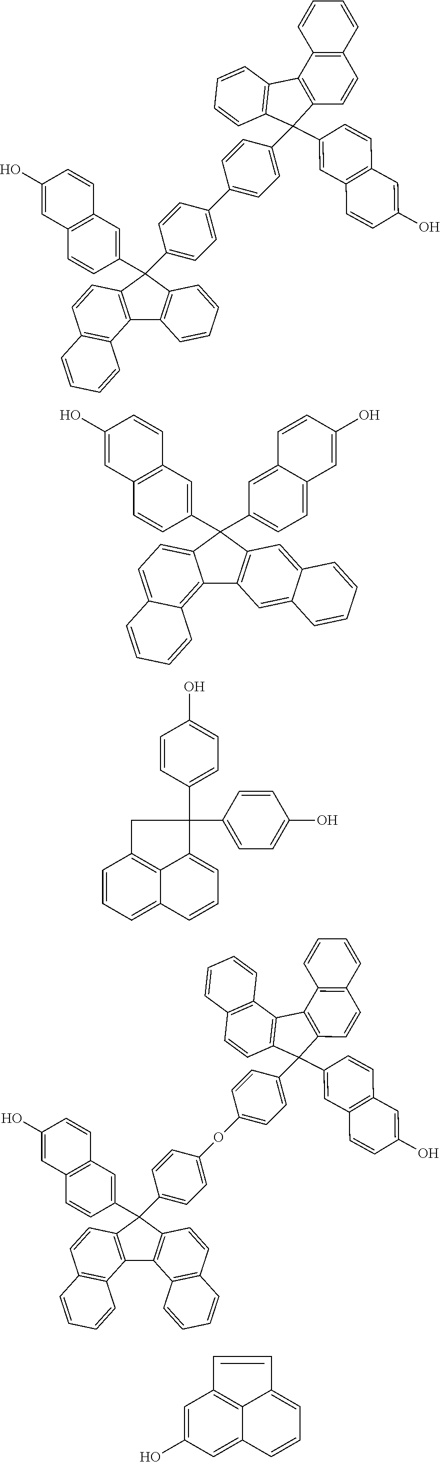

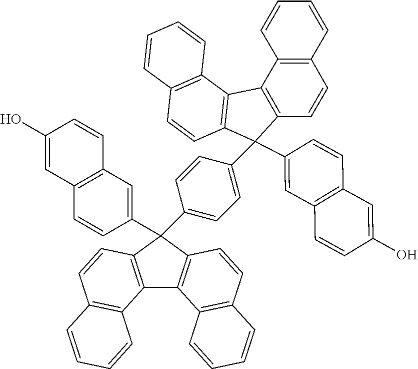 [SMILES: Oc1ccc2cc(C3(c4ccc(C5(c6ccc7cc(O)ccc7c6)c6ccc7ccccc7c6-c6c5ccc5ccccc65)cc4)c4ccc5ccccc5c4-c4c3ccc3ccccc43)ccc2c1]

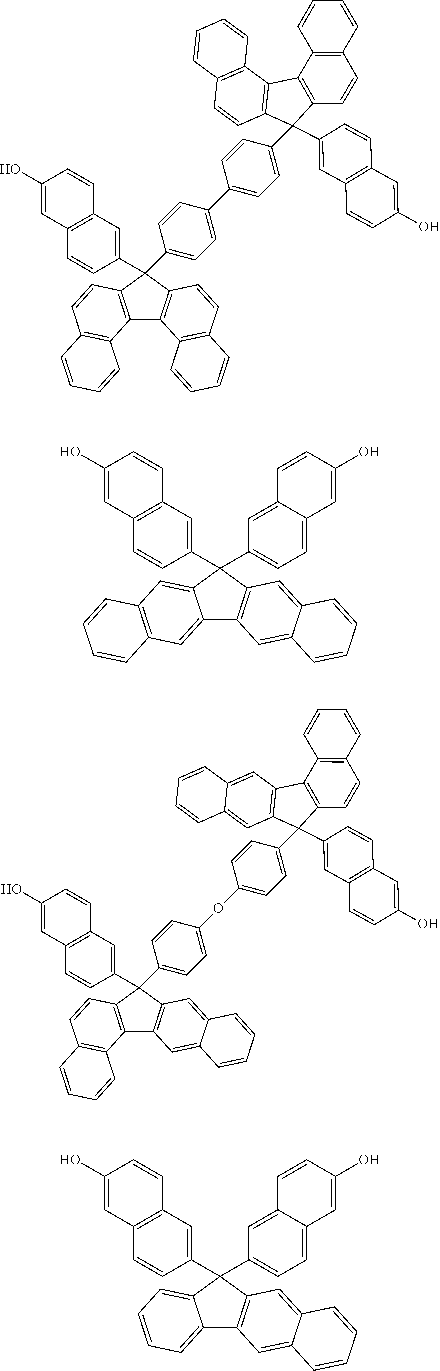 [SMILES: Oc1ccc2cc(C3(c4ccc(-c5ccc(C6(c7ccc8cc(O)ccc8c7)c7ccc8ccccc8c7-c7c6ccc6ccccc76)cc5)cc4)c4ccc5ccccc5c4-c4c3ccc3ccccc43)ccc2c1 ; Oc1ccc2cc(C3(c4ccc5cc(O)ccc5c4)c4cc5ccccc5cc4-c4cc5ccccc5cc43)ccc2c1 ; Oc1ccc2cc(C3(c4ccc(Oc5ccc(C6(c7ccc8cc(O)ccc8c7)c7cc8ccccc8cc7-c7c6ccc6ccccc76)cc5)cc4)c4cc5ccccc5cc4-c4c3ccc3ccccc43)ccc2c1 ; Oc1ccc2cc(C3(c4ccc5cc(O)ccc5c4)c4ccccc4-c4cc5ccccc5cc43)ccc2c1]

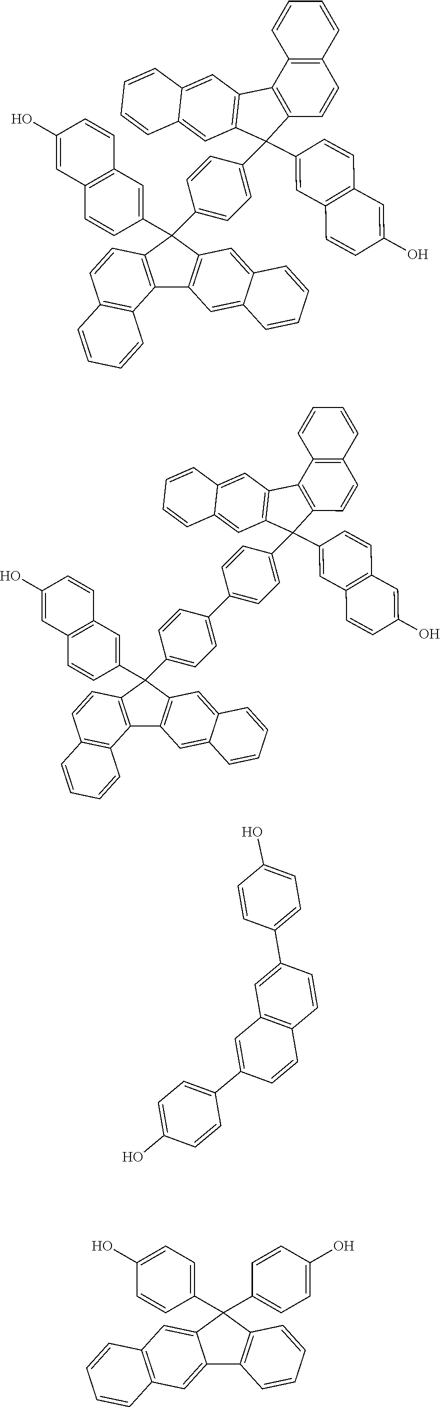 [SMILES: Oc1ccc2cc(C3(c4ccc(C5(c6ccc7cc(O)ccc7c6)c6cc7ccccc7cc6-c6c5ccc5ccccc65)cc4)c4cc5ccccc5cc4-c4c3ccc3ccccc43)ccc2c1 ; Oc1ccc2cc(C3(c4ccc(-c5ccc(C6(c7ccc8cc(O)ccc8c7)c7cc8ccccc8cc7-c7c6ccc6ccccc76)cc5)cc4)c4cc5ccccc5cc4-c4c3ccc3ccccc43)ccc2c1 ; Oc1ccc(-c2ccc3ccc(-c4ccc(O)cc4)cc3c2)cc1 ; Oc1ccc(C2(c3ccc(O)cc3)c3ccccc3-c3cc4ccccc4cc32)cc1]

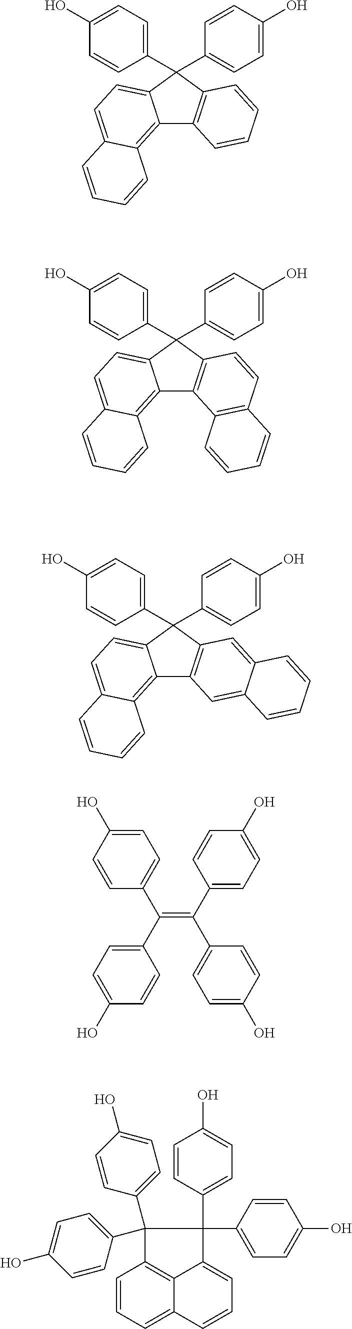 [SMILES: Oc1ccc(C2(c3ccc(O)cc3)c3ccccc3-c3c2ccc2ccccc32)cc1 ; Oc1ccc(C2(c3ccc(O)cc3)c3ccc4ccccc4c3-c3c2ccc2ccccc32)cc1 ; Oc1ccc(C2(c3ccc(O)cc3)c3cc4ccccc4cc3-c3c2ccc2ccccc32)cc1 ; Oc1ccc(C(=C(c2ccc(O)cc2)c2ccc(O)cc2)c2ccc(O)cc2)cc1 ; Oc1ccc(C2(c3ccc(O)cc3)c3cccc4cccc(c34)C2(c2ccc(O)cc2)c2ccc(O)cc2)cc1]

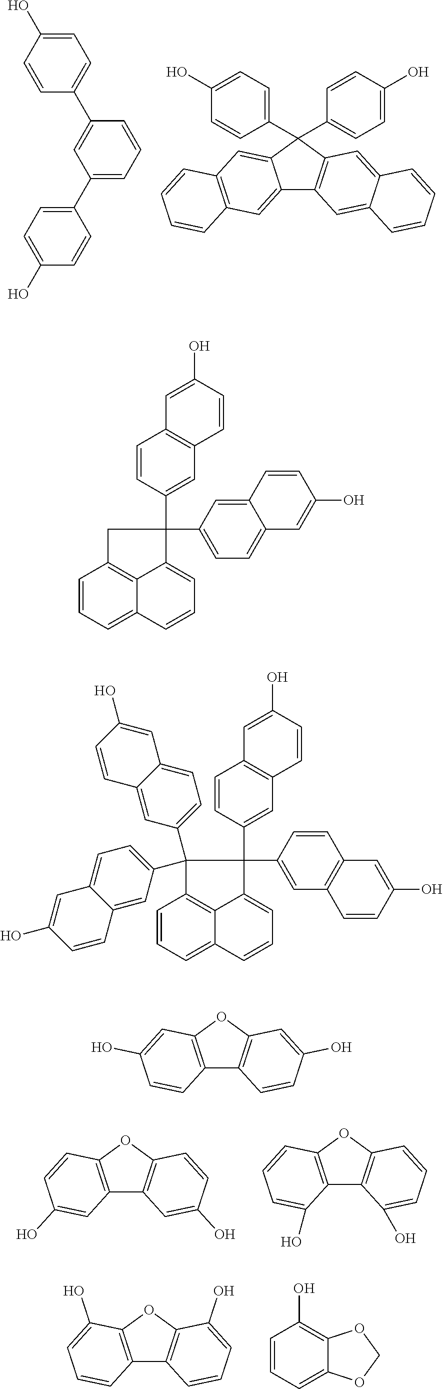

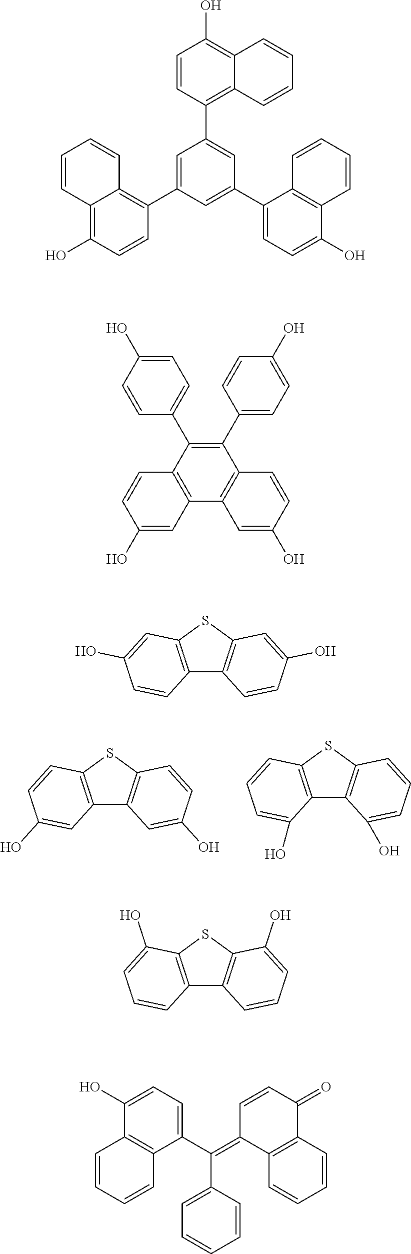

As for the repeating unit structure A having the phenol/phenoxy skeleton at least as a partial structure, typical unit structures with bonding sites will be shown below.

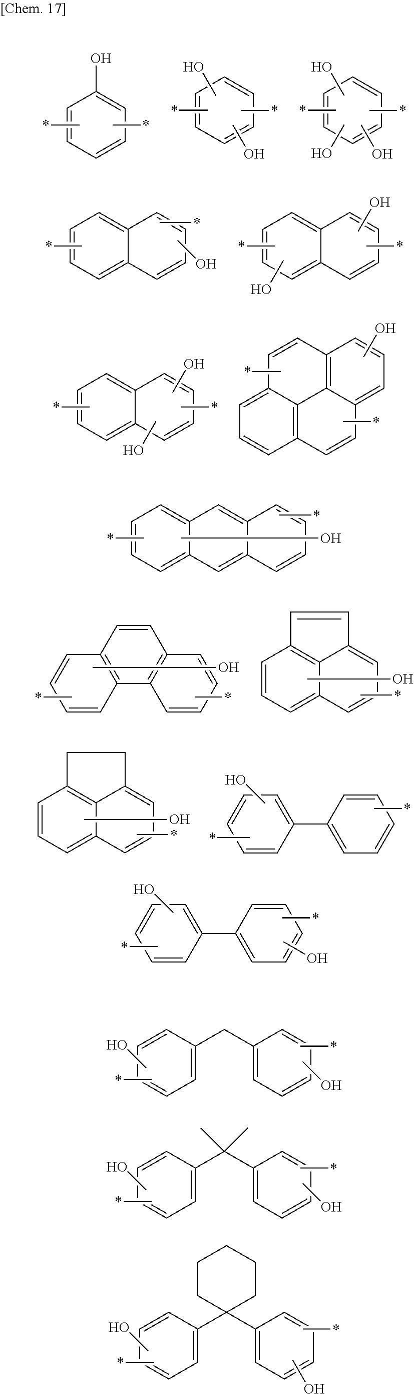

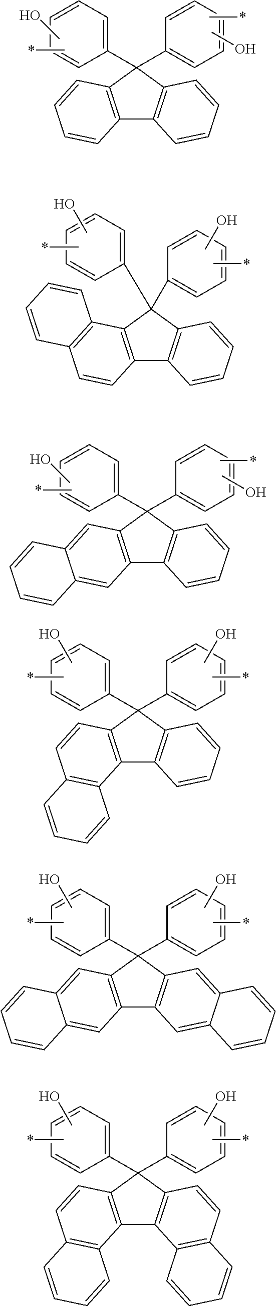

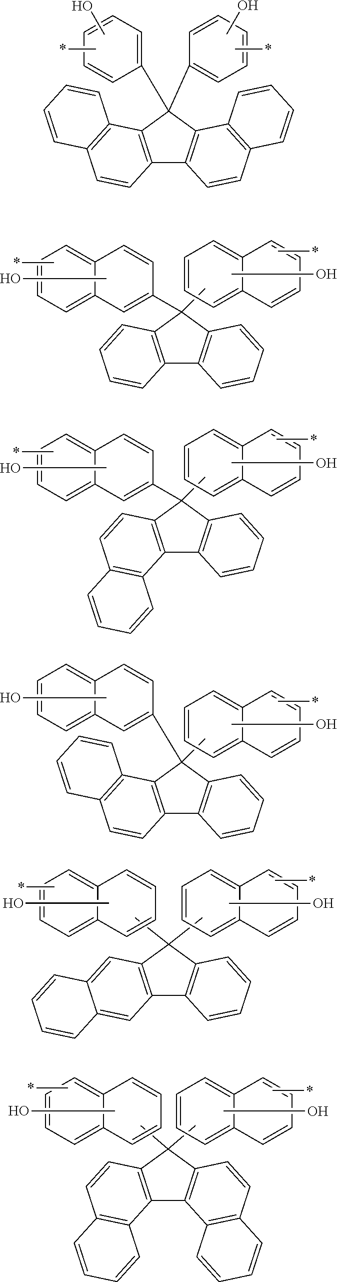

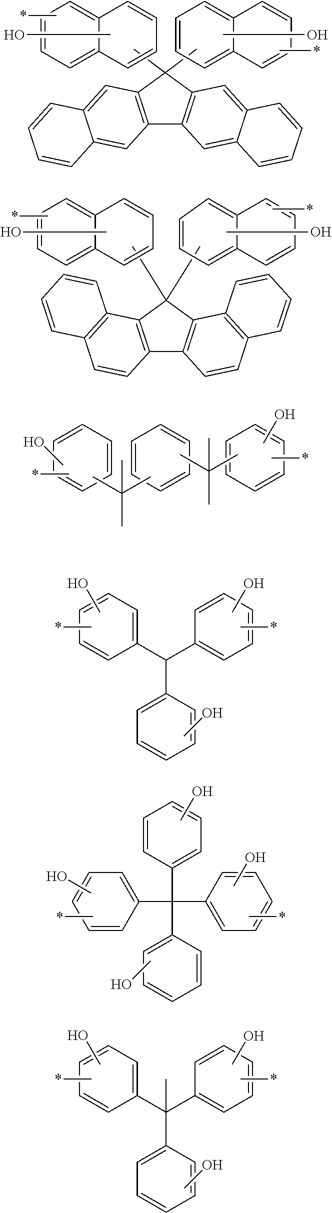

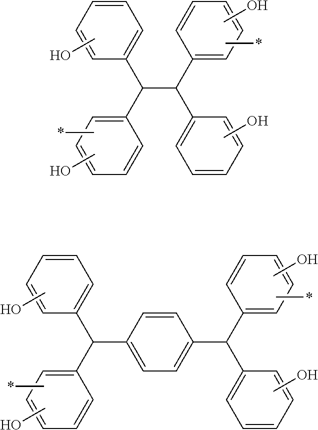

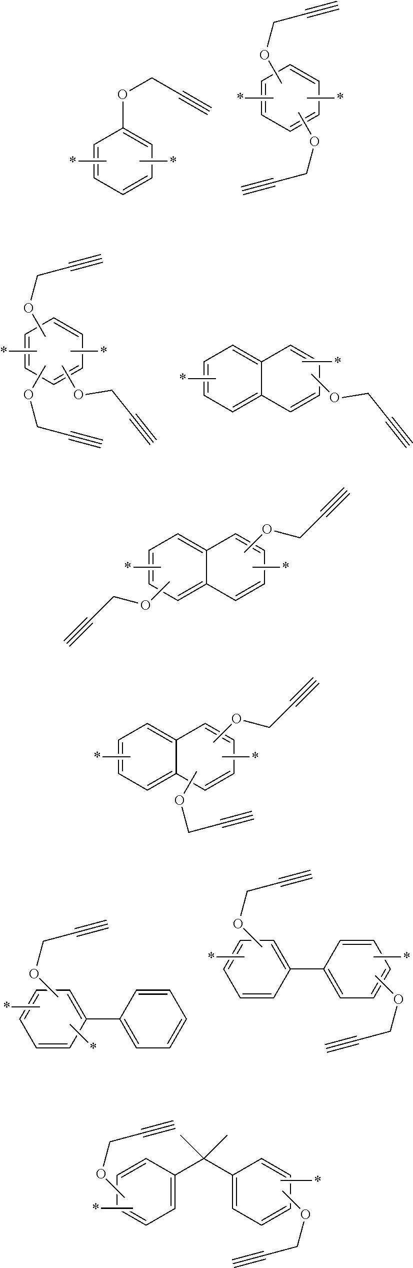

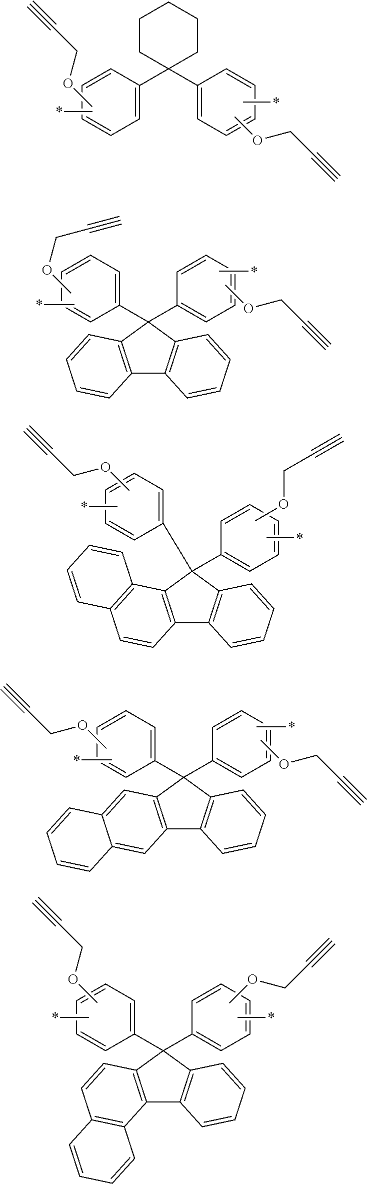

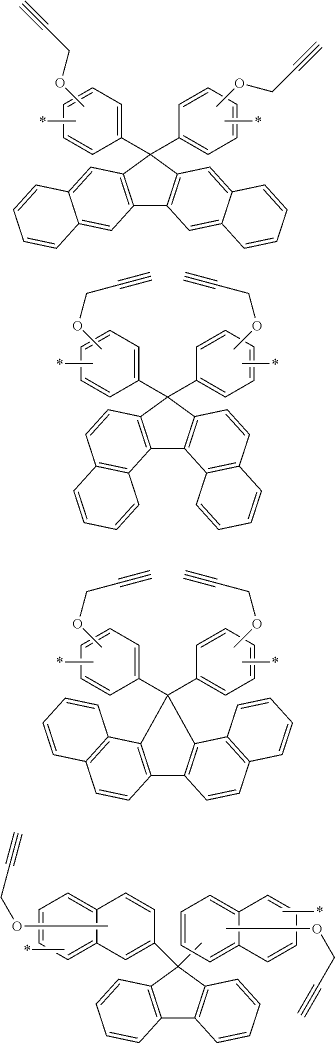

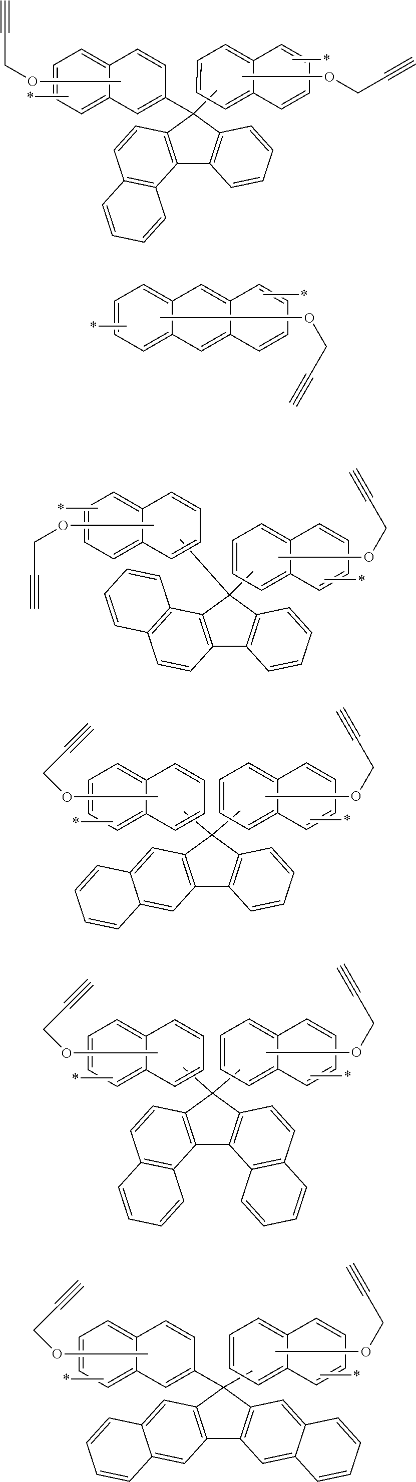

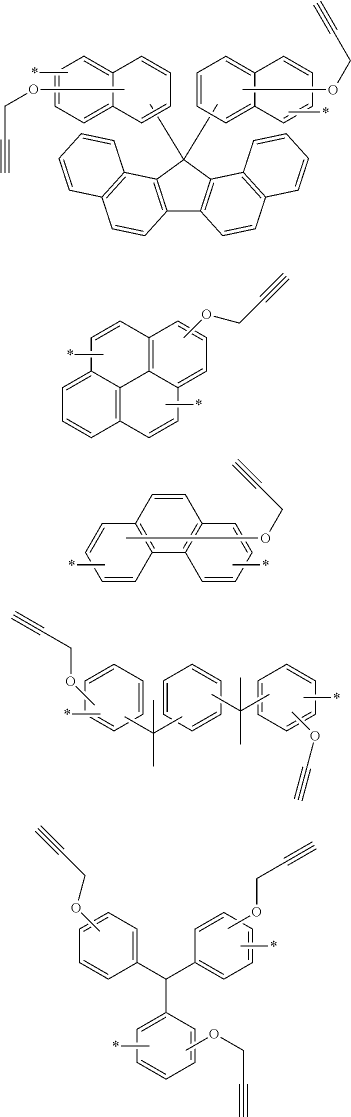

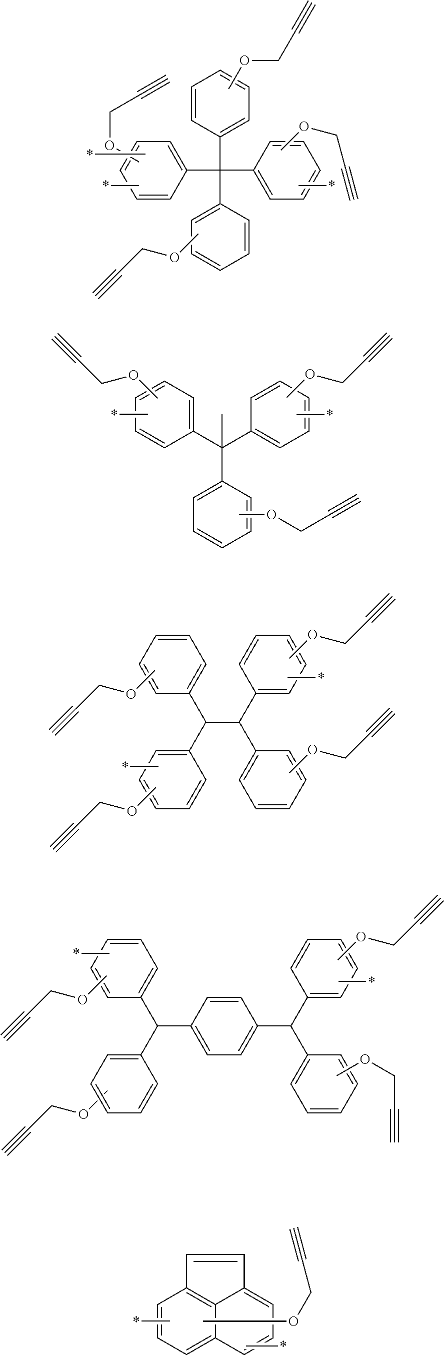

### (II-3) Other Unit Structure A

The unit structure A is the repeating unit structure in the novolac resin and derived from the compound having an aromatic ring. The novolac resin may have a unit structure A other than the unit structure having the carbazole skeleton or the phenol/phenoxy skeleton at least as a partial structure (hereinafter, which may be referred to as “other unit structure A”) as long as the effect of the coating composition for a nitrogen-atom-containing substrate of one aspect of the present invention is not impaired.

The aromatic ring in the other unit structure A preferably has 6 to 30, more preferably 6 to 24, carbon atoms.

The aromatic ring is preferably. one or more benzene rings, naphthalene rings, anthracene rings, or pyrene rings; or a condensed ring between a benzene ring, a naphthalene ring, an anthracene ring, a pyrene ring, or a biphenyl ring and a heteroring or an aliphatic ring (such as a fluorene ring, a benzofluorene ring, a dibenzofluorene ring, or an indole ring).

The aromatic ring may have optionally a substituent, and the substituent preferably has a heteroatom. In the aromatic ring, two or more aromatic rings may be linked via a linking group or linking groups, and the linking group preferably has a heteroatom. Examples of the heteroatom include an oxygen atom, a nitrogen atom, and a sulfur atom.

The “aromatic ring” is preferably an organic group having at least one heteroatom selected from N, S, and O on the ring, in the ring, or between the rings, and having 6 to 30 or 6 to 24 carbon atoms.

As the heteroatom included on the ring, the description in the (II-2-7) may be incorporated by reference unless the resulting unit structure corresponds to a unit structure having the carbazole skeleton or the phenol/phenoxy skeleton at least as a partial structure. Examples the heteroatom include: a nitrogen atom included in an amino group (for example, a propargylamino group), a cyano group, or the like; an oxygen atom included in a formyl group, a carboxyl group, or the like, which are an oxygen-containing substituent; and a nitrogen atom and an oxygen atom included in a nitro group, which is an oxygen-containing substituent and also a nitrogen-containing substituent. Examples of the heteroatom included in the ring include an oxygen atom included in xanthene.

Examples of the heteroatom included in the linking group between two or more aromatic rings include a nitrogen atom, an oxygen atom, and a sulfur atom included in an —NH— bond, an —NHCO— bond, an —O— bond, a —COO— bond, a —CO— bond, an —S— bond, an —SS-bond, an —SO₂— bond, and the like. The other unit structure A is preferably a unit structure having an aromatic ring having the aforementioned oxygen-containing substituent, a unit structure having two or more aromatic rings linked via —NH—, or a unit structure having a condensed ring between one or more aromatic hydrocarbon rings and one or more heterorings.

Examples of the skeleton used in the other unit structure A include the following skeletons.

### Examples of Other Unit Structure A Derived from Heteroring

Note that —NH— may be a structure in which a hydrogen atom on N thereof is replaced.

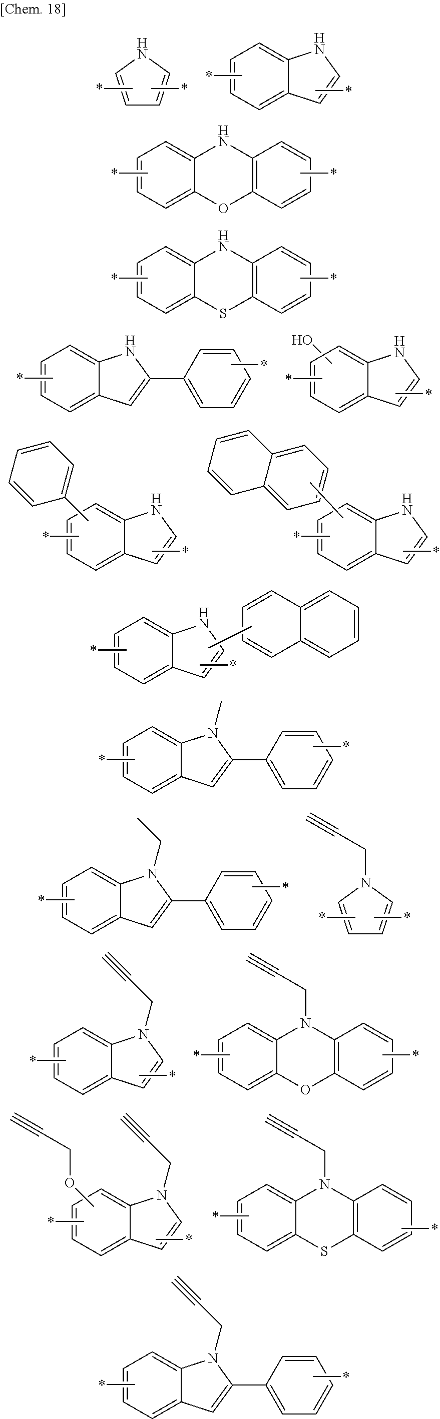

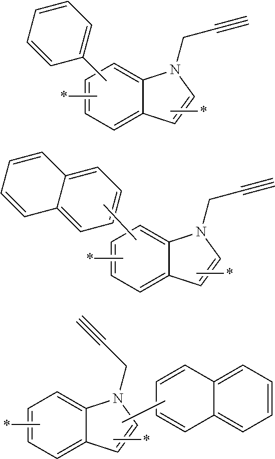

### Examples of Other Unit Structure A of Aromatic Hydrocarbon Linked with —NH—

Note that —NH— may be a structure in which a hydrogen atom on N thereof is replaced.

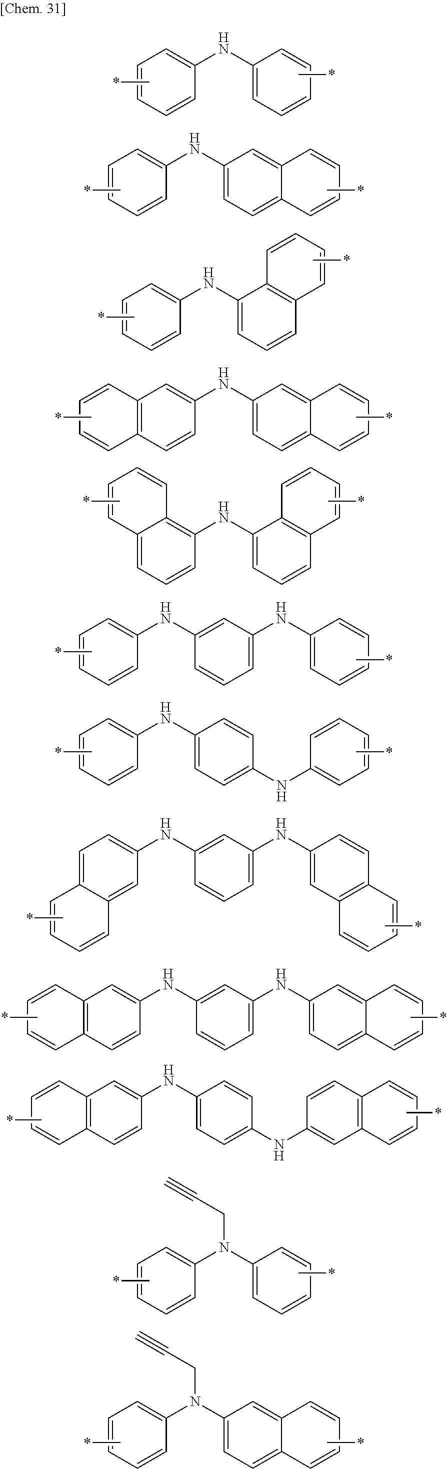

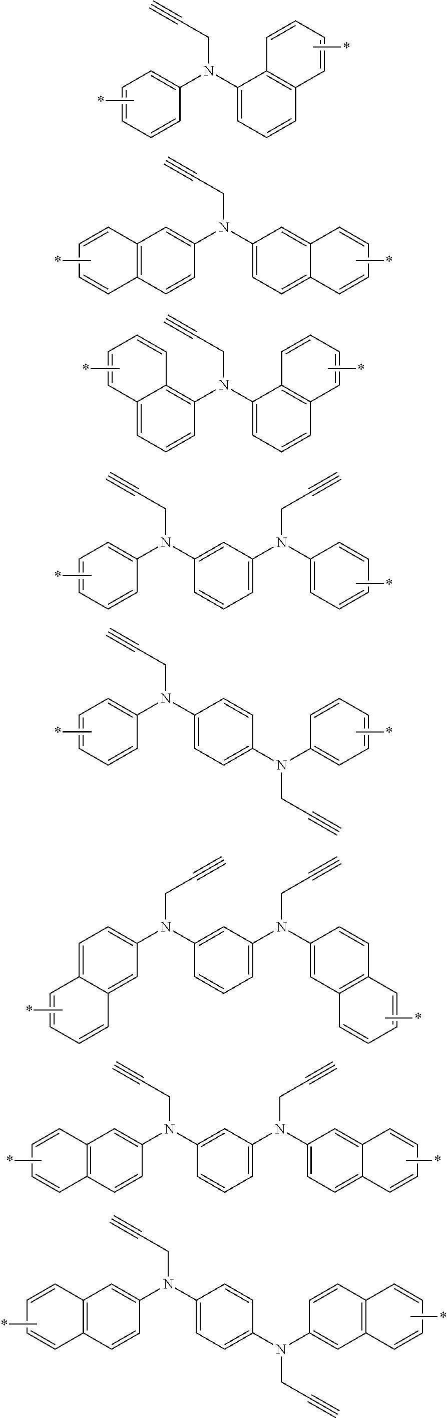

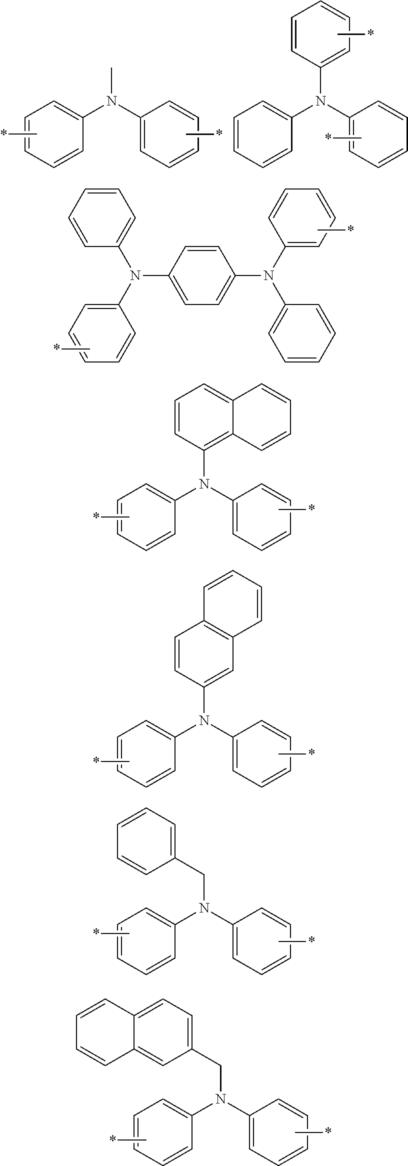

### (Others)

H of NH in the examples of the other unit structure A derived from the heteroring and H of NH in the examples of the other unit structure A of the aromatic hydrocarbon linked with —NH— may be substituted with another substituent, for example, the substituent exemplified in the (II-2-2).

### (II-4) Novolac Resin

The novolac resin preferably has a composite unit structure A-B represented by the following formula (AB):

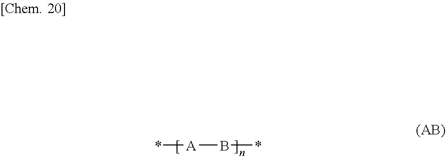

in the formula (AB), “n” represents the number of composite unit structures A-B, and a unit structure A represents the repeating unit structure A having the carbazole skeleton or the phenol/phenoxy skeleton at least as a partial structure, which has been described in the (II-2) to (II-3).

### (II-4-1) Unit Structure B

The unit structure B is one or more types of unit structure having a linkage carbon atom bonded to the aromatic ring in the unit structure A [see the (I-1)], and preferably has a structure represented by the formula (B1), (B2), or (B3) described later in (II-4-2) to (II-4-4). The unit structure B can link the two unit structures A via covalent bonds each to a carbon atom on the aromatic ring in the unit structure A.

At least one of the composite unit structures A-B may be replaced with one or more types of unit structure C, which is one unit structure equivalent thereto and has a structure represented by formulae (C1), (C2), and (C3) described in (II-4-2-3), (II-4-3-2), and (II-4-4-3) respectively later.

### (II-4-2) Formula (B1)

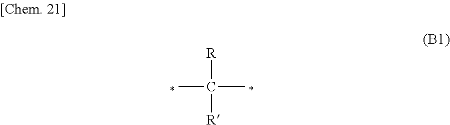

In the formula (B1),

R and R′ each independently represent: a hydrogen atom, an aromatic ring residue having 6 to 30 carbon atoms and optionally having a substituent; a heteroring residue having 3 to 30 carbon atoms and optionally having a substituent; a linear, branched, or cyclic alkyl group having 10 or less carbon atoms and optionally having a substituent; or a formyl group.

Two bonding sites in the formula (B1) each can be covalently bonded to the aromatic ring in the unit structure A.

### (II-4-2-1)

For “aromatic ring” and “heteroring” in the definitions of R and R′ in the formula (B1), the (I-3) and (I-4) may be referred to.

In the definitions of R and R′ in the formula (B1), examples of the “alkyl group” include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group, an n-heptyl group, an n-octyl group, an n-nonyl group, and an n-decyl group.

R and R′ each independently preferably represent phenyl, naphthalenyl, anthracenyl, phenanthrenyl, naphthacenyl, or pyrenyl.

### (II-4-2-2)

The unit structure having the structure represented by the formula (B1) may have, for example, a structure in which two or three of the structures of the formula (B1) that are the same or different from each other are bonded to a divalent or trivalent linking group to form a dimer or trimer structure. In this case, one of the two bonding sites in each structure of the formula (B1) is bonded to the linking group, as shown in the following formula (B11).

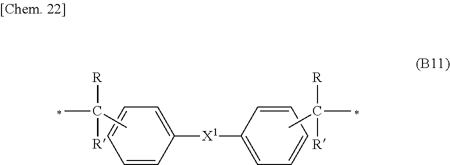

Examples of the linking group include a linking group having two or three aromatic rings (corresponding to the unit structure A). Specific examples of the divalent or trivalent linking group include: the following divalent linking group (L1), which is exemplified in the formula (B11):

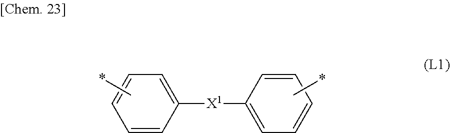

wherein X¹ represents a single bond, a methylene group, an oxygen atom, a sulfur atom, or —N(R⁵)—, and R⁵ represents a hydrogen atom or a hydrocarbon group having 1 to 20 carbon atoms, which encompasses a chain hydrocarbon and a cyclic hydrocarbon that may be an aromatic or non-aromatic.

Other examples include a divalent or trivalent linking group of the following formulae (L2) and (L3):

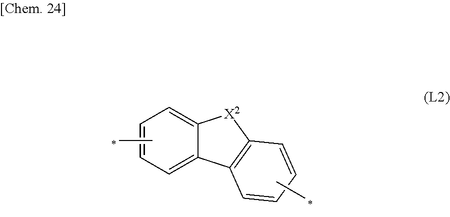

wherein X² represents a methylene group, an oxygen atom, or —N(R⁶)—, R⁶ represents a hydrogen atom, an aliphatic hydrocarbon group having 1 to 10 carbon atoms, or an aromatic hydrocarbon group having 5 to 20 carbon atoms; and

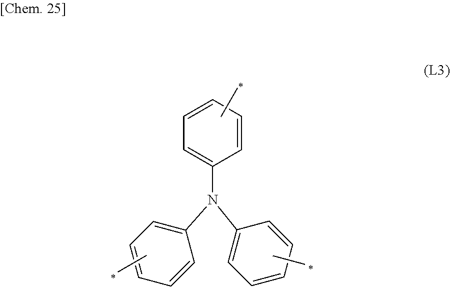

Still another example is a divalent linking group as of the following formula (L4), which can form a covalent bond to a linkage carbon atom through an addition reaction between an acetylide and a ketone.

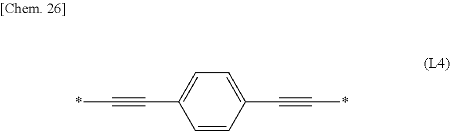 [SMILES: *C#Cc1ccc(C#C*)cc1]

### (II-4-2-3)

When at least one of R and R′ in the formula (B1) represents an aromatic ring residue, the aromatic ring [see Ar in the following formula (B12), for example] may be additionally bonded to another unit structure B.

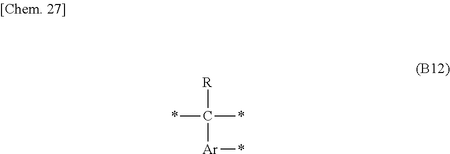

In this case, as in the following formula (C1):

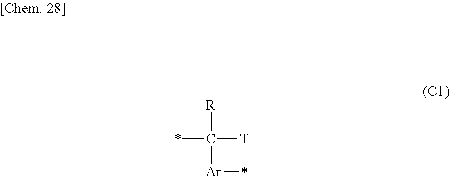

when one bonding site of the linkage carbon atom is bonded to a polymer terminal T (such as a hydrogen atom; various functional groups such as a hydroxy group and an unsaturated aliphatic hydrocarbon group; a terminal unit structure A; and the unit structure A in another polymer chain), the structure may be considered a unit structure C equivalent to the composite unit structure A-B and can replace at least one composite unit structure A-B. Specifically, the polymer chain may be extended by bonding between the aromatic ring in the formula (C1) [Ar in the formula (C1)] and the other unit structure B and also by bonding to the aromatic ring in the unit structure A via a bonding site from the remaining linkage carbon atom shown in the formula (C1).

### (II-4-2-4)

Some specific examples of the unit structure B having the structure represented by the formula (B1) include the followings. “*” basically represents a bonding site to the unit structure A. Needless to say, the unit structure may be a structure having the exemplified structure as a part of the entirety.

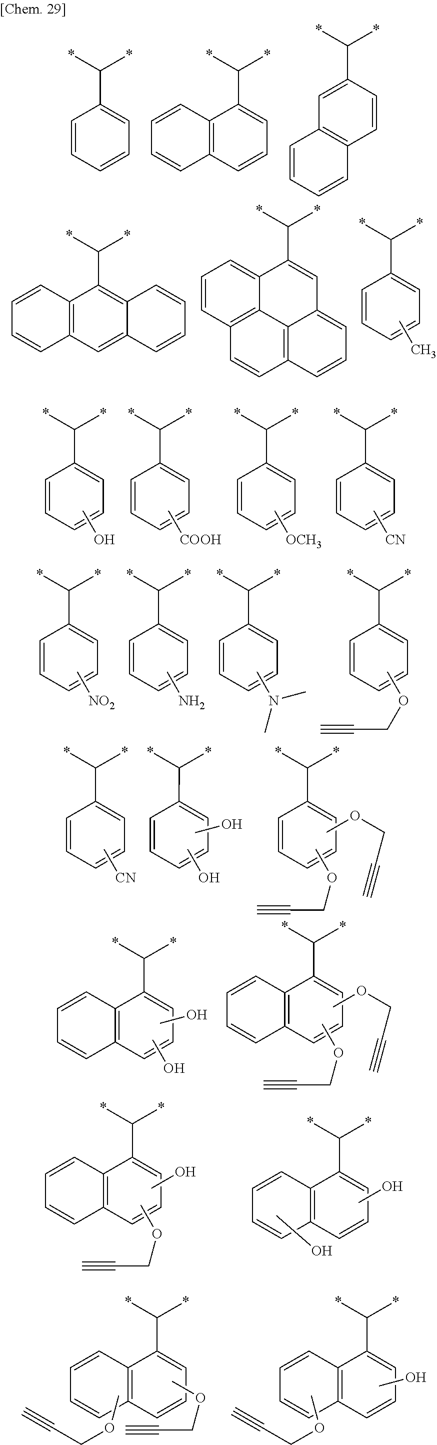

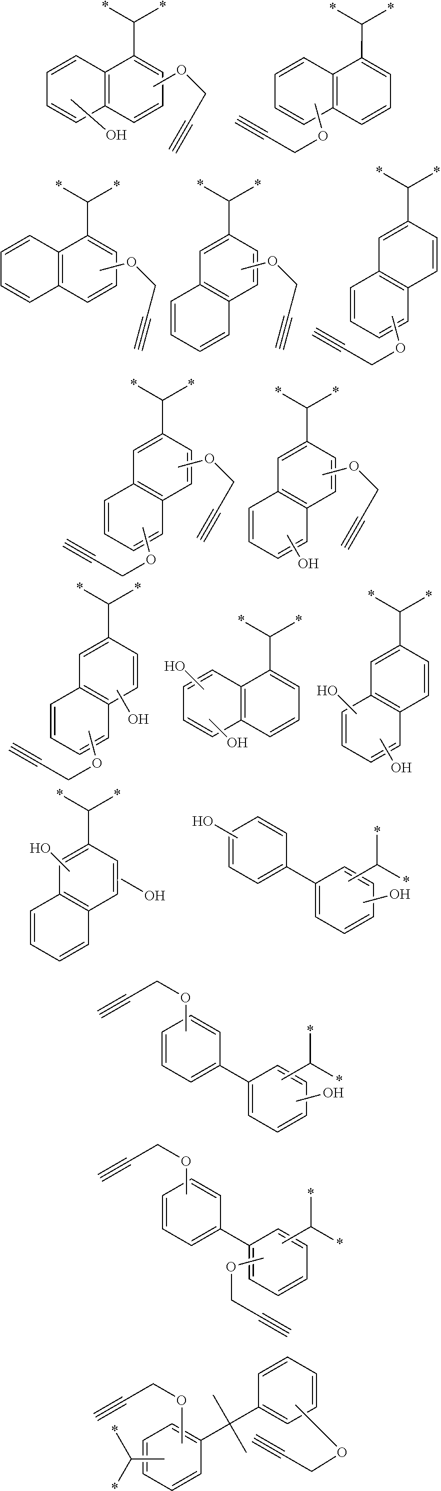

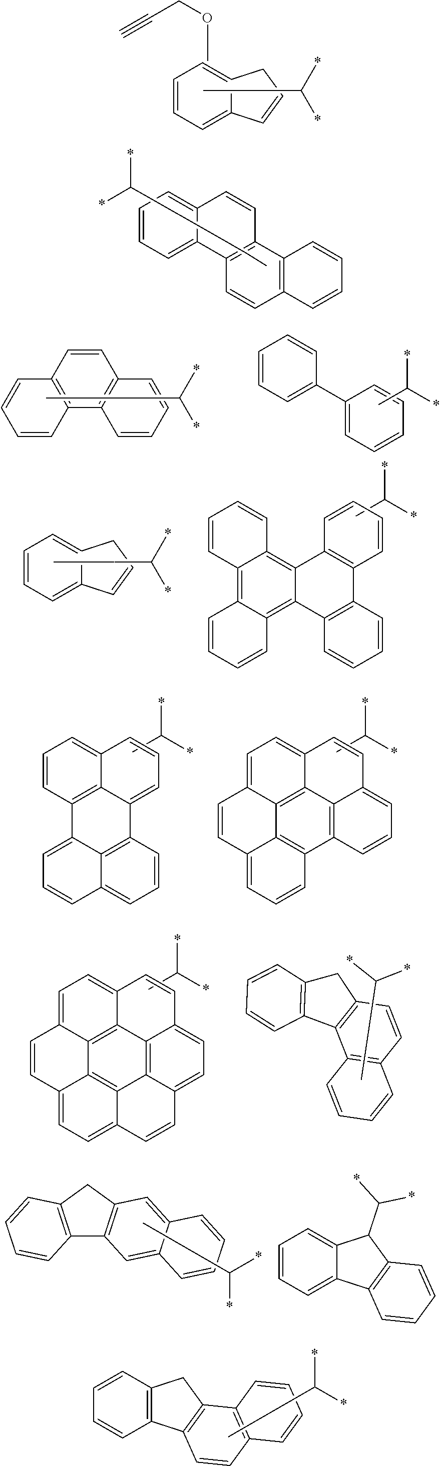

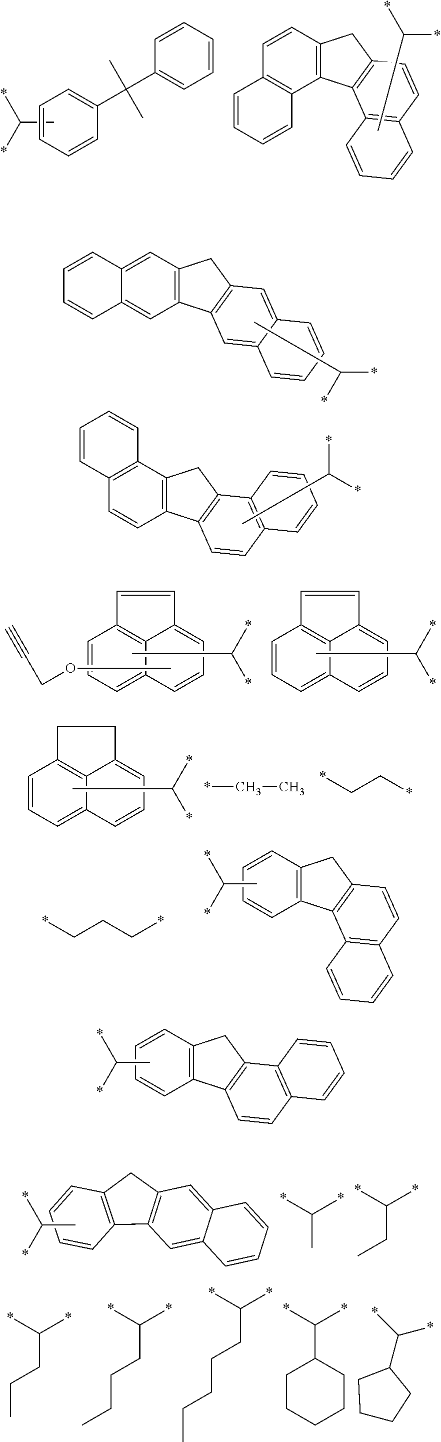

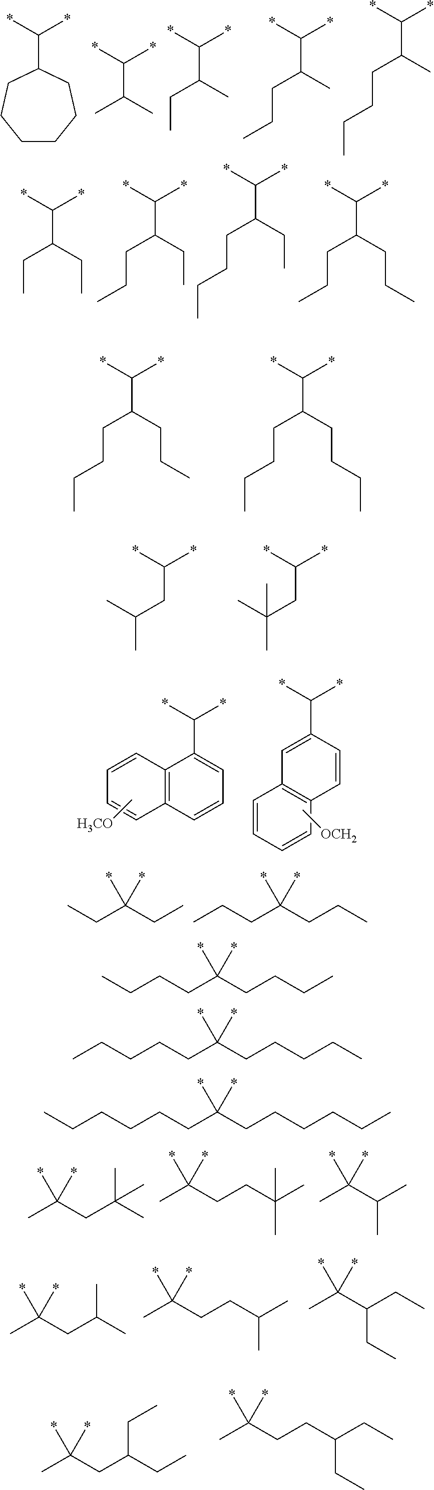

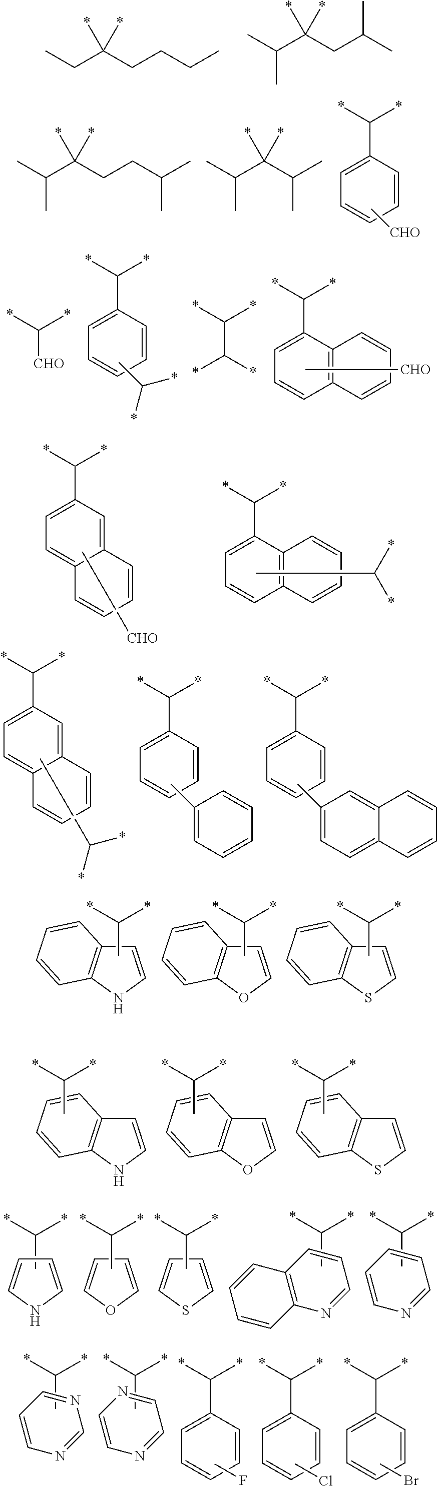

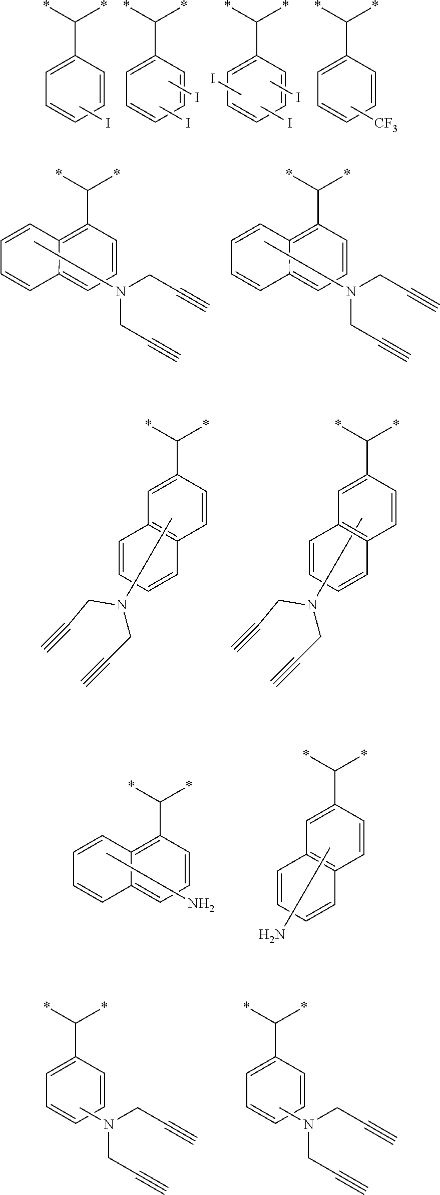

### (II-4-3) Formula (B32)

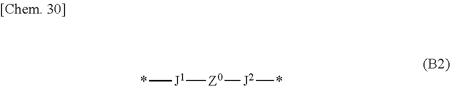

In the formula (B32),

Z⁰ represents an aromatic ring residue or an aliphatic ring residue having 6 to 30 carbon atoms and optionally having a substituent; or an organic group in which two aromatic ring residues or aliphatic ring residues are linked via a single bond. Examples of the organic group in which two aromatic ring residues or aliphatic ring residues are linked via a single bond include a divalent residue such as biphenyl, cyclohexylphenyl, and bicyclohexyl.

J¹ and J² each independently represent a direct bond or a divalent organic group optionally having a substituent. The divalent organic group is preferably a linear or branched alkylene group having 1 to 6 carbon atoms and optionally substituted with a hydroxyl group, an aryl group (such as a phenyl group and a substituted phenyl group), or a halo group (for example, fluorine), as a substituent. Examples of the linear alkylene group include a methylene group, an ethylene group, a propylene group, a butylene group, a pentylene group, and a hexylene group.

### (II-4-3-1)

The unit structure having the structure represented by the formula (B32) may have a structure in which two or three of the structures of the formula (B2) that are the same or different from each other are bonded to a divalent or trivalent linking group to form a dimer or trimer structure, as with the (II-4-2-2) about the formula (B1).

### (II-4-3-2)

Since the formula (B2) encompasses an aspect having an aromatic ring [Z⁰ in the formula (B2)], the aromatic ring [for example, an aromatic ring in Z⁰_{Ar} in the following formula (B21)] may be additionally bonded to another unit structure B [a vertical bonding site in the formula (B21)], as with (II-4-2-3) of the formula (B1).

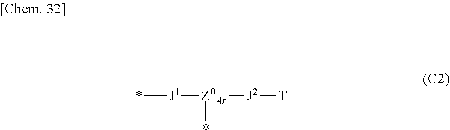

In the formula (B21),

Z⁰_{Ar} represents an aromatic ring residue having 6 to 30 carbon atoms and optionally having a substituent; or an organic group in which two aromatic ring residues or aliphatic ring residues are linked via a single bond, and is an organic group having at least one aromatic ring; and a bonding site extending downward from Z⁰_{Ar} extends from an aromatic ring in Z⁰_{Ar}, and
J¹ and J² have the same definitions as in the formula (B2).

In this case, as in the following (C2):

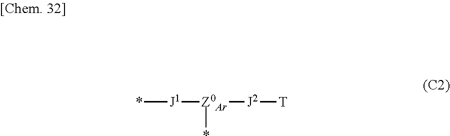

in the formula (C2),
Z⁰_{Ar}, J¹, and J² have the same definitions as in the formula (B21), and
T represents a polymer terminal,
when one bonding site of the linkage carbon atom is bonded to the polymer terminal T (such as a hydrogen atom; various functional groups such as a hydroxy group and an unsaturated aliphatic hydrocarbon group; a terminal unit structure A; and the unit structure A in another polymer chain), the structure may be considered a unit structure C equivalent to the composite unit structure A-B and can replace at least one composite unit structure A-B. Specifically, the polymer chain may be extended by bonding between the aromatic ring in the formula (C2) [the aromatic ring in Z⁰_{Ar} in the formula (C2)] and the other unit structure B and also by bonding to the aromatic ring in the unit structure A via a bonding site from the remaining linkage carbon atom shown in the formula (C2).

### (II-4-3-3)

Some specific examples of the unit structure having the structure represented by the formula (B2) include the followings. “*” represents a bonding site to the unit structure A. Needless to say, the unit structure may be a unit structure having the exemplified structure as a part of the entirety.

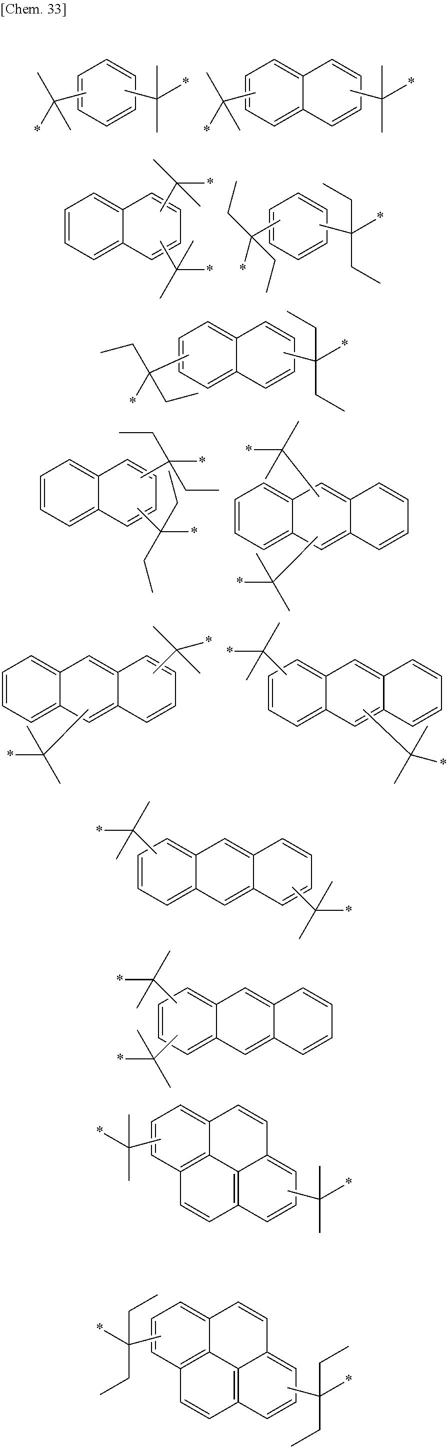

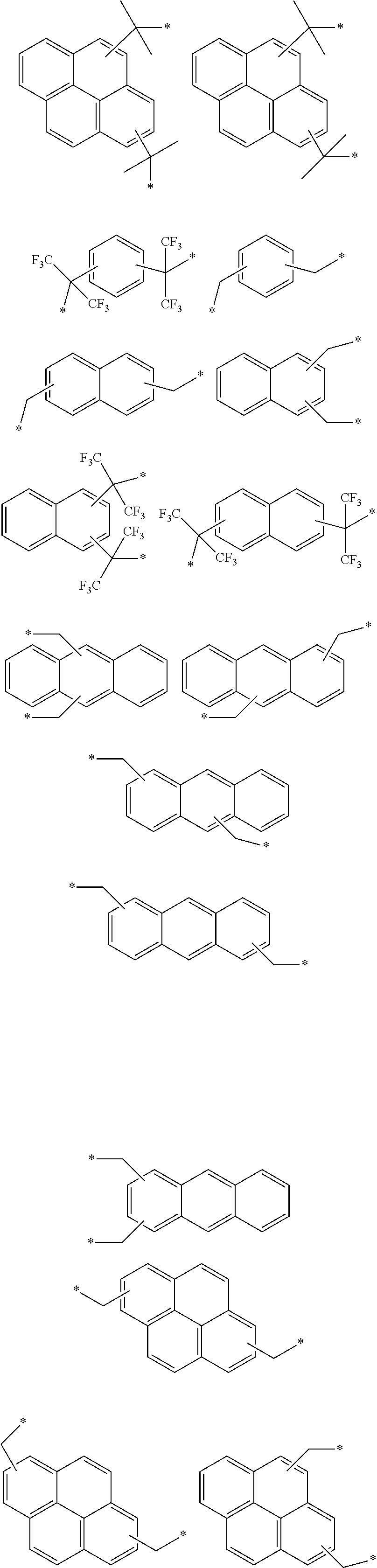

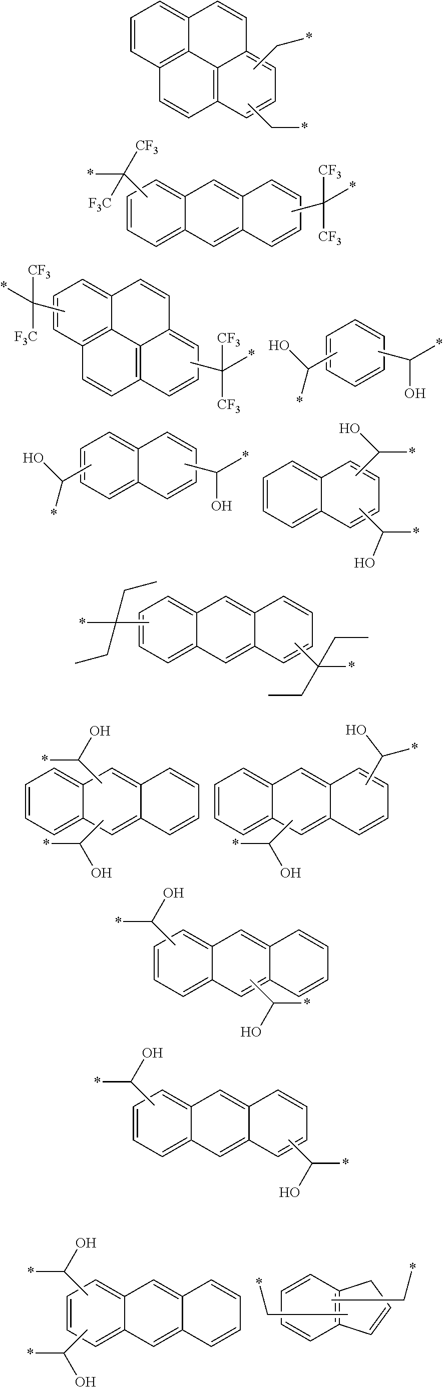

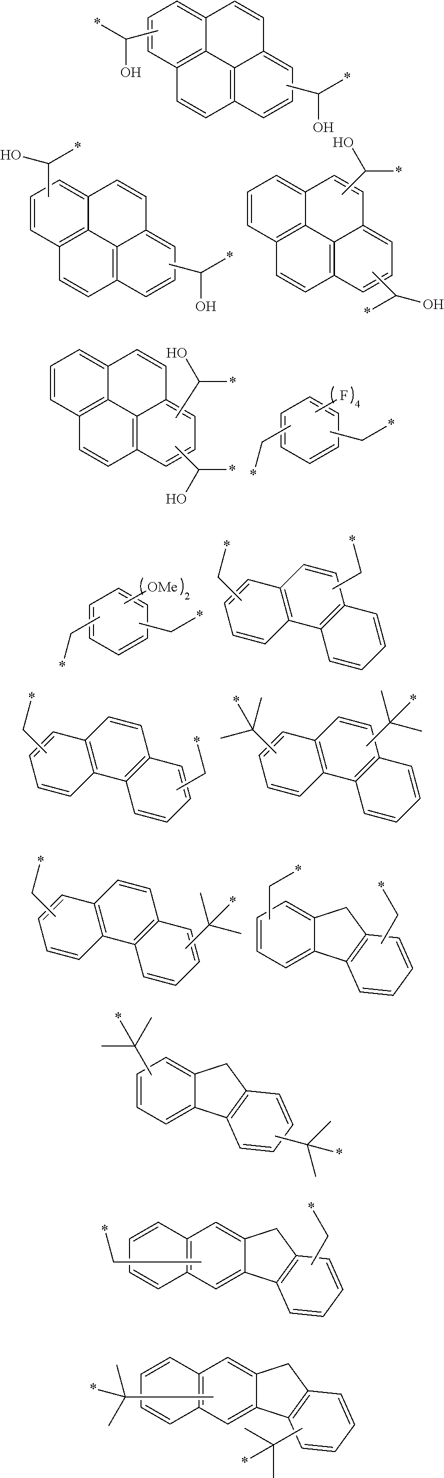

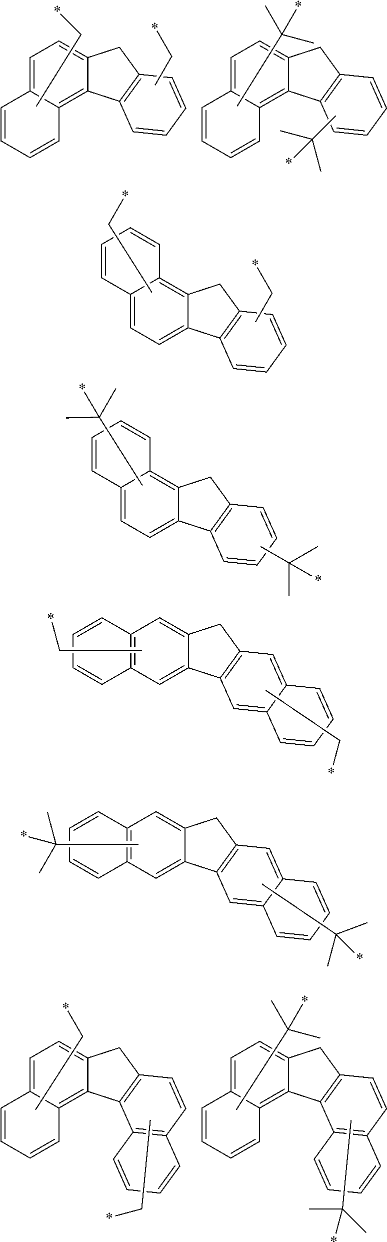

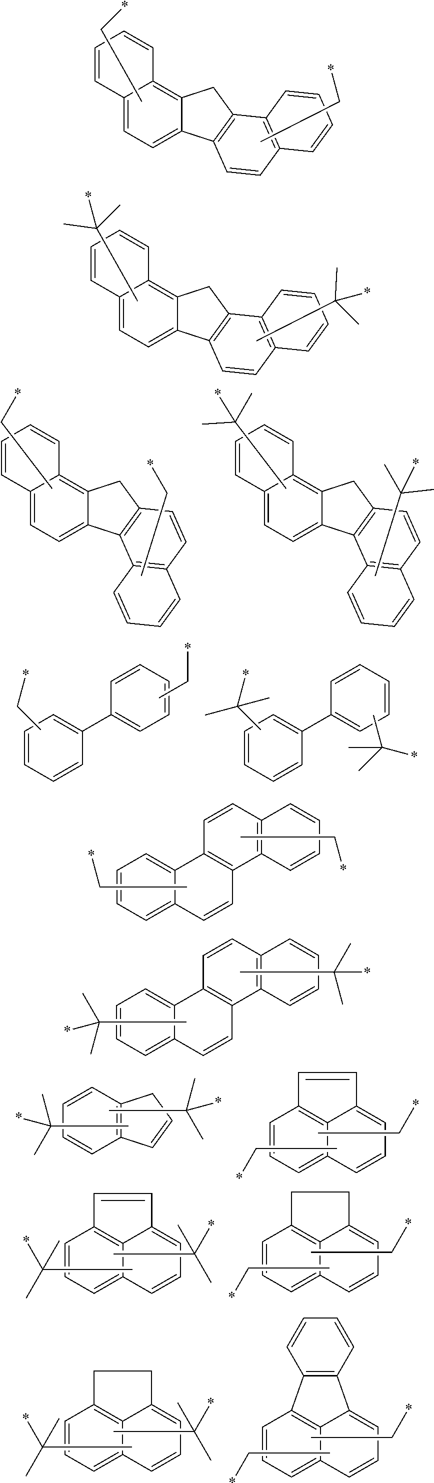

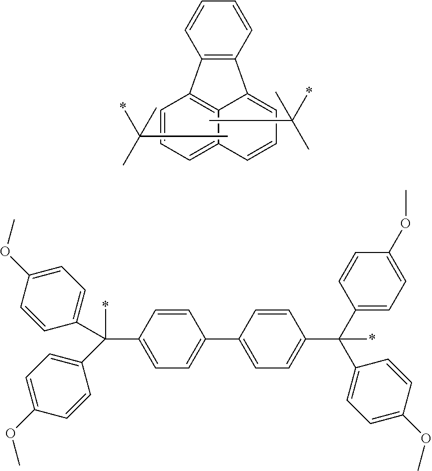

### (II-4-4) Formula (B3),

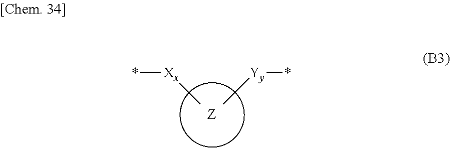

In the formula (B3),

Z represents a single ring or a bicyclic, tricyclic, or tetracyclic condensed ring having 4 to 25 carbon atoms and optionally having a substituent. The number of carbon atoms here means only the number of carbon atoms constituting a cyclic skeleton of the single ring or the bicyclic, tricyclic, or tetracyclic condensed ring excluding the substituent, and when the single ring or the condensed ring is a heteroring, the number of carbon atoms does not include the number of heteroatoms constituting the heteroring.

The single ring is a non-aromatic single ring; at least one single ring constituting the bicyclic, tricyclic, or tetracyclic ring is a non-aromatic single ring, and the other single ring(s) may be an aromatic single ring or a non-aromatic single ring.

The single ring or the bicyclic, tricyclic, or tetracyclic condensed ring may further form a condensed ring with one or more aromatic rings, and specifically form a penta- or higher-cyclic condensed ring. The number of carbon atoms in the penta- or higher-cyclic condensed ring is preferably 40 or less. The number of carbon atoms here means only the number of carbon atoms constituting a cyclic skeleton of the penta- or higher-cyclic condensed ring excluding a substituent, and when the penta- or higher-cyclic condensed ring is a heteroring, the number of carbon atoms does not include the number of heteroatoms constituting the heteroring.

X and Y are the same or different from each other and represent a —CR³¹R³²—group, and R³¹ and R³² are the same or different from each other and represent a hydrogen atom or a hydrocarbon group having 1 to 6 carbon atoms. The hydrocarbon group is preferably a linear, branched, or cyclic aliphatic hydrocarbon group.

“x” and “y” represent the numbers of X and Y, respectively, and each independently represent 0 or 1,

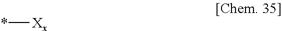

is bonded to any one carbon atom of the non-aromatic single ring of Z (when x=1), which is referred to as a “carbon atom 1”, or extends from the carbon atom 1 (when x=0),

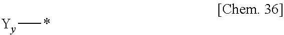

is bonded to any one carbon atom of the non-aromatic single ring of Z (when y=1), which is referred to as a “carbon atom 2”, or extends from the carbon atom 2 (when y=0), and
the carbon atom 1 and the carbon atom 2 may be identical or different from each other, and when the carbon atom 1 and the carbon atom 2 are different, the carbon atom 1 and the carbon atom 2 may be contained in an identical non-aromatic single ring or may be contained in different non-aromatic single rings.

In the formula (B3), another linkage carbon atom is optionally contained in addition to the carbon atom 1 and the carbon atom 2 [see (II-4-4-2), described later].

When Z represents a tri- or higher-cyclic condensed ring, the sequential positional relationship between one or two non-aromatic single rings in which the carbon atoms 1 and 2 are each contained and the remaining single rings in the condensed ring in the formula (B3) may be arbitrary. When the carbon atom 1 and the carbon atom 2 are each contained in different non-aromatic single rings (referred to as “non-aromatic single ring 1” and “non-aromatic single ring 2” respectively), a sequential positional relationship between the non-aromatic single ring 1 and the non-aromatic single ring 2 in the condensed ring may also be arbitrary.

### (II-4-4-1)

As with the (II-4-2-2) about the formula (B1), two or three of the structures of the formula (B3), which are the same or different from each other, may be bonded to a divalent or trivalent linking group to form a dimer or trimer structure.

### (II-4-4-2)

Some specific examples of the organic group having the structure represented by the formula (B3) include the followings. The bonding site to the unit structure A is not particularly limited. Needless to say, the structure may be a structure having the exemplified structure as a part of the entirety.

Examples having more than two bonding sites (*) are included, and the excess bonding site may be used for bonding, crosslinking, or the like to an aromatic ring in another polymer chain.

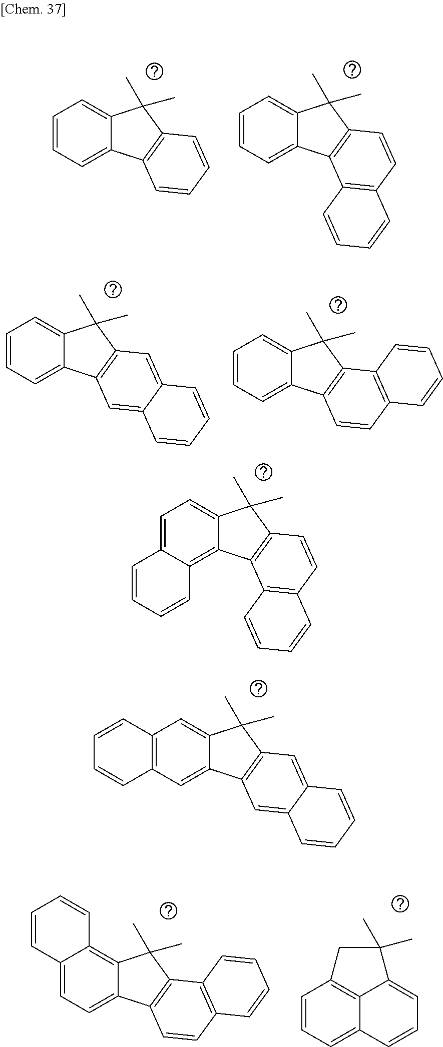

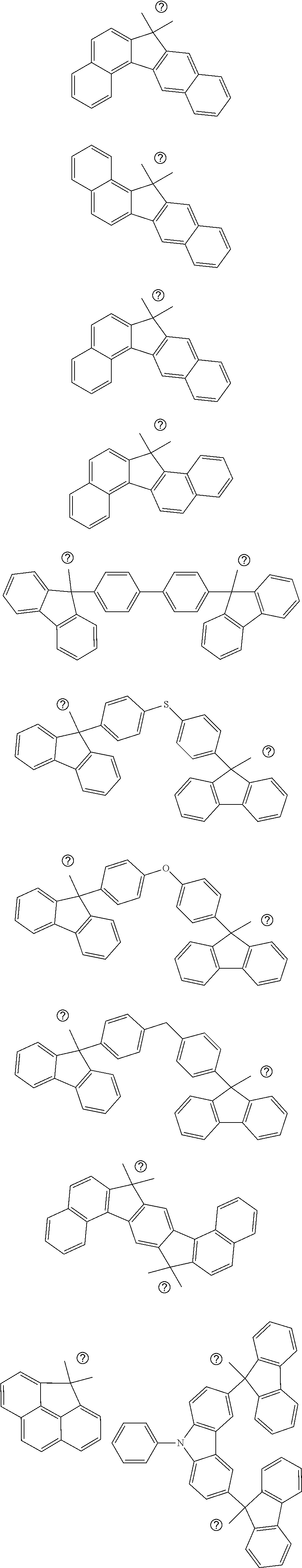

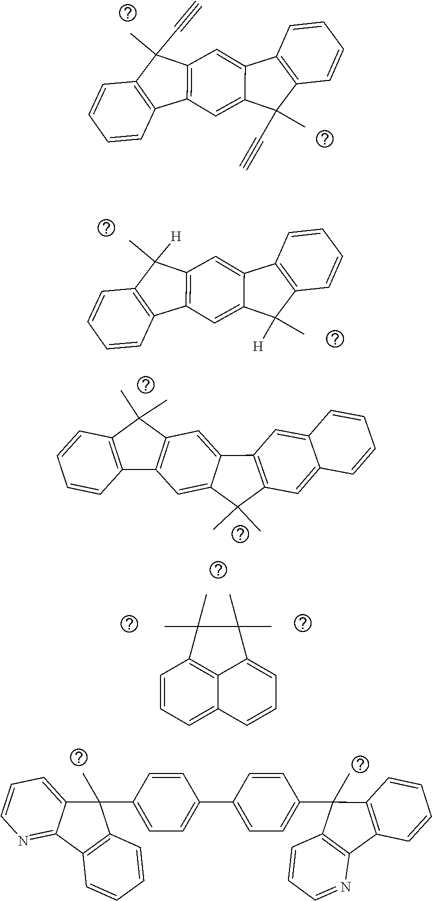

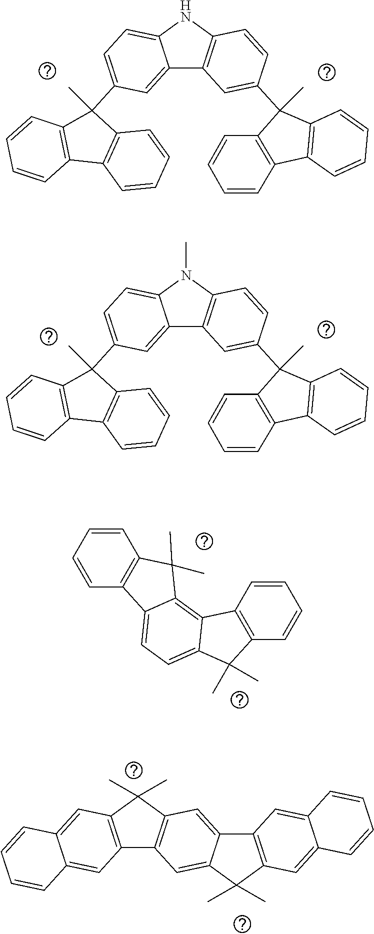

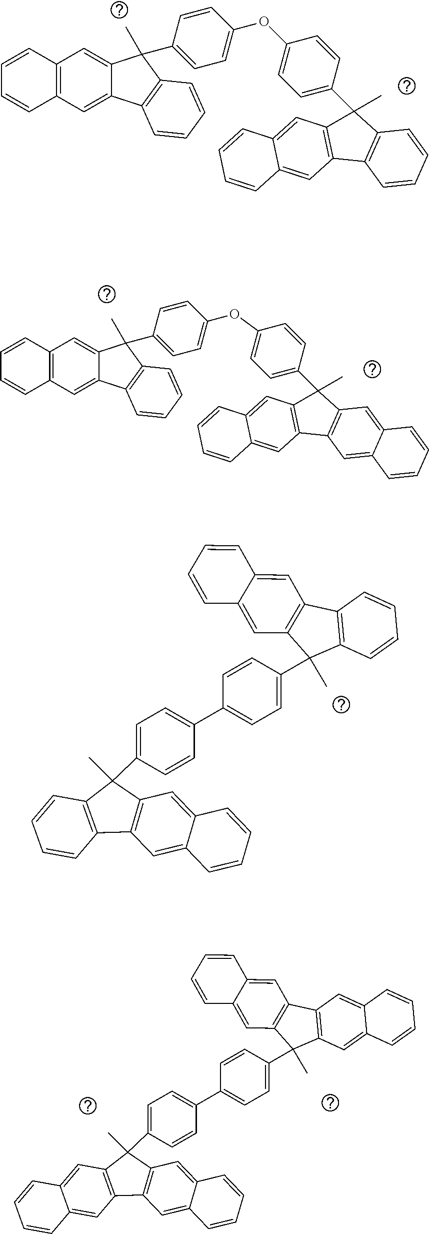

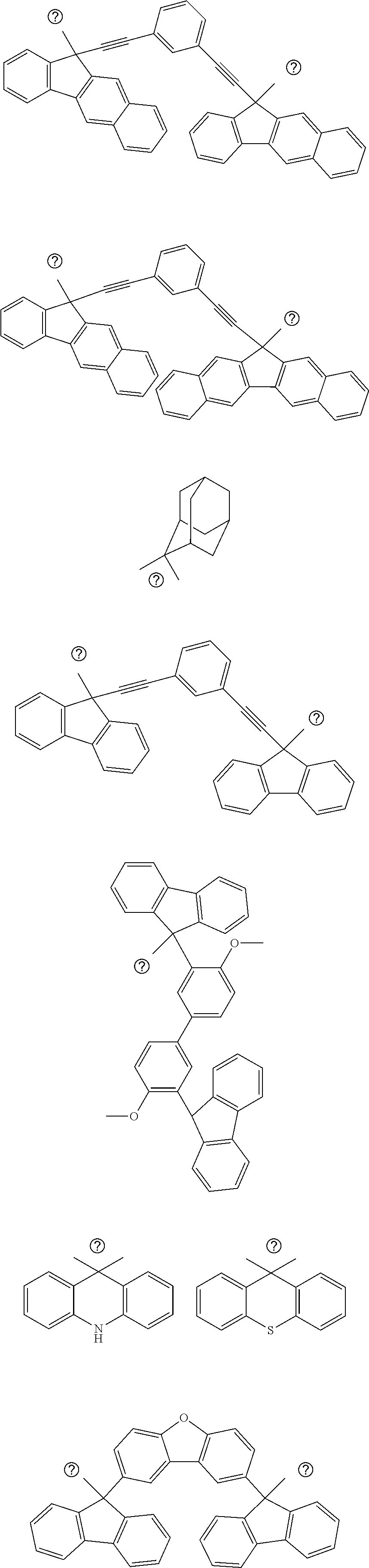

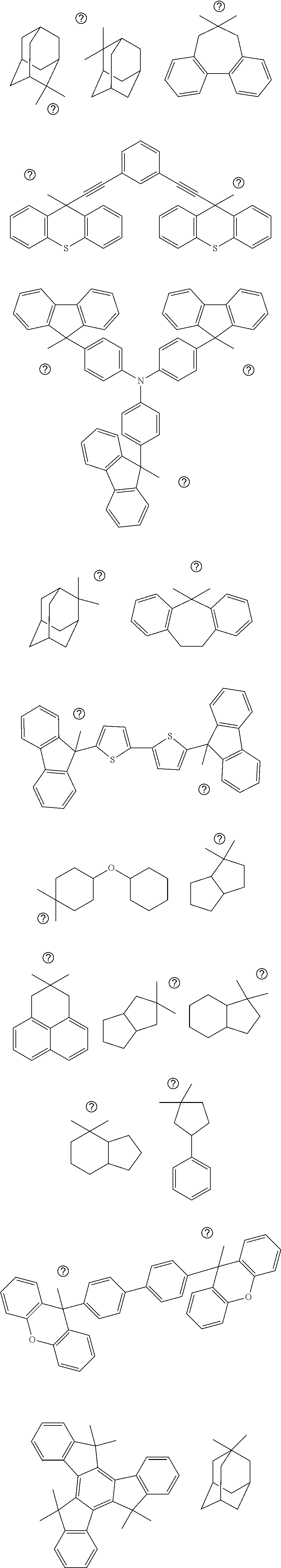

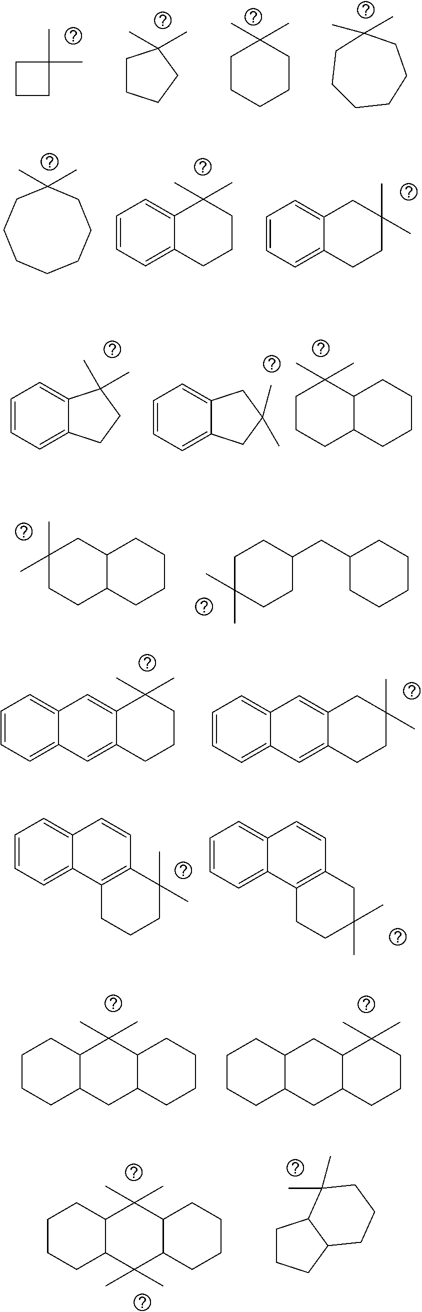

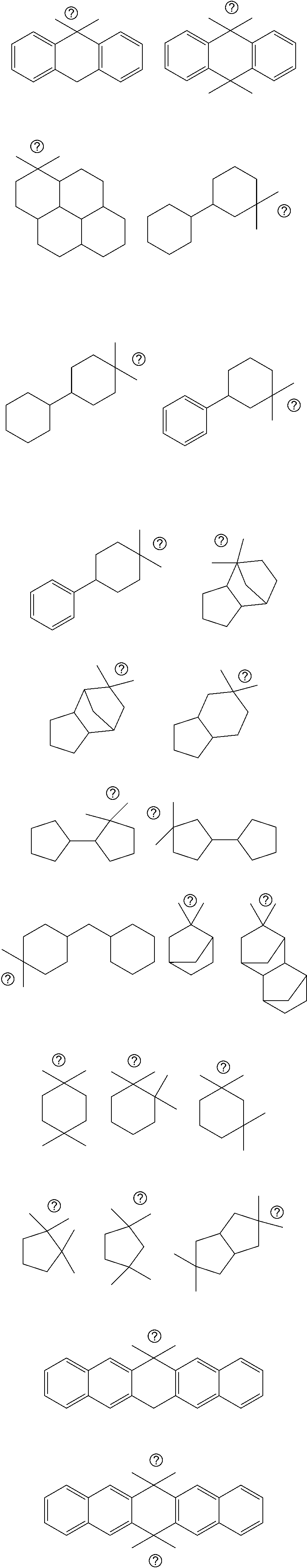

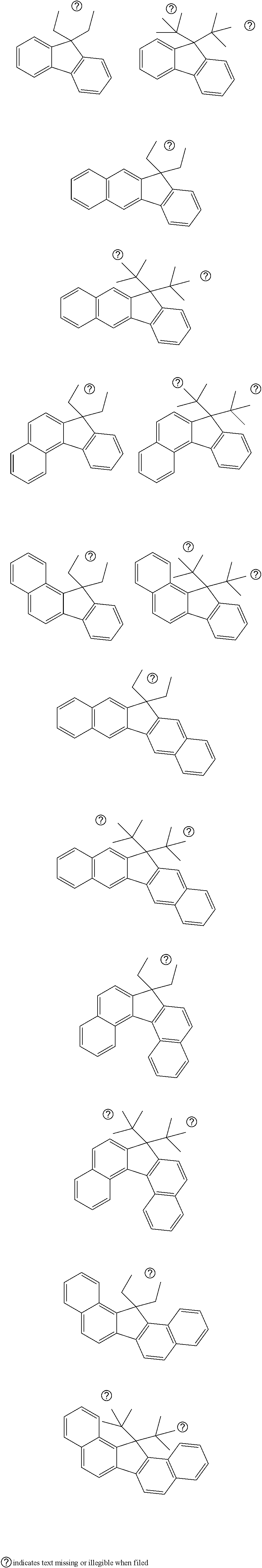

### (II-4-4-3)

When Z in the formula (133) has an aromatic ring, the aromatic ring [see Ar¹ in the following formula (1332), for example] may be additionally bonded to another unit structure B.

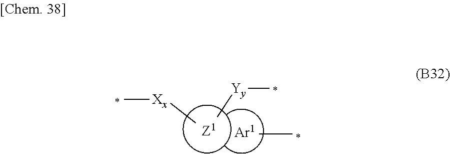

In the formula (1332),
Z¹ represents at least one non-aromatic single ring, Ar¹ represents at least one aromatic single ring forming a condensed ring with the non-aromatic single ring of Z¹, and Z¹ and Ar¹ constitute a bicyclic, tricyclic, tetracyclic, or pentacyclic condensed ring having 8 to 25 carbon atoms and optionally having a substituent, as an entirety. The number of carbon atoms here means only the number of carbon atoms constituting a cyclic skeleton of the bicyclic, tricyclic, tetracyclic, or pentacyclic condensed ring excluding the substituent, and when the bicyclic, tricyclic, tetracyclic, or pentacyclic condensed ring is a heteroring, the number of carbon atoms does not include the number of heteroatoms constituting the heteroring.

The bicyclic, tricyclic, tetracyclic, or pentacyclic condensed ring may further form a condensed ring with one or more aromatic rings, and specifically form a hexa- or higher-cyclic condensed ring. The number of carbon atoms in the hexa- or higher-cyclic condensed ring is preferably 40 or less. The number of carbon atoms here means only the number of carbon atoms constituting a cyclic skeleton of the hexa- or higher-cyclic condensed ring excluding a substituent, and when the hexa- or higher-cyclic condensed ring is a heteroring, the number of carbon atoms does not include the number of heteroatoms constituting the heteroring.

The sequential positional relationship between one or more non-aromatic single rings contained in Z¹ and one or more aromatic single rings contained in Ar¹ in the cyclic organic group encompasses arbitrary relationships. For example, when two or more non-aromatic single rings contained in Z¹ and two or more aromatic single rings contained in Ar¹ are present, the non-aromatic single rings contained in Z¹ and the aromatic single rings contained in Ar¹ may be alternately arranged to form the condensed ring.

X, Y, “x”, and “y” have the same definitions as in the formula (B3).

In this case, as in the following formula (C3):

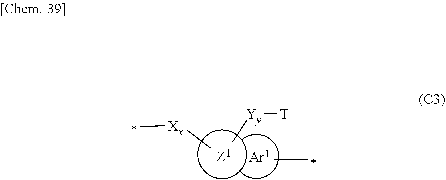

in the formula (C3),
Z¹, Ar¹, X, Y, “x”, and “y” have the same definitions as in the formula (B32), and
T represents a polymer terminal,
when one bonding site of a linkage carbon atom is bonded to the polymer terminal T (such as a hydrogen atom; various functional groups such as a hydroxy group and an unsaturated aliphatic hydrocarbon group; a terminal unit structure A; and the unit structure A in another polymer chain), the structure may be considered a unit structure C equivalent to the composite unit structure A-B and can replace at least one composite unit structure A-B. Specifically, the polymer chain may be extended by bonding between the aromatic ring in the formula (C3) [Ar¹ in the formula (C3)] and the other unit structure B and also by bonding to the aromatic ring in the unit structure A via a bonding site from the remaining linkage carbon atom shown in the formula (C3).

### (II-4-4-4)

A more specific structure of the formula (C3) is, for example, a structure represented by the following formula (C31). In the following formula (C31), T in the formula (C3) is a hydrogen atom as the terminal group, and among “p”, k₁ and k₂, each of which can be a bonding site, “p” and k₁ or “p” and k₂ form one unit structure C equivalent to the composite unit structure A-B.

The structure can function also as the unit structure A through k₁ and k₂.

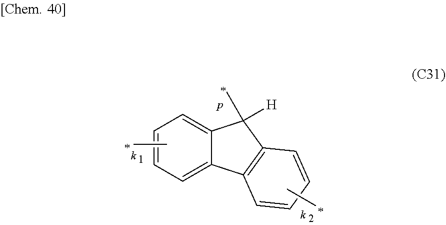

The following formula (C32) represents an example in which T in the formula (C3) represents a phenyl group. In this example, among “p”, k₁, k₂, and “m”, each of which can be a bonding site, “p” and k₁, “p” and k₂, or “p” and “m” form one unit structure C equivalent to the composite unit structure A-B.

The structure can function also as the unit structure A through k₁ and k₂, k₁ and “m”, or k₂ and “m”.

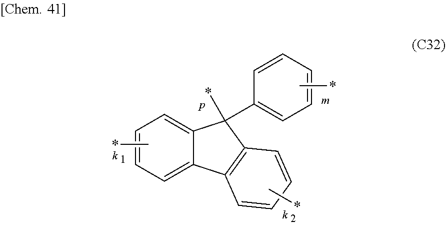

Various more specific examples of the unit structure C of the formula (C3) (one unit structure equivalent to the composite unit structure A-B) include the followings. “*” represents a bonding site to the unit structure A.

In the unit structure C, a bonding site to be bonded to the unit structure B separately extends from an aromatic ring in these structures, but such a bonding site is omitted in the following specific examples. Needless to say, the structure may be a unit structure having the exemplified structure as a part of the entirety.

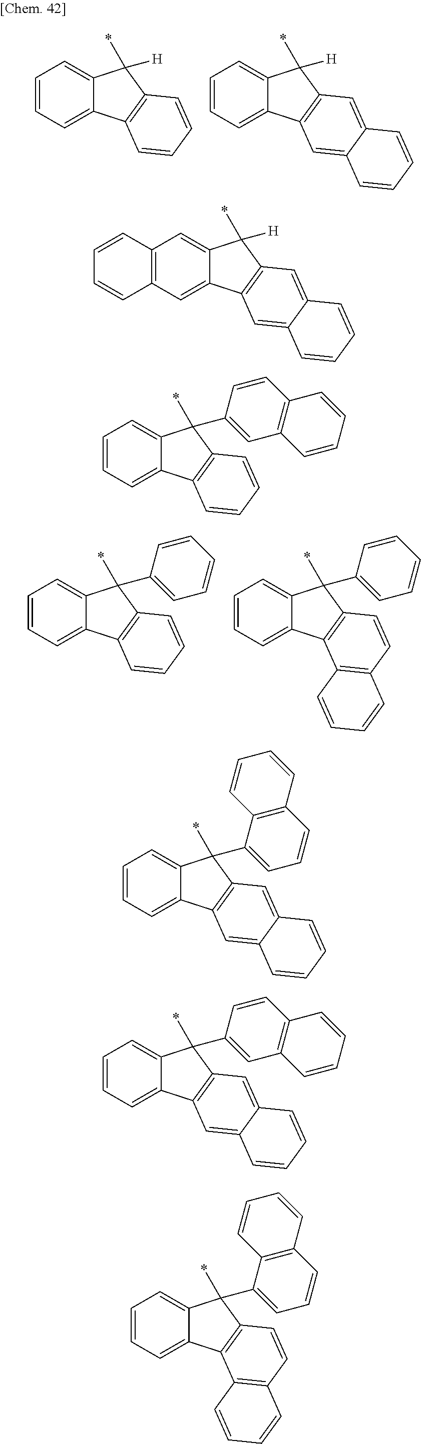

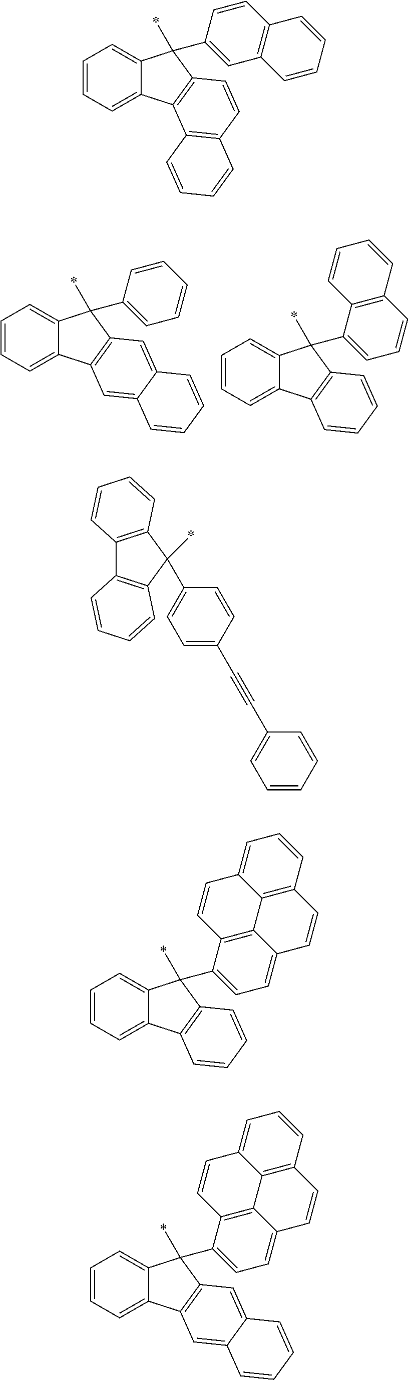

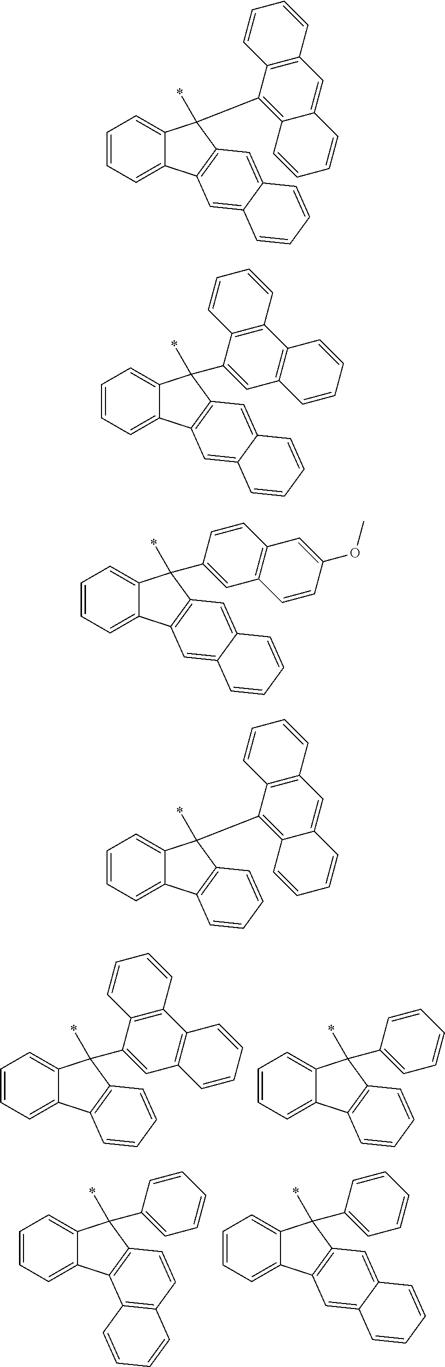

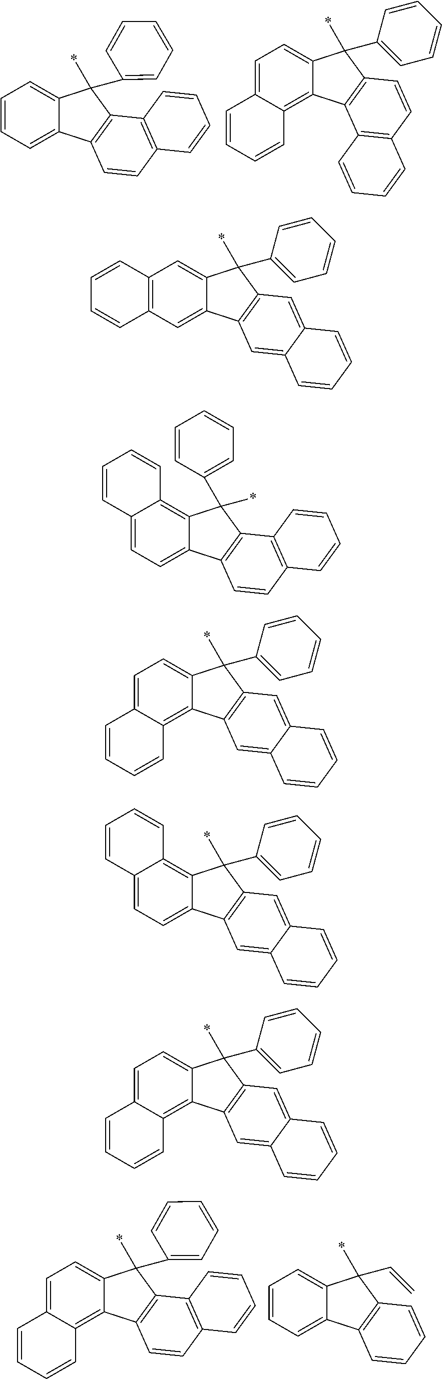

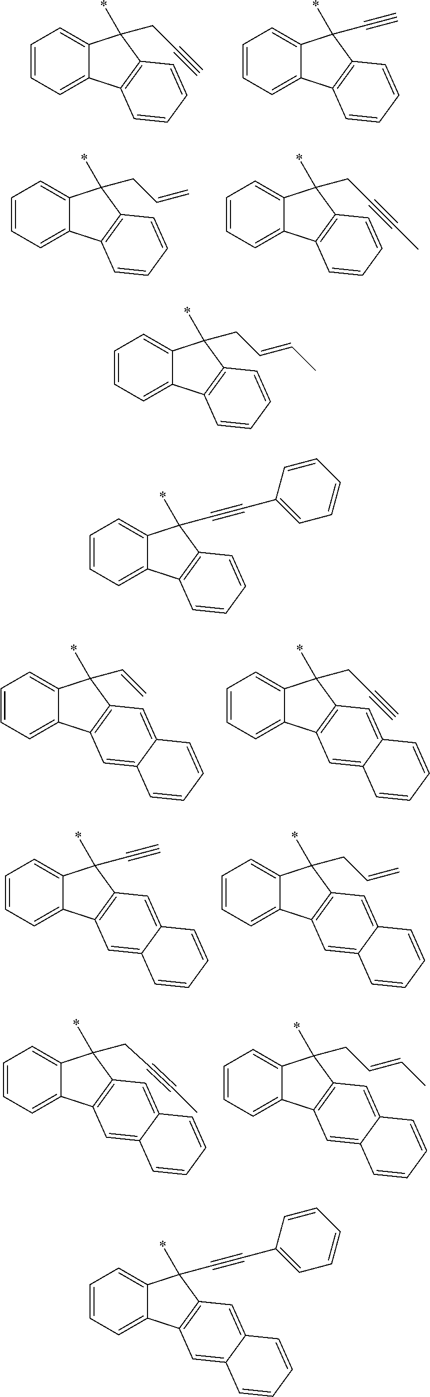

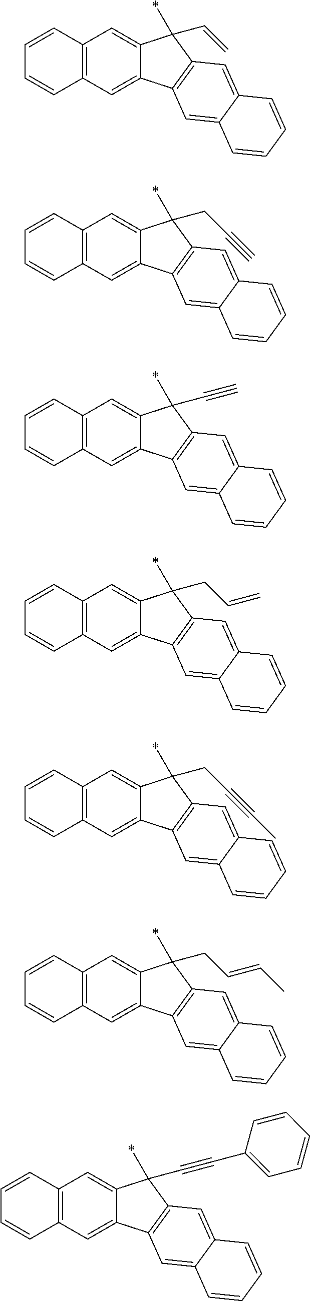

The specific examples may be specific examples of the polymer terminal when the bonding site from the aromatic ring is absent.

### (II-4-5)

The novolac resin having the structure represented by the formula (AB) can be prepared by a known method. For example, the novolac resin can be prepared by condensation between a ring-containing compound represented by H-A-H and an oxygen-containing compound represented by OHC—B, O═C—B, HO—B—OH, RO—B—OR, RO—CH₂—B—CH₂—OR, or the like. Here, A and B in the formula have the same definitions as above. R represents a hydrogen atom, a halogen, or an alkyl group having about 1 to 3 carbon atoms.

The ring-containing compounds may be used singly, or may be used in combination of two or more thereof, and the same applies to the oxygen-containing compound. In this condensation reaction, the oxygen-containing compound may be used at a ratio of 0.1 to 10 mol, preferably 0.1 to 2 mol, relative to 1 mol of the ring-containing compound.

As a catalyst used in the condensation reaction, for example, a mineral acid such as sulfuric acid, phosphoric acid, and perchloric acid; an organic sulfonic acid such as p-toluenesulfonic acid, p-toluenesulfonic acid monohydrate, methanesulfonic acid, and trifluoromethanesulfonic acid; a carboxylic acid such as formic acid and oxalic acid; mercaptopropionic acid may be used. The amount of the catalyst used varies depending on the type of the used catalyst, and is typically 0.001 to 10,000 parts by mass, preferably 0.01 to 1,000 parts by mass, and more preferably 0.05 to 100 parts by mass, per 100 parts by mass of the ring-containing compound (a case of a plurality types thereof, the sum thereof).

The condensation reaction is typically performed by using a solvent, though it may be performed without a solvent. The solvent is not particularly limited as long as the solvent can dissolve the reaction substrates and does not inhibit the reaction. Examples thereof include 1,2-dimethoxyethane, diethylene glycol dimethyl ether, propylene glycol monomethyl ether, propylene glycol monomethyl ether acetate, tetrahydrofuran, dioxane, dichloromethane, 1,2-dichloroethane, toluene, N-methylpyrrolidone, and dimethylformamide. The temperature for the condensation reaction is typically 40° C. to 200° C., and preferably 100° C. to 180° C. The reaction time varies depending on the reaction temperature, and is typically 5 minutes to 50 hours, and preferably 5 minutes to 24 hours.

The weight-average molecular weight of the novolac resin according to one aspect of the present invention is typically 500 to 100,000, and preferably 600 to 50,000, 700 to 10,000, or 800 to 8,000.

### (II-5) Solvent

The coating composition for a nitrogen-atom-containing substrate of one aspect of the present invention contains a solvent.

The solvent is not particularly limited as long as the solvent can dissolve the specific novolac resin and other optional components added as necessary.

### (II-5-1)

Examples of the solvent include methyl cellosolve acetate, ethyl cellosolve acetate, propylene glycol, propylene glycol monomethyl ether, propylene glycol monoethyl ether, propylene glycol monopropyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol monomethyl ether, diethylene glycol monoethyl ether, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, methyl 2-hydroxy-2-methylpropionate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone. These solvents may be used singly, or in combination of two or more thereof.

### (II-5-2)

A solvent having a boiling point of 160° C. or higher may be contained in combination with a solvent having a boiling point of lower than 160° C.

As such a high-boiling-point solvent, the following compounds described in WO 2018/131562 A1 may be preferably used, for example.

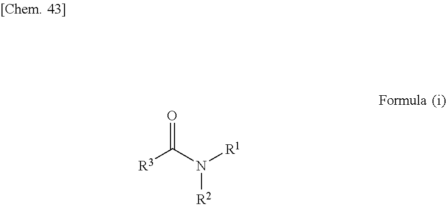

In the formula (i), R¹, R², and R³ each represent a hydrogen atom; or an alkyl group having 1 to 20 carbon atoms and optionally interrupted by an oxygen atom, a sulfur atom, or an amide bond, and may be the same or different from each other and be bonded to each other to form a cyclic structure.

Alternatively, 1,6-diacetoxyhexane (boiling point: 260° C.) and tripropylene glycol monomethyl ether (boiling point: 242° C.), which are described in JP 2021-84974 A, and other various high-boiling-point solvents described in paragraph 0082 of this Patent Publication may be preferably used.

Alternatively, dipropylene glycol monomethyl ether acetate (boiling point: 213° C.), diethylene glycol monoethyl ether acetate (boiling point: 217° C.), diethylene glycol monobutyl ether acetate (boiling point: 247° C.), dipropylene glycol dimethyl ether (boiling point: 171° C.), dipropylene glycol monomethyl ether (boiling point: 187° C.), dipropylene glycol monobutyl ether (boiling point: 231° C.), tripropylene glycol monomethyl ether (boiling point: 242° C.), γ-butyrolactone (boiling point: 204° C.), benzyl alcohol (boiling point: 205° C.), propylene carbonate (boiling point: 242° C.), tetraethylene glycol dimethyl ether (boiling point: 275° C.), 1,6-diacetoxyhexane (boiling point: 260° C.), dipropylene glycol (boiling point: 230° C.), and 1,3-butylene glycol diacetate (boiling point: 232° C.), which are described in JP 2019-20701 A, and other various high-boiling-point solvents described in paragraphs 0023 to 0031 in this Patent Publication may be preferably used.

(II-6) Acid and/or Salt Thereof, and/or Acid Generator

The coating composition for a nitrogen-atom-containing substrate of one aspect of the present invention may contain an acid and/or a salt thereof, and/or an acid generator.

### (II-6-1)

Examples of the acid include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

As a salt, a salt of the aforementioned acid may be used. The salt is not particularly limited, and an ammonia derivative salt such as a trimethylamine salt and a triethylamine salt, a pyridine derivative salt, a morpholine derivative salt, and the like may be suitably used.

The acids and/or the salts thereof may be used singly, or may be used in combination of two or more thereof. The content is typically 0.0001 to 20 mass %, preferably 0.0005 to 10 mass %, and further preferably 0.01 to 5 mass % relative to the total solid content.

### (II-6-2)

Examples of the acid generator include a thermal acid generator and a photoacid generator.

### (II-6-2-1)

Examples of the thermal acid generator include 2,4,4,6-tetrabromocyclohexadienone, benzoin tosylate, 2-nitrobenzyl tosylate, K-PURE (registered trademark) series: CXC-1612, CXC-1614, TAG-2172, TAG-2179, TAG-2678, TAG-2689, and TAG-2700 (manufactured by King Industries, Inc.), SI-45, SI-60, SI-80, SI-100, SI-110, and SI-150 (manufactured by SANSHIN CHEMICAL INDUSTRY CO., LTD.), and other organic sulfonic acid alkyl esters.

### (II-6-2-2)

The photoacid generator generates an acid when the resist is exposed. Thus, the acidity of the resist underlayer film, which is a coating, can be regulated. This is one method for adjusting the acidity of the resist underlayer film to the acidity of the resist as an upper layer. Regulating the acidity of the resist underlayer film can regulate the pattern shape of the resist to be formed in the upper layer.

Examples of the photoacid generator contained in the coating composition for a nitrogen-atom-containing substrate of one aspect of the present invention include an onium salt compound, a sulfonimide compound, and a disulfonyldiazomethane compound.

Examples of the onium salt compound include: an iodonium salt compound such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate; and a sulfonium salt compound such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

### (II-6-2-3)

The acid generators may be used singly, or may be used in combination of two or more thereof.

When the acid generator is used, the amount thereof is 0.01 to 10 parts by mass, 0.1 to 8 parts by mass, or 0.5 to 5 parts by mass, per 100 parts by mass of the solid content of the coating composition for a nitrogen-atom-containing substrate.

### (II-7) Other Optional Components

The coating composition for a nitrogen-atom-containing substrate of one aspect of the present invention may contain a crosslinker, a surfactant, a light absorber, a rheology adjuster, an adhesive auxiliary, and the like, in addition to the above, as necessary.

### (II-7-1) Crosslinker

Representative examples of the crosslinker include an aminoplast crosslinker and a phenoplast crosslinker.

As the crosslinker, a crosslinker having high heat resistance may be used. As the crosslinker having high heat resistance, a compound containing a substituent that can form crosslink and having an aromatic ring (for example, a benzene ring or a naphthalene ring) in the molecule may be preferably used.

### (II-7-1-1)

Examples of the aminoplast crosslinker include a highly alkylated, alkoxylated, or alkoxyalkylated melamine, benzoguanamine, glycoluril, or urea, and a polymer thereof. The aminoplast crosslinker is preferably a crosslinker having at least two substituents that can form crosslink, and is a compound such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or butoxymethylated thiourea. A condensate of these compounds may also be used.

The aminoplast crosslinker is preferably at least one selected from the group consisting of tetramethoxymethylglycoluril and hexamethoxymethylmelamine.

Some specific examples thereof include the followings.

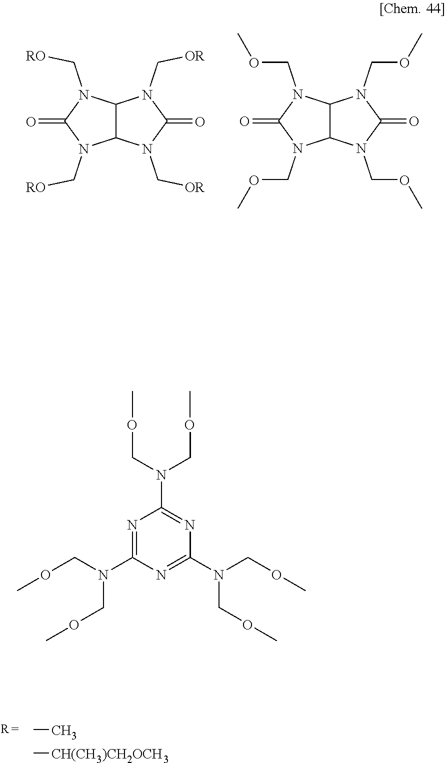

### (II-7-1-2)

Examples of the phenoplast crosslinker include a highly alkylated, alkoxylated, or alkoxyalkylated aromatic compound and a polymer thereof. The phenoplast crosslinker is preferably a crosslinker having, in one molecule, at least two substituents that can form crosslink, and is a compound such as 2,6-dihydroxymethyl-4-methylphenol, 2,4-dihydroxymethyl-6-methylphenol, bis(2-hydroxy-3-hydroxymethyl-5-methylphenyl)methane, bis(4-hydroxy-3-hydroxymethyl-5-methylphenyl)methane, 2,2-bis(4-hydroxy-3,5-dihydroxymethylphenyl)propane, bis(3-formyl-4-hydroxyphenyl)methane, bis(4-hydroxy-2,5-dimethylphenyl)formylmethane, and α,α-bis(4-hydroxy-2,5-dimethylphenyl)-4-formyltoluene. A condensate of these compounds may also be used.

In addition to the above, other examples of such a compound include a compound having a partial structure of the following formula (4), and a polymer or oligomer having a repeating unit of the following formula (5).

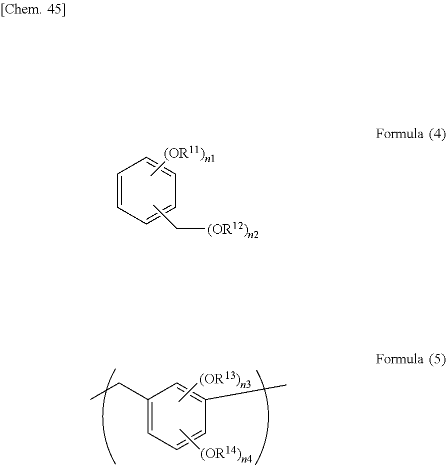

The R¹¹, R¹², R¹³ and R¹⁴ represent a hydrogen atom or an alkyl group having 1 to 10 carbon atoms, and these alkyl groups may be any of the aforementioned example. n1 represents an integer of 1 to 4, n2 represents an integer of 1 to (5-n1), and (n1+n2) represents an integer of 2 to 5. n3 represents an integer of 1 to 4, n4 represents 0 to (4-n3), and (n3+n4) represents an integer of 1 to 4. The oligomer and the polymer that can be used have the number of repeating unit structures within a range of 2 to 100, or 2 to 50.

Some specific examples include the followings.

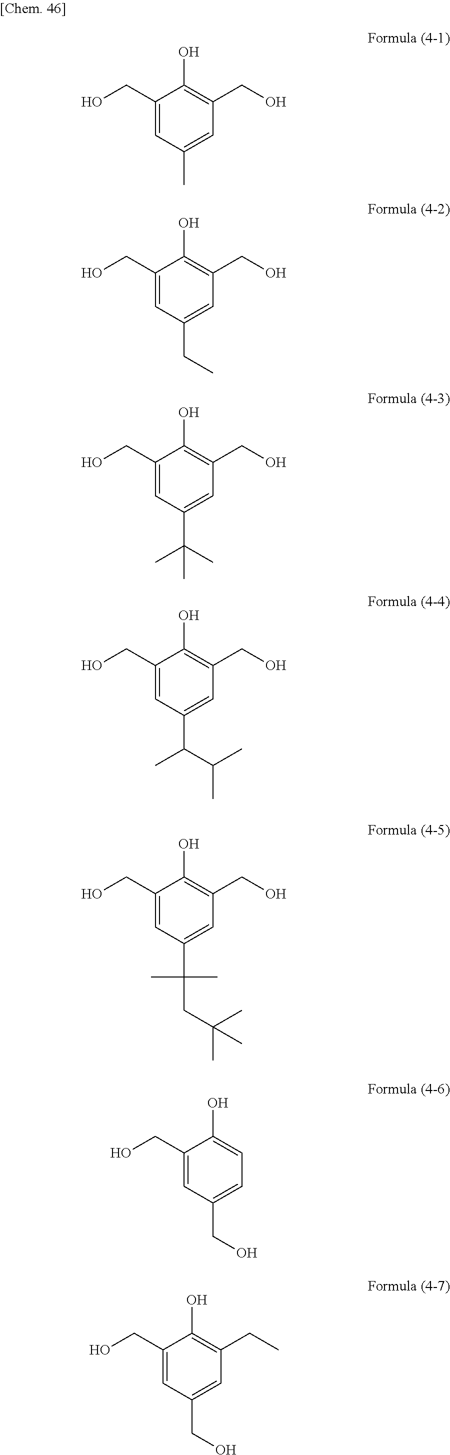

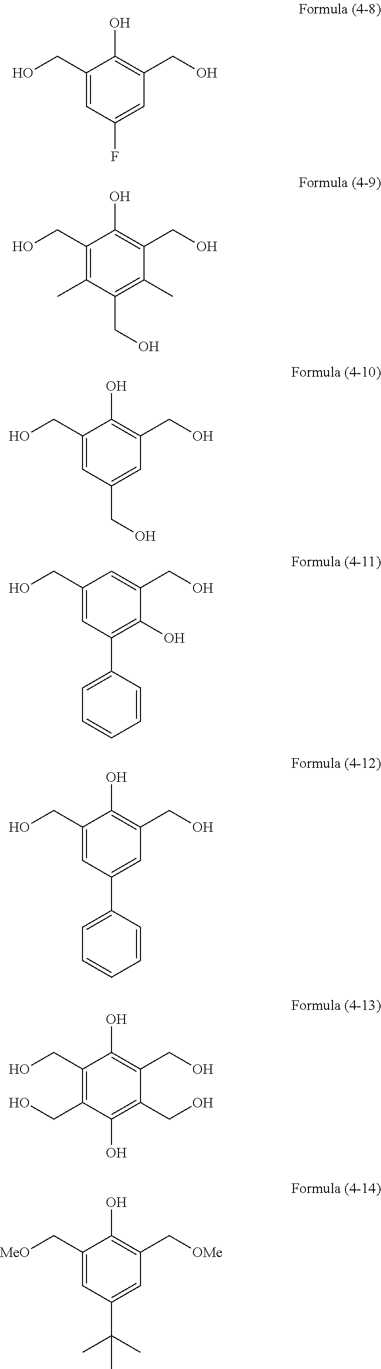

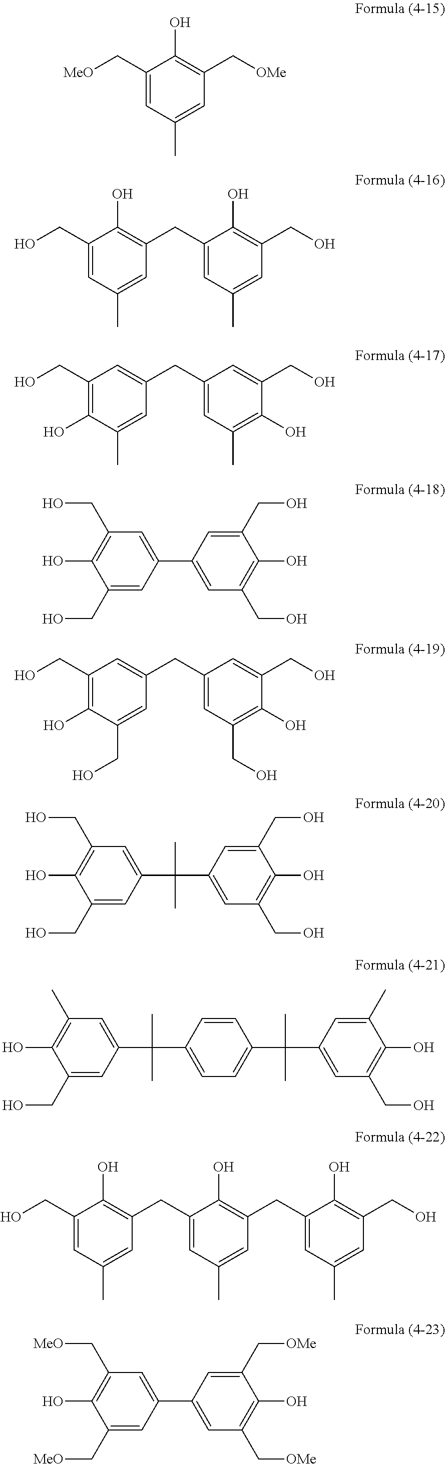

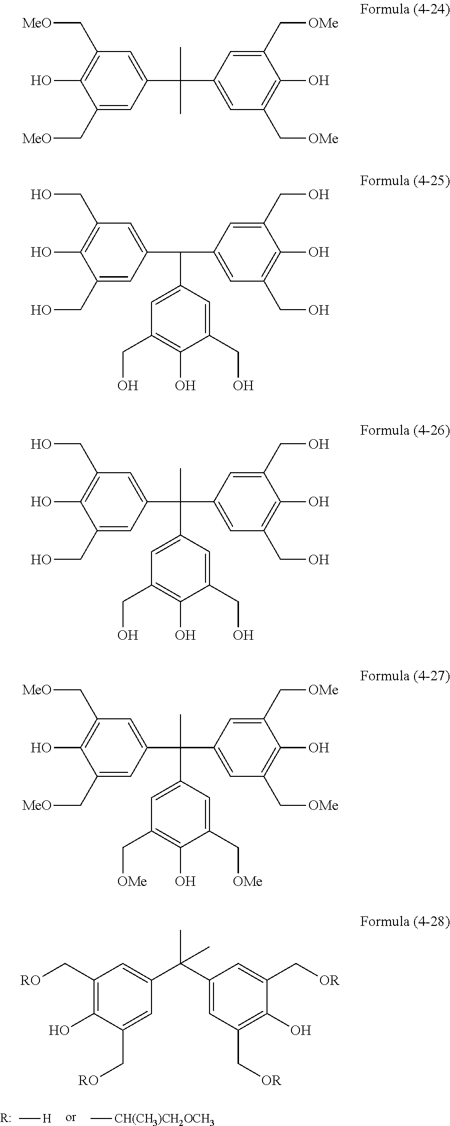

### (II-7-1-3)

The crosslinkers such as the aminoplast crosslinkers and the phenoplast crosslinkers, may be used singly, or may be used in combination of two or more thereof. The aminoplast crosslinker and the phenoplast crosslinker can be manufactured by a known method or a method equivalent thereto, or a commercially available product thereof may be used.

The amount of the crosslinker used, such as the aminoplast crosslinker and the phenoplast crosslinker, varies depending on the coating solvent used, the base substrate used, a required solution viscosity, a required film shape, and the like, and is 0.001 mass % or more, 0.01 mass % or more, 0.05 mass % or more, 0.5 mass % or more, or 0.1 mass % or more, and 80 mass % or less, 50 mass % or less, 40 mass % or less, 20 mass % or less, or 10 mass % or less, relative to a total solid content of the coating composition for a nitrogen-atom-containing substrate or the composition for forming a resist underlayer film according to the present invention.

### (II-7-2) Surfactant

In the coating composition for a nitrogen-atom-containing substrate according to the present invention, a surfactant may be incorporated to avoid generation of pinholes and striations and to further improve coatability against surface unevenness.

Examples of the surfactant include: a nonionic surfactant such as: a polyoxyethylene alkyl ether such as polyoxyethylene lauryl ether, polyoxyethylene stearyl ether, polyoxyethylene cetyl ether, and polyoxyethylene oleyl ether; a polyoxyethylene alkylaryl ether such as polyoxyethylene octylphenol ether and polyoxyethylene nonylphenol ether; a polyoxyethylene-polyoxypropylene block copolymer; a sorbitan fatty acid ester such as sorbitan monolaurate, sorbitan monopalmitate, sorbitan monostearate, sorbitan monooleate, sorbitan trioleate, and sorbitan tristearate; a polyoxyethylene sorbitan fatty acid ester such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate;
a fluorine surfactant such as EFTOP series EF301, EF303, and EF352 (manufactured by Tohkem Products Corporation, bland names), MEGAFACE (registered trademark) series F171, F173, R-30, and R-40 (manufactured by DIC Corporation, bland names), Fluorad series FC430 and FC431 (manufactured by Sumitomo 3M Limited, bland names), and Asahi Guard (registered trademark) AG710, Surflon series S-382, SC101, SC102, SC103, SC104, SC105, and SC106 (manufactured by AGC, Inc., bland names); and
organosiloxane polymer KP341 (manufactured by Shin-Etsu Chemical Co., Ltd.).

The amount of the surfactant incorporated is typically 2.0 mass % or less, and preferably 1.0 mass % or less, relative to the total solid content of the coating composition for a nitrogen-atom-containing substrate of one aspect of the present invention. These surfactants may be added singly, or may be added in combination of two or more thereof.

### (II-7-3) Other Additives

As the light absorber, commercially available light absorbers described in “Technology and Market of Industrial Dyes” (CMC Publishing Co., Ltd.) and “Dye Handbook” (edited by The Society of Synthetic Organic Chemistry, Japan) may be suitably used, including C.I. Disperse Yellow 1, 3, 4, 5, 7, 8, 13, 23, 31, 49, 50, 51, 54, 60, 64, 66, 68, 79, 82, 88, 90, 93, 102, 114, and 124; C.I. Disperse Orange 1, 5, 13, 25, 29, 30, 31, 44, 57, 72, and 73; C.I. Disperse Red 1, 5, 7, 13, 17, 19, 43, 50, 54, 58, 65, 72, 73, 88, 117, 137, 143, 199, and 210; C.I. Disperse Violet 43; C.I. Disperse Blue 96; C.I. Fluorescent Brightening Agent 112, 135, and 163; C.I. Solvent Orange 2 and 45; C.I. Solvent Red 1, 3, 8, 23, 24, 25, 27, and 49; C.I. Pigment Green 10; and C.I. Pigment Brown 2. The light absorber is incorporated in an amount of typically 10 mass % or less, and preferably 5 mass % or less, relative to the total solid content of the coating composition for a nitrogen-atom-containing substrate or the composition for forming a resist underlayer film according to the present invention.

The rheology adjuster is added mainly for a purpose of increasing flowability of the coating composition for a nitrogen-atom-containing substrate to enhance the uniformity of the film thickness of the coating and to improve the filling properties of the coating composition for a nitrogen-atom-containing substrate inside holes particularly in a baking process. Specific examples thereof include: a phthalate derivative such as dimethyl phthalate, diethyl phthalate, diisobutyl phthalate, dihexyl phthalate, and butyl isodecyl phthalate; an adipate derivative such as dinormalbutyl adipate, diisobutyl adipate, diisooctyl adipate, and octyl decyl adipate; a maleate derivative such as di(n-butyl) maleate, diethyl maleate, and dinonyl maleate; an oleate derivative such as methyl oleate, butyl oleate, and tetrahydrofurfuryl oleate; or a stearate derivative such as n-butyl stearate and glyceryl stearate. The rheology adjuster is incorporated in an amount of typically less than 30 mass % relative to the total solid content of the coating composition for a nitrogen-atom-containing substrate of one aspect of the present invention.

The adhesive auxiliary is added mainly for a purpose of increasing adhesiveness between the substrate or the resist and the coating formed of the coating composition for a nitrogen-atom-containing substrate to prevent peeling of the resist particularly in development. Specific examples thereof include: a chlorosilane such as trimethylchlorosilane, dimethylvinylchlorosilane, methyldiphenylchlorosilane, and chloromethyldimethylchlorosilane; an alkoxysilane such as trimethylmethoxysilane, dimethyldiethoxysilane, methyldimethoxysilane, dimethylvinylethoxysilane, diphenyldimethoxysilane, and phenyltriethoxysilane; a silazane such as hexamethyldisilazane, N,N′-bis(trimethylsilyl)urea, dimethyltrimethylsilylamine, and trimethylsilylimidazole; a silane such as vinyltrichlorosilane, γ-chloropropyltrimethoxysilane, γ-aminopropyltriethoxysilane, and γ-glycidoxypropyltrimethoxysilane; a heterocyclic compound such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and a urea or thiourea compound such as 1,1-dimethylurea and 1,3-dimethylurea. The adhesive auxiliary is incorporated in an amount of typically less than 5 mass %, and preferably less than 2 mass %, relative to the total solid content of the coating composition for a nitrogen-atom-containing substrate of one aspect of the present invention.

The solid content of the coating composition for a nitrogen-atom-containing substrate of one aspect of the present invention is 0.1 to 70 mass %, or 0.1 to 60 mass %. The solid content refers to the content of all the components excluding the solvent from the coating composition for a nitrogen-atom-containing substrate. The solid content may contain the crosslinkable resin at a proportion of 1 to 99.9 mass %, 50 to 99.9 mass %, 50 to 95 mass %, or 50 to 90 mass %.

### [III. Resist Underlayer Film]

By using the coating composition for a nitrogen-atom-containing substrate of one aspect of the present invention, the resist underlayer film can be formed on the nitrogen-atom-containing substrate. Specifically, the resist underlayer film as a baked product of the coating film formed of the coating composition for a nitrogen-atom-containing substrate can be formed on the nitrogen-atom-containing substrate. Another aspect of the present invention is a method for manufacturing a laminate of two or more layers including a nitrogen-atom-containing substrate and a resist underlayer film, the method including: a step of applying the coating composition for a nitrogen-atom-containing substrate on at least one surface of the nitrogen-atom-containing substrate; and a step of baking the resulting coating film to form the resist underlayer film. In the laminate, a resist film may be stacked on the surface of the resist underlayer film opposite from the nitrogen-atom-containing substrate (stacked in an order of the substrate/the resist underlayer film/the resist film). Another aspect of the present invention is a use of the coating composition for a nitrogen-atom-containing substrate for forming a resist underlayer film on a nitrogen-atom-containing substrate.

Another aspect of the present invention is a laminate of two or more layers including a nitrogen-atom-containing substrate and a resist underlayer film. Still another aspect of the present invention is a laminate in which the resist underlayer film and a resist film are stacked in this order on at least one surface of a nitrogen-atom-containing substrate. Still another aspect of the present invention is a use of the coating composition for a nitrogen-atom-containing substrate in manufacturing such laminates or semiconductor devices.

More specifically, the coating composition for a nitrogen-atom-containing substrate of one aspect of the present invention is applied on a nitrogen-atom-containing substrate (for example, a silicon nitride substrate (a SiN substrate), a silicon oxynitride substrate (a SiON substrate), a titanium nitride substrate (a TiN substrate), or a titanium oxynitride substrate (a TiON substrate)), among substrates used for manufacturing a semiconductor device, by an appropriate applying method such as a spinner and a coater, and then the composition is baked by using a heating means such as a hotplate to form the resist underlayer film on the nitrogen-atom-containing substrate. The baking condition is appropriately selected from a baking temperature of 80° C. to 800° C. and a baking time of 0.3 to 60 minutes. The baking temperature is preferably 150° C. to 500° C. (more preferably 150° C. to 400° C.), and the baking time is preferably 0.5 to 2 minutes. As an atmosphere gas during the baking, air may be used, and inert gas such as nitrogen and argon may also be used. In one aspect, the oxygen concentration is particularly preferably 1% or less.

Here, the film thickness of the resist underlayer film to be formed is, for example, 10 to 1000 nm, or may be 20 to 500 nm, 30 to 400 nm, or 50 to 300 nm, and in views of the cost and manufacture, an ultrathin film with a film thickness of less than 10 nm is preferable. The film thickness is preferably 1 nm to less than 10 nm, and more preferably 3 nm to less than 10 nm. Even when formed into such an ultrathin film, the coating composition for a nitrogen-atom-containing substrate of one aspect of the present invention has good coatability due to the specific novolac resin incorporated, and can retain resolution of a resist even when the resist film is exposed a long time after the formation the resist film, comparable to a case of immediately after the formation of the resist film.

On the resist underlayer film of an aspect of the present invention on the nitrogen-atom-containing substrate, an adhesion layer and/or a silicon-containing layer containing 99 mass % or less or 50 mass % or less of Si can be formed by coating or vapor deposition. For example, such layers can be formed by a method in which a composition for forming an adhesion layer, described in JP 2013-202982 A or JP 5827180 B2, or a silicon-containing resist underlayer film (an inorganic resist underlayer film), described in WO 2009/104552 A1, is applied by spin-coating to form a layer, or a Si-based inorganic material film can be formed by a CVD method.

The coating composition for a nitrogen-atom-containing substrate of one aspect of the present invention can be applied to a semiconductor substrate having a portion having a step and a portion having no step (a so-called stepped substrate) and baked to thereby reduce the step between the portion having a step and the portion having no step.

### [IV Method for Manufacturing Semiconductor Device]

### (IV-1)

A method for manufacturing a semiconductor device of one aspect of the present invention includes:
a step of forming a resist underlayer film from the coating composition for a nitrogen-atom-containing substrate of one aspect of the present invention on a nitrogen-atom-containing semiconductor substrate;
a step of forming a resist film on the resist underlayer film; and
a step of forming a resist pattern in the resist film by irradiation with light or electron beam and development.

A method for forming a resist pattern used for manufacturing a semiconductor of one aspect of the present invention includes a step of applying the coating composition for a nitrogen-atom-containing substrate to a nitrogen-atom-containing semiconductor substrate, and a step of then baking the composition to form a resist underlayer film.

Furthermore, another aspect of the present invention is a semiconductor device having, as a resist underlayer film, a baked product of a coating film of the coating composition for a nitrogen-atom-containing substrate on at least one surface of a nitrogen-atom-containing semiconductor substrate. The resist underlayer film may be patterned according to a circuit wiring.

The method may further includes a step of etching the resist underlayer film through the resist pattern, and may further include a step of processing the semiconductor substrate with the patterned resist underlayer film.

### (IV-2)

The step of forming the resist underlayer film from the coating composition for a nitrogen-atom-containing substrate of one aspect of the present invention on the nitrogen-atom-containing semiconductor substrate is as described in the [III. Resist Underlayer Film].

On the resist underlayer film formed in the above step, a hard mask such as a silicon-containing film may be formed as a second resist underlayer film, and the resist pattern may be formed thereon. The hard mask may be a coating film formed of a composition containing an inorganic substance or the like, or may be a vapor-deposited film of an inorganic substance or the like formed by a vapor deposition method such as CVD and PVD. Examples thereof include a SiON film, a SiN film, and a SiO₂ film. Furthermore, on the hard mask, an anti-reflective film (BARC) may be formed, or a resist-shape correcting film having no anti-reflective ability may be formed.

### (IV-3)

In the step of forming a resist pattern after forming the resist film on the resist underlayer film, the resist pattern can be formed in the resist film by irradiation with light or electron beam and development.

The exposure is performed through a mask (a reticle) for forming a predetermined pattern or with direct writing. As an exposure light source, g-line, i-line, KrF excimer laser, ArF excimer laser, EUV, or electron beam may be used, for example. After the exposure, post exposure baking (PEB) is performed as necessary. Thereafter, development is performed with a developing liquid (for example, a 2.38 mass % tetramethylammonium hydroxide aqueous solution and butyl acetate), followed by rinsing with a rinsing liquid or pure water, and the used developing liquid is removed. Thereafter, the post baking is performed to dry the resist pattern and increase adhesiveness to the base.

The etching step performed after the formation of the resist pattern is performed by dry etching, for example.

For processing the hard mask (the silicon-containing layer), the resist underlayer film, and the substrate, the following gas: CF₄, CHF₃, CH₂F₂, CH₃F, C₄F₆, C₄F₈, O₂, N₂O, NO₂, H₂, or He may be used. These gases may be used singly, or two or more thereof may be mixed and used. Furthermore, with any of these gases, argon, nitrogen, carbon dioxide, carbonyl sulfide, sulfur dioxide, neon, or nitrogen trifluoride may be mixed and used.

### (IV-4)

The resist film may be pattern-formed by a nanoimprinting method or a directed self-assembly method. That is, the step of forming the resist pattern in the resist film may be performed by a nanoimprinting method or a directed self-assembly method.

In the nanoimprinting method, a resist composition is molded by using a mold that is transparent to irradiation light and that has a formed pattern. In the directed self-assembly method, a patten is formed by using a directed self-assembly film of, for example, a diblock polymer (such as polystyrene-polymethyl methacrylate) that naturally forms a regular structure with a nanometer order.

In the nanoimprinting method, a silicon-containing layer (a hard mask layer) may be optionally formed on the resist underlayer film by coating or vapor deposition before applying a curable composition for forming a resist film, and an adhesion layer may be further formed on the resist underlayer film or on the silicon-containing layer (the hard mask layer) by coating or vapor deposition. The curable composition for forming a resist film may be applied on the adhesion layer.

### (IV-5)

For a purpose of simplifying the process steps and reducing damage to the substrate to be processed, a wet etching treatment may be performed. This leads to reduction in variation in the size after processing and pattern roughness, and therefore can process the substrate with a good yield. Thus, when the hard mask is used, the hard mask can be removed with any one of etching or an alkaline chemical reagent. Particularly when the alkaline chemical reagent is used, the following material is preferably contained as an alkali component, though components are not limited.

Examples of the alkali component include tetramethylammonium hydroxide, tetraethylammonium hydroxide, tetrapropylammonium hydroxide, tetrabutylammonium hydroxide, methyltripropylammonium hydroxide, methyltributylammonium hydroxide, ethyltrimethylammonium hydroxide, dimethyldiethylammonium hydroxide, benzyltrimethylammonium hydroxide, hexadecyltrimethylammonium hydroxide, (2-hydroxyethyl)trimethylammonium hydroxide, monoethanolamine, diethanolamine, triethanolamine, 2-(2-aminoethoxy)ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine, triisopropanolamine, tetrahydrofurfurylamine, N-(2-aminoethyl)piperazine, 1,8-diazabicyclo[5.4.0]undecene-7, 1,4-diazabicyclo[2.2.2]octane, hydroxyethylpiperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4.3.0]nonene-5. In view of operability, tetramethylammonium hydroxide and tetraethylammonium hydroxide are particularly preferable, and an inorganic base may be used in combination with the quaternary ammonium hydroxide. As the inorganic base, a hydroxide of an alkali metal such as potassium hydroxide, sodium hydroxide, or rubidium hydroxide is preferable, and potassium hydroxide is more preferable.

### EXAMPLES

### Synthesis of Polymer

Compounds A to D, catalysts E, solvents F, and reprecipitation solvents G shown below were used for synthesizing polymers of structural formulae (S1) to (S20) used for resist underlayer films and synthesizing polymers of structural formulae (SS1) to (SS2) for Comparative Examples.

### Compounds A to D

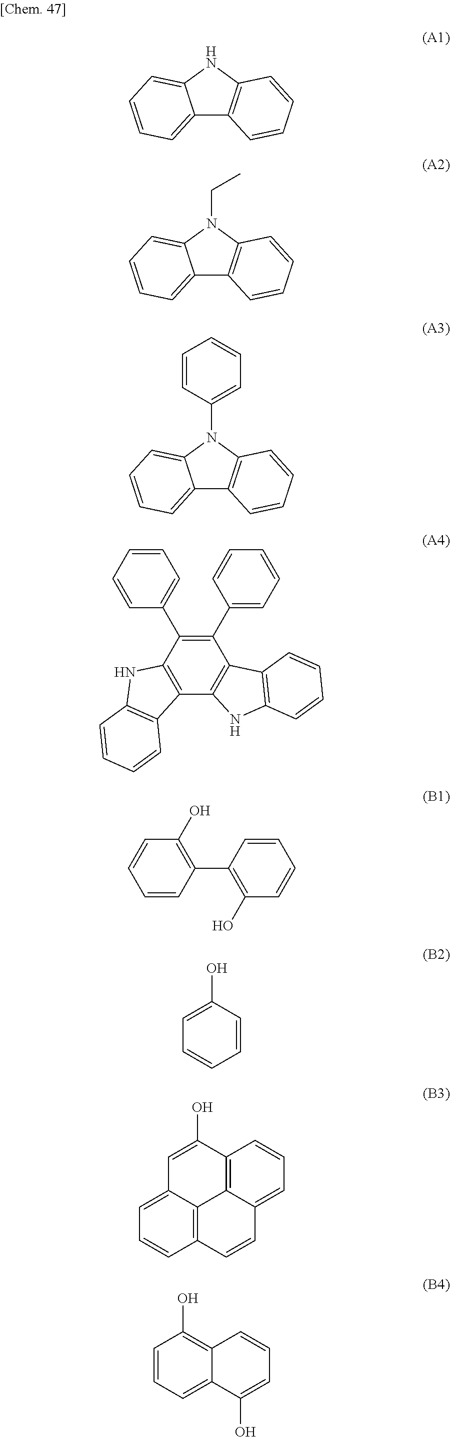

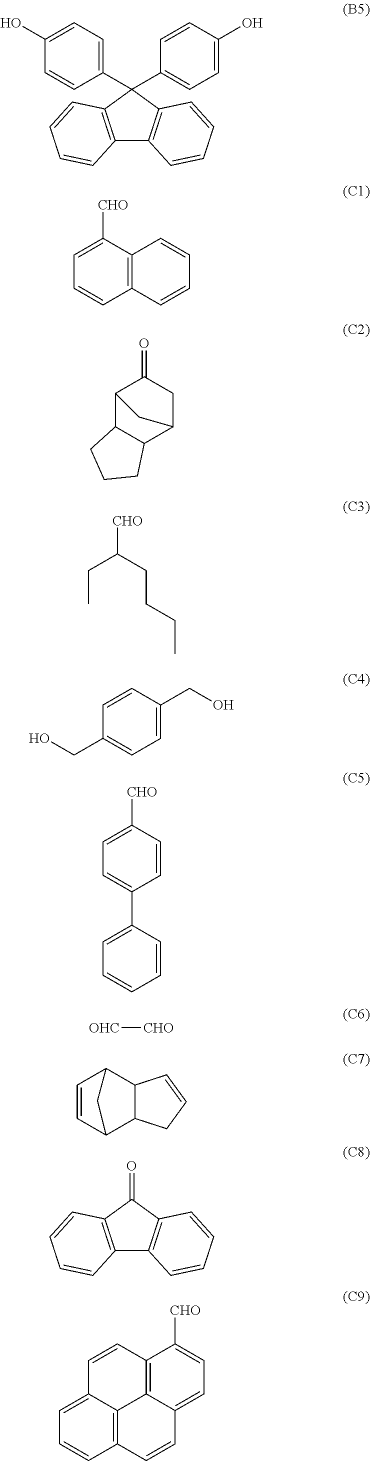

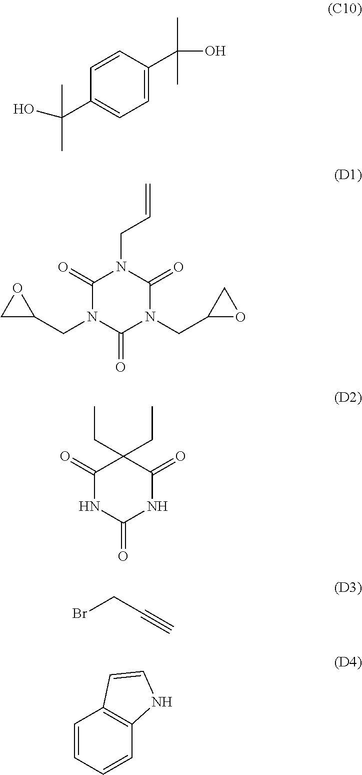

### Catalysts E, Solvents F, and Reprecipitation Solvents G

Methanesulfonic acid: E1
Paratoluenesulfonic acid monohydrate: E2
Tetrabutylammonium iodide: E3
Benzyltriethylammonium chloride: E4
Mercaptopropionic acid: E5
Propylene glycol monomethyl ether acetate (=PGMEA): F₁
Propylene glycol monomethyl ether (=PGME): F₂
Tetrahydrofuran (=THF): F₃
25% Sodium hydroxide aqueous solution: F₄
Methanol: G1
Methanol/Water: G2

### Synthesis Example 1

Into a flask, 12.0 g of A1, 7.9 g of C1, 3.2 g of C2, 0.7 g of E1, and 71.3 g of PGMEA were added. Thereafter, the mixture was heated to 120° C. under nitrogen and allowed to react for about 14 hours. After the reaction was terminated, the product was reprecipitated in methanol, and the resin was dried to obtain (S1). The weight-average molecular weight Mw in terms of polystyrene measured by GPC was about 1,700. The obtained resin was dissolved in PGMEA, and ion exchange was performed for 4 hours by using a cation-exchange resin and an anion-exchange resin to obtain a target compound solution. Note that a polymer insoluble in PGMEA was dissolved in PGME or cyclohexanone to perform the ion exchange in the same manner as above.

### Synthesis Examples 2 to 17 and 22

Resins (S2) to (S17) and (SS2) were synthesized in the same manner as in Synthesis Example 1 (see Table 1 for compounds used for the reactions). Note that a polymer insoluble in PGMEA was dissolved in PGME or cyclohexanone to perform the ion exchange in the same manner as above.

### Synthesis Example 18

Into a flask, 7.0 g of the resin (S17) synthesized in Synthesis Example 17, 9.0 g of D3, 0.5 g of E3, 18.8 g of THF, and 15.7 g of the 25% sodium hydroxide aqueous solution were added. The mixture was heated to 55° C. under nitrogen and allowed to react for about 24 hours. After the reaction was terminated, fractionation with butyl acetate and water was repeated, and the organic layer was condensed. The condensed product was reprecipitated in methanol and water, and the resultant was dried to obtain a resin (S18). The weight-average molecular weight Mw in terms of polystyrene measured by GPC was about 2,900. The obtained resin was dissolved in PGMEA, and ion exchange was performed for 4 hours by using a cation-exchange resin and an anion-exchange resin to obtain a target compound solution.

### Synthesis Examples 19 to 20

(S19) to (S20) were obtained in the same manner as in Synthesis Example 18 (see Table 1 for compounds used for the reactions).

### Synthesis Example 21

In a flask, 100.0 g of D1, 66.4 g of D2, and 4.1 g of E4 were dissolved in 682.0 g of propylene glycol monomethyl ether. The mixture was then allowed to react at 130° C. for 24 hours. The resulting solution was subjected to ion exchange for 4 hours by using a cation-exchange resin and an anion-exchange resin to obtain a target resin (SS1). The weight-average molecular weight Mw in terms of polystyrene measured by GPC was about 6,800.

TABLE 1

| Synthesis | Structural | | | | Temperature/ | |
|---|---|---|---|---|---|---|
| Example | formula | Compound | Catalyst | Solvent | Time | Reprecipitation |
| 1 | S1 | A1/C1/C2 | E1 | F1 | 120° C./ | G1 |
| | | 12.0 g/7.9 g/3.2 g | 0.7 g | 71.3 g | 14 hours | |
| 2 | S2 | A1/C1/C3 | E1 | F1 | 120° C./ | G1 |
| | | 12.0 g/7.9 g/2.8 g | 0.7 g | 69.9 g | 14 hours | |
| 3 | S3 | A1/C1/C4 | E1 | F1 | 120° C./ | G1 |
| | | 12.0 g/7.9 g/3.0 g | 0.7 g | 70.6 g | 14 hours | |
| 4 | S4 | A1/C5 | E1 | F1 | 120° C./ | G1 |
| | | 10.0 g/10.9 g | 0.3 g | 31.8 g | 4 hours | |
| 5 | S5 | A1/A2/C6 | E2 | F3 | 90° C./ | G2 |
| | | 4.8 g/13.0 g/9.9 g | 1.3 g | 25.1 g | 24 hours | |
| 6 | S6 | A1/C7 | E1 | F1 | 150° C./ | G1 |
| | | 15.0 g/11.9 g | 3.5 g | 30.3 g | 3.5 hours | |
| 7 | S7 | A1/C8 | E1 | F1 | 150° C./ | G1 |
| | | 8.0 g/8.6 g | 2.3 g | 18.9 g | 3.5 hours | |
| 8 | S8 | A1/C1 | E1 | F1 | 120° C./ | G1 |
| | | 7.0 g/6.5 g | 0.4 g | 32.4 g | 7 hours | |
| 9 | S9 | B1/C1/C9 | E1 | F2 | 120° C./ | G1 |
| | | 10.0 g/4.2 g/6.2 g | 1.5 g | 21.9 g | 24 hours | |
| 10 | S10 | B2/C5 | E1 | F1 | 150° C./ | G2 |
| | | 8.0 g/15.5 g | 2.5 g | 60.6 g | 14 hours | |
| 11 | S11 | B3/C5 | E1 | F1 | 150° C./ | G1 |
| | | 10.0 g/8.3 g | 1.3 g | 45.7 g | 20 hours | |
| 12 | S12 | A1/A3/C1 | E1 | F1 | 120° C./ | G1 |
| | | 10.0 g/6.2 g/13.4 g | 0.8 g | 91.3 g | 14 hours | |
| 13 | S13 | A1/B4/C1 | E1 | F1 | 120° C./ | G1 |
| | | 22.0 g/9.0 g/29.4 g | 1.8 g | 186.7 g | 15 hours | |
| 14 | S14 | A1/B5/C1 | E1 | F1 | 120° C./ | G1 |
| | | 18.0 g/16.2 g/24.0 g | 1.5 g | 179.1 g | 15 hours | |
| 15 | S15 | A4/C10 | E1 | F1 | 100° C./ | G1 |
| | | 12.6 g/7.4 g | 2.5 g | 51.7 g | 2 hours | |
| 16 | S16 | A4/C1 | E1/E5 | F1 | 90° C./ | G1 |
| | | 12.7 g/7.3 g | 0.9 g/0.1 g | 48.8 g | 3 hours | |
| 17 | S17 | A4/C8 | E1/E5 | F1 | 80° C./ | G1 |
| | | 14.02 g/6.18 g | 6.6 g/0.7 g | 41.3 g | 1.5 hours | |
| 18 | S18 | S17/D3 | E3 | F3/F4 | 55° C./ | G2 |
| | | 7.0 g/9.0 g | 0.5 g | 18.8 g/ | 24 hours | |
| | | | | 15.7 g | | |
| 19 | S19 | S13/D3 | E2 | F3/F4 | 50° C./ | G2 |
| | | 10.0 g/11.8 g | 0.6 g | 33.6 g/ | 8 hours | |
| | | | | 15.1 g | | |
| 20 | S20 | S14/D3 | E2 | F3/F4 | 50° C./ | G2 |
| | | 10.0 g/99 g | 0.5 g | 30.6 g/ | 8 hours | |
| | | | | 13.8 g | | |
| 21 | SS1 | D1/D2 | E4 | F2 | 130° C./ | — |
| | | 100.0 g/66.4 g | 4.1 g | 682.0 g | 24 hours | |
| 22 | SS2 | C1/D4 | E1 | F1 | 120° C./ | G1 |
| | | 15.0 g/23.1 g | 3.7 g | 62.7 g | 5 hours | |

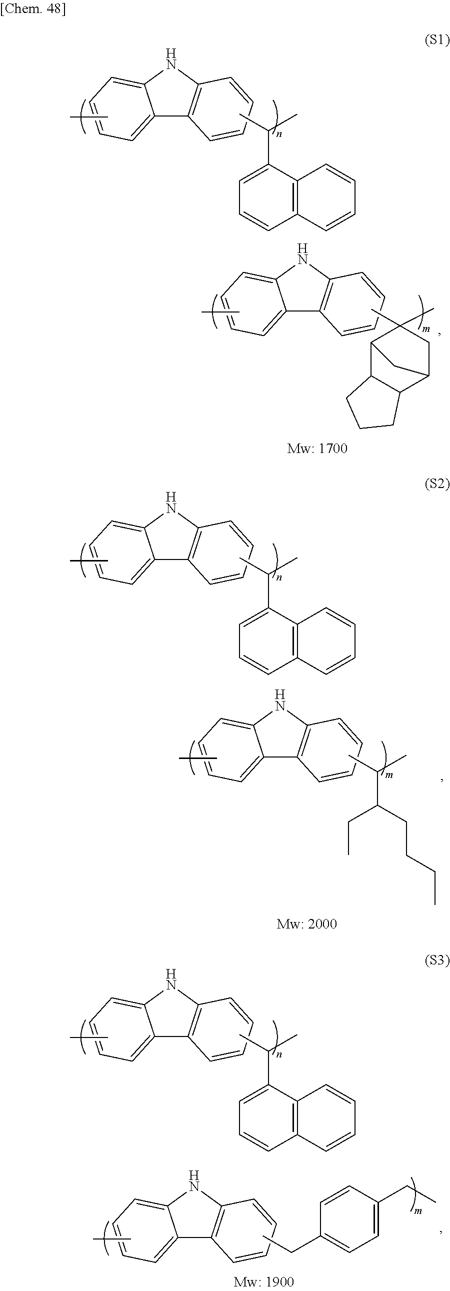

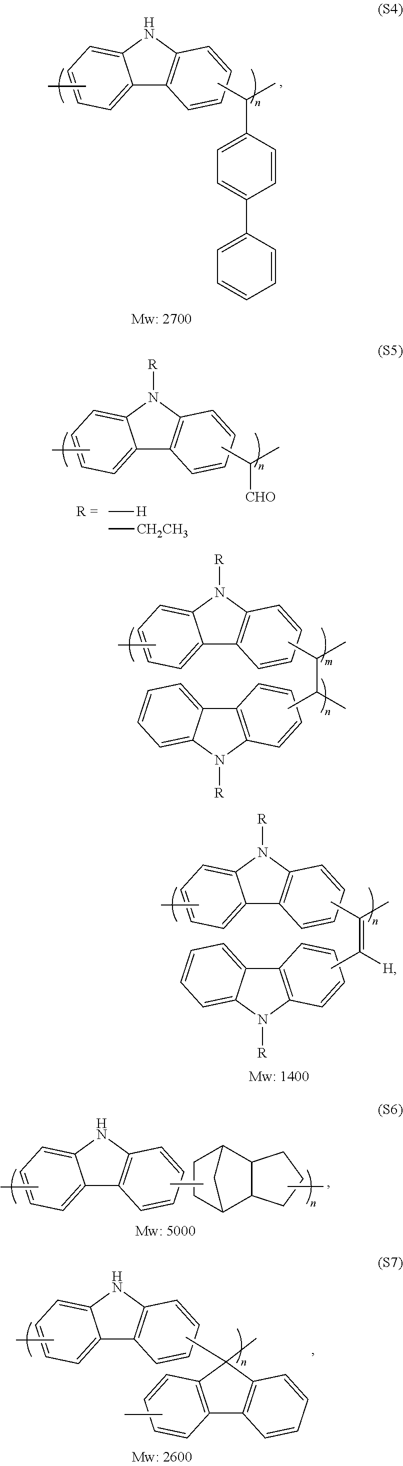

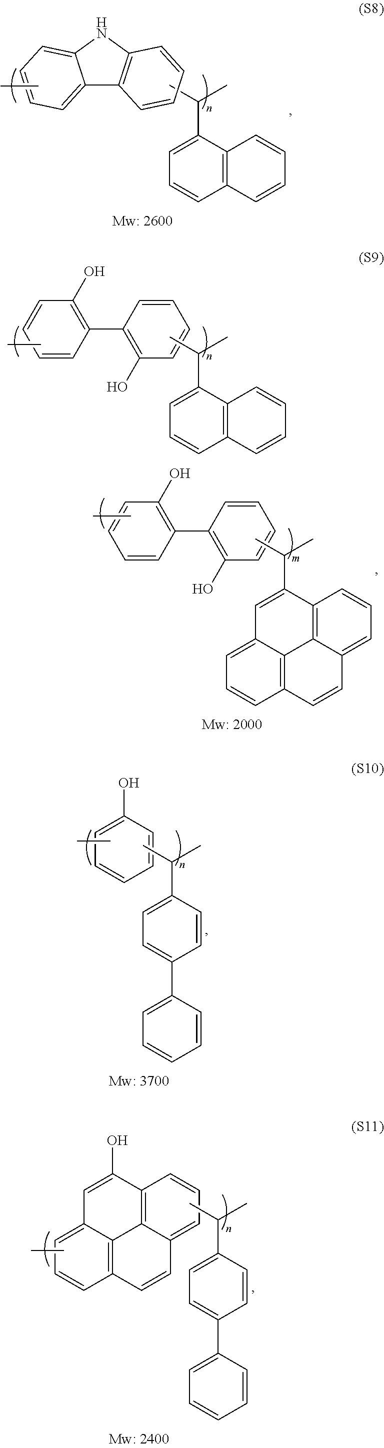

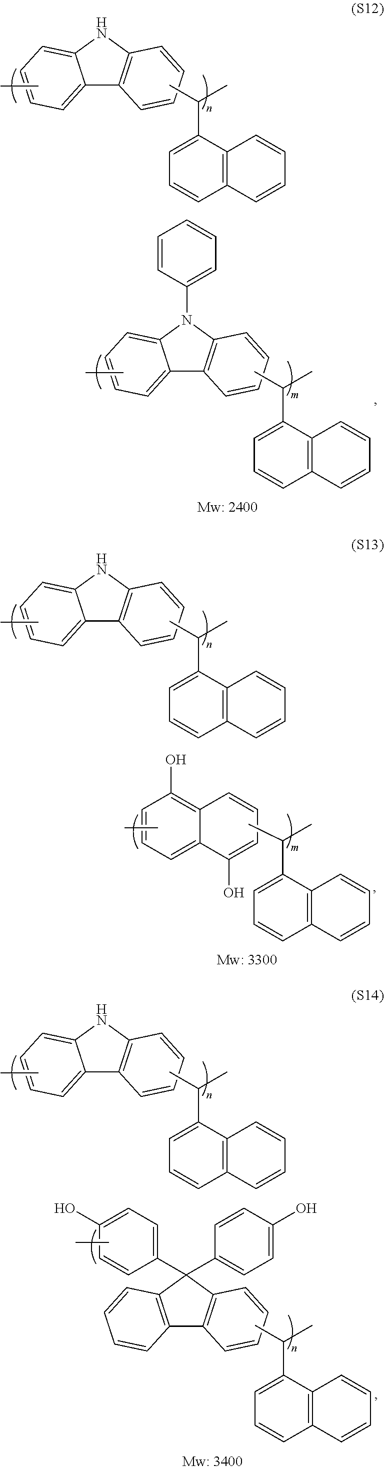

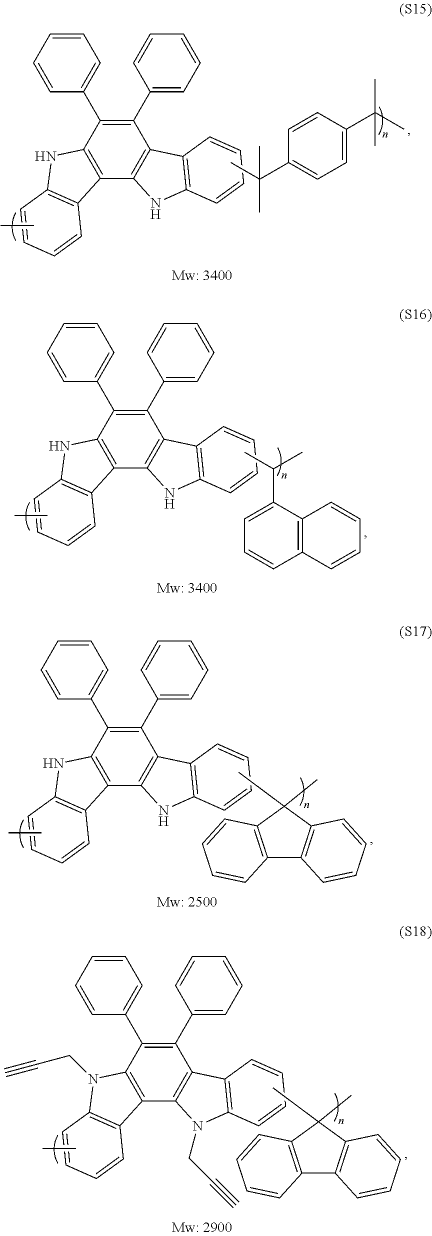

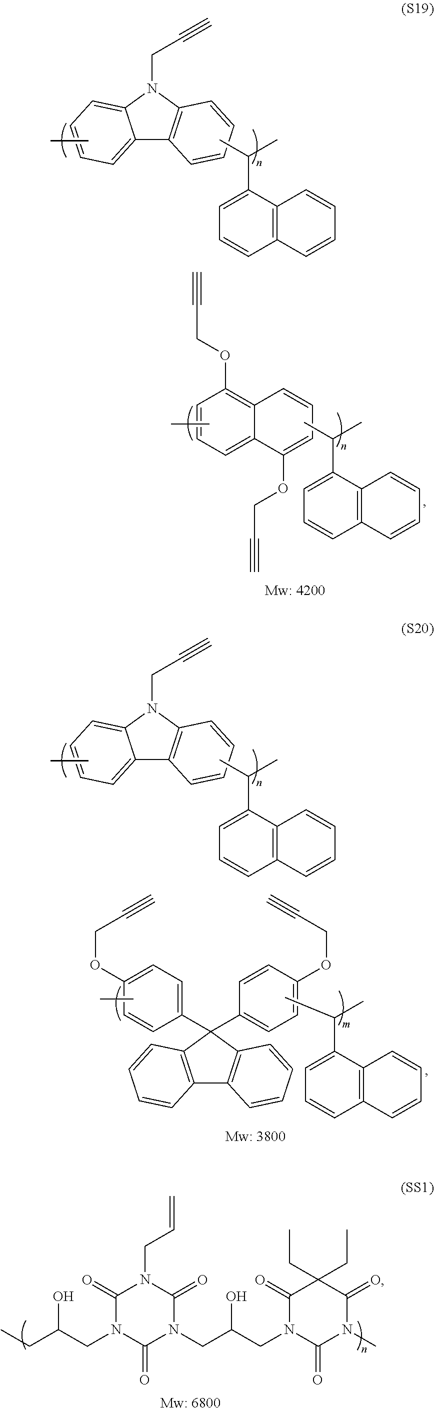

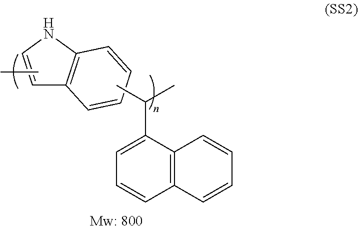

### Preparation of Material for Resist Underlayer Film

The resins (S1) to (S20) and (SS1) to (SS2), crosslinkers (CL1 to CL4), acid generators (Ad1 to Ad2), solvents (propylene glycol monomethyl ether acetate (PGMEA), propylene glycol monomethyl ether (PGME), and cyclohexanone (CYH)), and MEGAFACE (registered trademark) R-40 (manufactured by DIC Corporation, H1) as a surfactant were mixed at a ratio shown in the following Table 2 (for the crosslinkers, the acid generators, and the surfactant, the amounts shown are in parts by mass per 100 parts by mass of the resin; and for the solvents, the amounts shown are in parts by mass per 100 of the total mass of the solvents), and the mixture was filtered through a micro-filter made of polytetrafluoroethylene with 0.1 μm to prepare a material for resist underlayer films (M1 to M21 and Comparative M1 to Comparative M2) as a coating composition for a substrate.

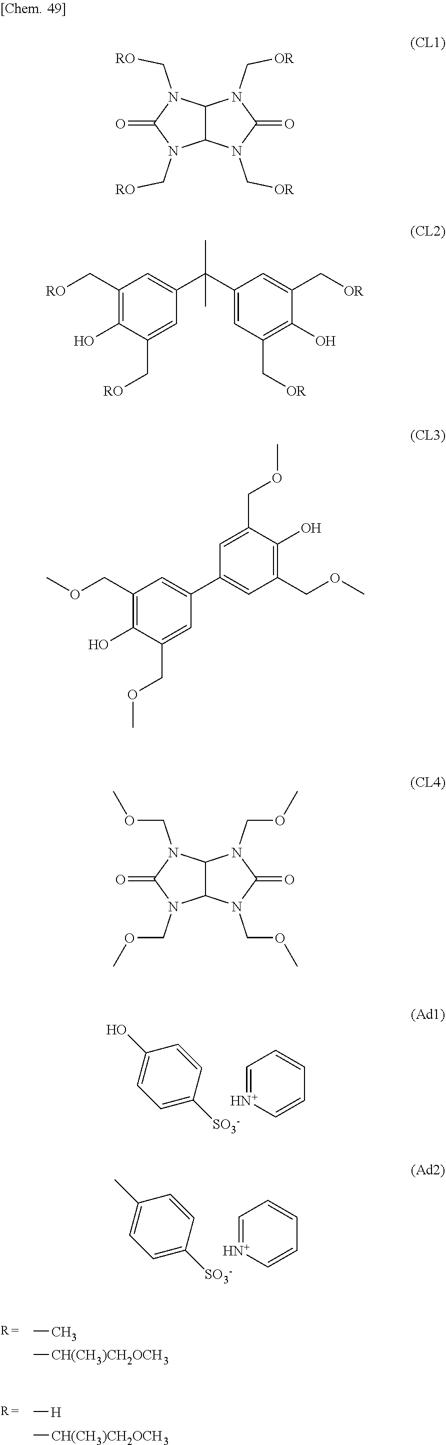

TABLE 2

| | | | Acid | | | | |
|---|---|---|---|---|---|---|---|
| Composition | Resin | Crosslinker | generator | Surfactant | Solvent (100 in total) | | |
| M1 | S1 | CL1 | Ad1 | H1 | PGMEA | PGME | CYH |
| | 100 | 56 | 3.8 | 0.1 | 70 | 30 | 0 |
| M2 | S2 | CL1 | Ad1 | H1 | PGMEA | PGME | CYH |
| | 100 | 56 | 3.8 | 0.1 | 70 | 30 | 0 |
| M3 | S3 | CL1 | Ad1 | H1 | PGMEA | PGME | CYH |
| | 100 | 56 | 3.8 | 0.1 | 70 | 30 | 0 |
| M4 | S4 | CL1 | Ad1 | H1 | PGMEA | PGME | CYH |
| | 100 | 56 | 3.8 | 0.1 | 70 | 30 | 0 |
| M5 | S5 | CL1 | Ad1 | H1 | PGMEA | PGME | CYH |
| | 100 | 56 | 3.8 | 0.1 | 40 | 10 | 50 |
| M6 | S6 | CL1 | Ad1 | H1 | PGMEA | PGME | CYH |
| | 100 | 56 | 3.8 | 0.1 | 30 | 10 | 60 |
| M7 | S7 | CL1 | Ad1 | H1 | PGMEA | PGME | CYH |
| | 100 | 56 | 3.8 | 0.1 | 70 | 30 | 0 |
| M8 | S8 | CL1 | Ad1 | H1 | PGMEA | PGME | CYH |
| | 100 | 56 | 3.8 | 0.1 | 60 | 20 | 20 |
| M9 | S9 | CL1 | Ad1 | H1 | PGMEA | PGME | CYH |
| | 100 | 56 | 3.8 | 0.1 | 70 | 30 | 0 |
| M10 | S10 | CL1 | Ad1 | H1 | PGMEA | PGME | CYH |
| | 100 | 56 | 3.8 | 0.1 | 70 | 30 | 0 |
| M11 | S11 | CL1 | Ad1 | H1 | PGMEA | PGME | CYH |
| | 100 | 56 | 3.8 | 0.1 | 70 | 30 | 0 |
| M12 | S12 | CL1 | Ad1 | H1 | PGMEA | PGME | CYH |
| | 100 | 56 | 3.8 | 0.1 | 70 | 30 | 0 |
| M13 | S13 | CL1 | Ad1 | H1 | PGMEA | PGME | CYH |
| | 100 | 56 | 3.8 | 0.1 | 30 | 70 | 0 |
| M14 | S14 | CL1 | Ad1 | H1 | PGMEA | PGME | CYH |
| | 100 | 56 | 3.8 | 0.1 | 70 | 30 | 0 |
| M15 | S14 | CL2 | Ad2 | H1 | PGMEA | PGME | CYH |
| | 100 | 50 | 3.8 | 0.1 | 70 | 30 | 0 |
| M16 | S14 | CL3 | Ad1 | H1 | PGMEA | PGME | CYH |
| | 100 | 50 | 3.8 | 0.1 | 70 | 30 | 0 |
| M17 | S15 | CL1 | Ad1 | H1 | PGMEA | PGME | CYH |
| | 100 | 56 | 3.8 | 0.1 | 70 | 30 | 0 |
| M18 | S16 | CL4 | Ad2 | H1 | PGMEA | PGME | CYH |
| | 100 | 56 | 3.8 | 0.1 | 70 | 30 | 0 |
| M19 | S18 | CL4 | Ad2 | H1 | PGMEA | PGME | CYH |
| | 100 | 56 | 3.8 | 0.1 | 70 | 30 | 0 |
| M20 | S19 | CL1 | Ad1 | H1 | PGMEA | PGME | CYH |
| | 100 | 56 | 3.8 | 0.1 | 70 | 30 | 0 |
| M21 | S20 | CL1 | Ad1 | H1 | PGMEA | PGME | CYH |
| | 100 | 56 | 3.8 | 0.1 | 70 | 30 | 0 |
| Comparative | SS1 | CL4 | Ad2 | H1 | PGMEA | PGME | CYH |
| M1 | 100 | 25 | 2.3 | 0.1 | 30 | 70 | 0 |
| Comparative | SS2 | CL1 | Ad1 | H1 | PGMEA | PGME | CYH |
| M2 | 100 | 56 | 3.8 | 0.1 | 70 | 30 | 0 |

### [Test for Elution to Resist Solvent]

The resist underlayer film materials of Comparative Examples 1 to 2 and Examples 1 to 21 were each applied by using a spin coater to a nitrogen-atom-containing substrate on which SiON or TiN was vapor-deposited, and baked in the atmosphere at a predetermined temperature for a predetermined time shown in Table 3 to form a resist underlayer film with a film thickness of 5 nm. The formed resist underlayer film was immersed in a mixed solvent of PGME/PGMEA=7/3, which was a common thinner, for 60 seconds, then spin-dried, and baked at 100° C. for 30 seconds. After the solvent was evaporated, the film thickness was measured. The film thicknesses before and after the immersion were compared to evaluate resistance against the solvent. A case where the change in the film thickness before and after the immersion in the thinner was 10% or more was graded as “×”, a case of the change of 5% or more and less than 10% was graded as “Δ”, a case of the change of 2% or more and less than 5% was graded as “∘”, and a case of the change of less than 2% was graded as “⊚” (Table 3). A sample with the evaluation of “∘” or better was judged to be at a usable level. Solvent resistance in a nitrogen atmosphere was evaluated in the same manner as above by using ACT-8, manufactured by Tokyo Electron Ltd.

TABLE 3

| Example/ | | | | Solvent | Solvent |
|---|---|---|---|---|---|
| Comparative | | | Baking | resistance | resistance |
| Example | Composition | Substrate | temperature | under air | under nitrogen |
| Example 1 | M1 | SiON | 240° C./ | ⊚ | ⊚ |
| | | | 60 seconds | | |
| Example 2 | M2 | SiON | 350° C./ | ⊚ | ⊚ |
| | | | 60 seconds | | |
| Example 3 | M3 | SiON | 240° C./ | ⊚ | ⊚ |
| | | | 60 seconds | | |
| Example 4 | M4 | SiON | 240° C./ | ⊚ | ⊚ |
| | | | 60 seconds | | |
| Example 5 | M5 | SiON | 350° C./ | ⊚ | ⊚ |
| | | | 60 seconds | | |
| Example 6 | M6 | SiON | 240° C./ | ⊚ | ⊚ |
| | | | 60 seconds | | |
| Example 7 | M7 | SiON | 240° C./ | ⊚ | ⊚ |
| | | | 60 seconds | | |
| Example 8 | M8 | SiON | 240° C./ | ⊚ | ⊚ |
| | | | 60 seconds | | |
| | | TiN | 240° C./ | ⊚ | ⊚ |
| | | | 60 seconds | | |
| Example 9 | M9 | SiON | 240° C./ | ⊚ | ⊚ |
| | | | 60 seconds | | |
| | | TiN | 240° C./ | ⊚ | ⊚ |
| | | | 60 seconds | | |
| Example 10 | M10 | SiON | 240° C./ | ⊚ | ⊚ |
| | | | 60 seconds | | |
| Example 11 | M11 | SiON | 400° C./ | ⊚ | ◯ |
| | | | 60 seconds | | |
| Example 12 | M12 | SiON | 240° C./ | ⊚ | ⊚ |
| | | | 60 seconds | | |
| Example 13 | M13 | SiON | 240° C./ | ⊚ | ⊚ |
| | | | 60 seconds | | |
| Example 14 | M14 | SiON | 240° C./ | ⊚ | ⊚ |
| | | | 60 seconds | | |
| Example 15 | M15 | SiON | 240° C./ | ⊚ | ⊚ |
| | | | 60 seconds | | |
| Example 16 | M16 | SiON | 240° C./ | ⊚ | ⊚ |
| | | | 60 seconds | | |
| | | TiN | 240° C./ | ⊚ | ⊚ |
| | | | 60 seconds | | |
| Example 17 | M17 | SiON | 350° C./ | ⊚ | ⊚ |
| | | | 60 seconds | | |
| Example 18 | M18 | SiON | 400° C./ | ⊚ | ⊚ |
| | | | 60 seconds | | |
| Example 19 | M19 | SiON | 350° C./ | ⊚ | ⊚ |
| | | | 60 seconds | | |
| | | TiN | 350° C./ | ⊚ | ⊚ |
| | | | 60 seconds | | |
| Example 20 | M20 | SiON | 350° C./ | ⊚ | ⊚ |
| | | | 60 seconds | | |
| | | TiN | 350° C./ | ⊚ | ⊚ |
| | | | 60 seconds | | |
| Example 21 | M21 | SiON | 350° C./ | ⊚ | ⊚ |
| | | | 60 seconds | | |
| Comparative | Comparative | SiON | 240° C./ | ⊚ | ⊚ |
| Example 1 | M1 | | 60 seconds | | |
| | | SiON | 400° C./ | Not | Not |
| | | | 60 seconds | determined | determined |
| Comparative | Comparative | SiON | 240° C./ | X | X |
| Example 2 | M2 | | 60 seconds | | |
| | | SiON | 400° C./ | Δ | Δ |
| | | | 60 seconds | | |
| | | TiN | 240° C./ | X | X |
| | | | 60 seconds | | |

Since the film with 5 nm is an ultrathin film, even a very small decrease in the film thickness thereof significantly affects properties, compared with the case of a thick film. Examples exhibit extremely good curability on the nitrogen-atom-containing substrate in both of the oxygen atmosphere and the nitrogen atmosphere. Comparative Example 1 exhibits good curing properties when baked at a low temperature, but when baked at a high temperature, the film disappeared to a level such that the film thickness was unmeasurable due to insufficient heat resistance of the resin. Comparative Example 2 fails to exhibit sufficient solvent resistance in not only the baking condition of the nitrogen atmosphere but also the air atmosphere, which is a common baking condition, and is thus unusable as the resist underlayer film. Therefore, for Comparative Examples, only the sample of Comparative Example 1 baked at 240° C. was subjected to the following evaluations.

### [Coatability Evaluation 1]

Each of the materials for resist underlayer films of Comparative Example 1 and Examples 1 to 21 was applied to various substrates having no step by using a spin coater, and baked in the air atmosphere at a predetermined temperature for a predetermined time shown in Table 4 to form a resist underlayer film with a film thickness of 5 nm. The film was visually observed, and a case where the application was performed without pinholes, unevenness, or repellence was graded as “o”. Each of the materials for resist underlayer films of Comparative Example 1 and Examples 1 to 21 was applied to various substrates having a step (a SiO₂ substrate, a SiN substrate, and a TiN substrate having a film thickness of 200 nm) by using a spin coater, and baked in the air atmosphere at a predetermined temperature for a predetermined time shown in Table 4 to form a resist underlayer film with a film thickness of 100 nm. A film with a thickness of 5 nm failed to provide a sufficient amount of the resin for filling the depth of the step in the substrate, and it was therefore difficult to appropriately evaluate the coatability. Thus, the evaluation was performed for a film thickness of 100 nm. The film was visually observed, and a case where the application was performed without pinholes, unevenness, or repellence was graded as “o” (Table 4).

To demonstrate that the materials have the coatability comparable to that of conventional materials on a Si substrate and SiO₂ substrate, which contained no nitrogen atom, the results thereon are shown as reference.

TABLE 4
Example/

| Comparative | | Baking | Substrate having no step | | | | | Substrate having step | | |
|---|---|---|---|---|---|---|---|---|---|---|
| Example | Composition | temperature | Si | SiO₂ | TiN | SiN | SiON | SiO₂ | TiN | SiN |
| Example 1 | M1 | 240° C./ | ◯ | ◯ | ◯ | ◯ | ◯ | ◯ | ◯ | ◯ |
| | | 60 seconds | | | | | | | | |
| Example 2 | M2 | 350° C./ | ◯ | ◯ | ◯ | ◯ | ◯ | ◯ | ◯ | ◯ |
| | | 60 seconds | | | | | | | | |
| Example 3 | M3 | 240° C./ | ◯ | ◯ | ◯ | ◯ | ◯ | ◯ | ◯ | ◯ |
| | | 60 seconds | | | | | | | | |
| Example 4 | M4 | 240° C./ | ◯ | ◯ | ◯ | ◯ | ◯ | ◯ | ◯ | ◯ |
| | | 60 seconds | | | | | | | | |
| Example 5 | M5 | 350° C./ | ◯ | ◯ | ◯ | ◯ | ◯ | ◯ | ◯ | ◯ |
| | | 60 seconds | | | | | | | | |
| Example 6 | M6 | 240° C./ | ◯ | ◯ | ◯ | ◯ | ◯ | ◯ | ◯ | ◯ |
| | | 60 seconds | | | | | | | | |
| Example 7 | M7 | 240° C./ | ◯ | ◯ | ◯ | ◯ | ◯ | ◯ | ◯ | ◯ |
| | | 60 seconds | | | | | | | | |
| Example 8 | M8 | 240° C./ | ◯ | ◯ | ◯ | ◯ | ◯ | ◯ | ◯ | ◯ |
| | | 60 seconds | | | | | | | | |
| Example 9 | M9 | 240° C./ | ◯ | ◯ | ◯ | ◯ | ◯ | ◯ | ◯ | ◯ |
| | | 60 seconds | | | | | | | | |
| Example 10 | M10 | 240° C./ | ◯ | ◯ | ◯ | ◯ | ◯ | ◯ | ◯ | ◯ |
| | | 60 seconds | | | | | | | | |
| Example 11 | M11 | 400° C./ | ◯ | ◯ | ◯ | ◯ | ◯ | ◯ | ◯ | ◯ |
| | | 60 seconds | | | | | | | | |
| Example 12 | M12 | 240° C./ | ◯ | ◯ | ◯ | ◯ | ◯ | ◯ | ◯ | ◯ |
| | | 60 seconds | | | | | | | | |
| Example 13 | M13 | 240° C./ | ◯ | ◯ | ◯ | ◯ | ◯ | ◯ | ◯ | ◯ |
| | | 60 seconds | | | | | | | | |
| Example 14 | M14 | 240° C./ | ◯ | ◯ | ◯ | ◯ | ◯ | ◯ | ◯ | ◯ |
| | | 60 seconds | | | | | | | | |
| Example 15 | M15 | 240° C./ | ◯ | ◯ | ◯ | ◯ | ◯ | ◯ | ◯ | ◯ |
| | | 60 seconds | | | | | | | | |
| Example 16 | M16 | 240° C./ | ◯ | ◯ | ◯ | ◯ | ◯ | ◯ | ◯ | ◯ |
| | | 60 seconds | | | | | | | | |
| Example 17 | M17 | 350° C./ | ◯ | ◯ | ◯ | ◯ | ◯ | ◯ | ◯ | ◯ |
| | | 60 seconds | | | | | | | | |
| Example 18 | M18 | 400° C./ | ◯ | ◯ | ◯ | ◯ | ◯ | ◯ | ◯ | ◯ |
| | | 60 seconds | | | | | | | | |
| Example 19 | M19 | 350° C./ | ◯ | ◯ | ◯ | ◯ | ◯ | ◯ | ◯ | ◯ |
| | | 60 seconds | | | | | | | | |
| Example 20 | M20 | 350° C./ | ◯ | ◯ | ◯ | ◯ | ◯ | ◯ | ◯ | ◯ |
| | | 60 seconds | | | | | | | | |
| Example 21 | M21 | 350° C./ | ◯ | ◯ | ◯ | ◯ | ◯ | ◯ | ◯ | ◯ |
| | | 60 seconds | | | | | | | | |
| Comparative | Comparative | 240° C./ | ◯ | ◯ | ◯ | ◯ | ◯ | ◯ | ◯ | ◯ |
| Example 1 | M1 | 60 seconds | | | | | | | | |

### [Coatability Evaluation 2]

The resist underlayer film materials of Comparative Example 1 and Examples 1 to 21 were applied by using ACT-8 or Lithius Pro, manufactured by Tokyo Electron Ltd., and baked in the air atmosphere at a predetermined temperature for a predetermined time shown in Table 5 to form a resist underlayer film of 5 nm. Note that the nitrogen-atom-containing substrate on which SiON was vapor deposited was coated by using ACT-8, and the silicon wafer was coated by using Lithius Pro. For the formed resist underlayer film, the film thickness of the entire wafer was measured at 49 points on a circumference to evaluate uniformity of the in-plane film thickness of the wafer. A case where a ratio of the variation of the film thickness (the maximum film thickness—the minimum film thickness) to the average film thickness was smaller than that in Comparative Example 1 was graded as “o”. Note that a smaller ratio of the variation in the film thickness means higher uniformity of the in-plane film thickness of the wafer (Table 5).

To demonstrate that the materials have the coatability comparable to that of conventional materials on a Si substrate, which contained no nitrogen atom, the results thereon are shown as reference.

### [Coatability Evaluation 3]

The resist underlayer film materials of Comparative Example 1 and Examples 1 to 21 were applied by using ACT-8, manufactured by Tokyo Electron Ltd., to a nitrogen-atom-containing substrate on which SiON was vapor-deposited, and baked in the air atmosphere at a predetermined temperature for a predetermined time shown in Table 5 to form a resist underlayer film of 5 nm. Thereafter, surface roughness was evaluated by using an AFM to evaluate the coatability. As a result of the AFM observation, a case of no problem about the coatability was graded as “∘” (Table 5).

TABLE 5

| | | | | Coatability | |
|---|---|---|---|---|---|
| Example/ | | | | evaluation 2: | Coatability |
| Comparative | | Baking | Substrate | Uniformity of | evaluation 3: |
| Example | Composition | temperature | type | film thickness | AFM |
| Example 1 | M1 | 240° C./ | Si | ◯ | — |
| | | 60 seconds | substrate | | |
| | | | SiON | ◯ | ◯ |
| Example 2 | M2 | 350° C./ | Si | ◯ | — |
| | | 60 seconds | substrate | | |
| | | | SiON | ◯ | ◯ |
| Example 3 | M3 | 240° C./ | Si | ◯ | — |
| | | 60 seconds | substrate | | |
| | | | SiON | ◯ | ◯ |
| Example 4 | M4 | 240° C./ | Si | ◯ | — |
| | | 60 seconds | substrate | | |
| | | | SiON | ◯ | ◯ |
| Example 5 | M5 | 350° C./ | Si | ◯ | — |
| | | 60 seconds | substrate | | |
| | | | SiON | ◯ | ◯ |
| Example 6 | M6 | 240° C./ | Si | ◯ | — |
| | | 60 seconds | substrate | | |
| | | | SiON | ◯ | ◯ |
| Example 7 | M7 | 240° C./ | Si | ◯ | — |
| | | 60 seconds | substrate | | |
| | | | SiON | ◯ | ◯ |
| Example 8 | M8 | 240° C./ | Si | ◯ | — |
| | | 60 seconds | substrate | | |
| | | | SiON | ◯ | ◯ |
| Example 9 | M9 | 240° C./ | Si | ◯ | — |
| | | 60 seconds | substrate | | |
| | | | SiON | ◯ | ◯ |
| Example 10 | M10 | 240° C./ | Si | ◯ | — |
| | | 60 seconds | substrate | | |
| | | | SiON | ◯ | ◯ |
| Example 11 | M11 | 400° C./ | Si | ◯ | — |
| | | 60 seconds | substrate | | |
| | | | SiON | ◯ | ◯ |
| Example 12 | M12 | 240° C./ | Si | ◯ | — |
| | | 60 seconds | substrate | | |
| | | | SiON | ◯ | ◯ |
| Example 13 | M13 | 240° C./ | Si | ◯ | — |
| | | 60 seconds | substrate | | |
| | | | SiON | ◯ | ◯ |
| Example 14 | M14 | 240° C./ | Si | ◯ | — |
| | | 60 seconds | substrate | | |
| | | | SiON | ◯ | ◯ |
| Example 15 | M15 | 240° C./ | Si | ◯ | — |
| | | 60 seconds | substrate | | |
| | | | SiON | ◯ | ◯ |
| Example 16 | M16 | 240° C./ | Si | ◯ | — |
| | | 60 seconds | substrate | | |
| | | | SiON | ◯ | ◯ |
| Example 17 | M17 | 350° C./ | Si | ◯ | — |
| | | 60 seconds | substrate | | |
| | | | SiON | ◯ | ◯ |
| Example 18 | M18 | 400° C./ | Si | ◯ | — |
| | | 60 seconds | substrate | | |
| | | | SiON | ◯ | ◯ |
| Example 19 | M19 | 350° C./ | Si | ◯ | — |
| | | 60 seconds | substrate | | |
| | | | SiON | ◯ | ◯ |
| Example 20 | M20 | 350° C./ | Si | ◯ | — |
| | | 60 seconds | substrate | | |
| | | | SiON | ◯ | ◯ |
| Example 21 | M21 | 350° C./ | Si | ◯ | — |
| | | 60 seconds | substrate | | |
| | | | SiON | ◯ | ◯ |
| Comparative | Comparative | 240° C./ | Si | ◯ | — |
| Example 1 | M1 | 60 seconds | substrate | | |
| | | | SiON | ◯ | ◯ |

From Table 4 and Table 5, it was found that, similarly to the conventional material compositions, the coating composition for a nitrogen-atom-containing substrate of the present invention exhibited excellent coatability on the nitrogen-atom-containing substrate regardless of presence or absence of steps, as with on the silicon wafer.

### [Lithography Evaluation]

By using ACT-8, manufactured by Tokyo Electron Ltd., the coating compositions of Comparative Example 1 and Examples 1 to 21 were each applied with a film thickness of 5 nm to a nitrogen-atom-containing substrate on which a SiON film was formed, and baked at a predetermined temperature for a predetermined time shown in Table 6 to form a resist underlayer film. As Comparative Examples, Comparative Examples 2 to 4, in which the resist underlayer film was not formed, were performed in addition to Comparative Example 1. To these resist underlayer films or substrates without the resist underlayer film, a commercially available resist solution for ArF (manufactured by Shin-Etsu Chemical Co., Ltd., bland name: SAIL X-206) was applied, and baked at 85° C. for 60 seconds to form a photoresist film having a film thickness of 100 nm. Two types of the substrates: a substrate immediately after the resist film formation; and a substrate after 48 hours from the resist film formation were subjected to exposure and development treatments. By using NSR (registered trademark)—S307E scanner, manufactured by NIKON CORPORATION (wavelength: 193 nm, NA=0.85, σ=0.93/0.85), the exposure was each performed through a mask such that a line width and a width between the lines of the photoresist after the development were each 0.1 m, that is, a dense line with 0.1 m line-and-space, (L/S)=1/1, was formed. Thereafter, baking was performed at 95° C. for 60 seconds on a hotplate, and after cooling, development was performed for 60 seconds with butyl acetate to form a negative pattern on the resist underlayer film.

The pattern size immediately after the formation of the resist pattern was observed by using a CD-SEM (manufactured by Hitachi High-Tech Corporation). The size of the resist pattern when the exposure and the development were performed immediately after the formation of the resist film and the size of the resist pattern when the exposure and the development were performed after 48 hours were compared. A case where variation in the pattern size was smaller than all of those in Comparative Examples 1 to 4 was graded as “∘”. Subsequently, the chip on which the target pattern size was formed was cut, and observed by using a scanning electron microscope (5-4800), manufactured by Hitachi High-Tech Corporation. A case where poisoning probably due to the nitrogen-atom-containing substrate did not affect the resist shape, resulting in a perpendicular shape, was graded as “∘”, and a case where the poisoning affected the resist shape to result in a non-perpendicular shape was graded as “×” (Table 6).

TABLE 6

| Example/ | | | Sub- | Lithography evaluation | |
|---|---|---|---|---|---|
| Comparative | | Baking | strate | | Variation in |
| Example | Composition | temperature | type | Shape | pattern size |
| Example 1 | M1 | 240° C./ | SiON | ◯ | ◯ |
| | | 60 seconds | | | |
| Example 2 | M2 | 350° C./ | SiON | ◯ | ◯ |
| | | 60 seconds | | | |
| Example 3 | M3 | 240° C./ | SiON | ◯ | ◯ |
| | | 60 seconds | | | |
| Example 4 | M4 | 240° C./ | SiON | ◯ | ◯ |
| | | 60 seconds | | | |
| Example 5 | M5 | 350° C./ | SiON | ◯ | ◯ |
| | | 60 seconds | | | |
| Example 6 | M6 | 240° C./ | SiON | ◯ | ◯ |
| | | 60 seconds | | | |
| Example 7 | M7 | 240° C./ | SiON | ◯ | ◯ |
| | | 60 seconds | | | |
| Example 8 | M8 | 240° C./ | SiON | ◯ | ◯ |
| | | 60 seconds | | | |
| Example 9 | M9 | 240° C./ | SiON | ◯ | ◯ |
| | | 60 seconds | | | |
| Example 10 | M10 | 240° C./ | SiON | ◯ | ◯ |
| | | 60 seconds | | | |
| Example 11 | M11 | 400° C./ | SiON | ◯ | ◯ |
| | | 60 seconds | | | |
| Example 12 | M12 | 240° C./ | SiON | ◯ | ◯ |
| | | 60 seconds | | | |
| Example 13 | M13 | 240° C./ | SiON | ◯ | ◯ |
| | | 60 seconds | | | |
| Example 14 | M14 | 240° C./ | SiON | ◯ | ◯ |
| | | 60 seconds | | | |
| Example 15 | M15 | 240° C./ | SiON | ◯ | ◯ |
| | | 60 seconds | | | |
| Example 16 | M16 | 240° C./ | SiON | ◯ | ◯ |
| | | 60 seconds | | | |
| Example 17 | M17 | 350° C./ | SiON | ◯ | ◯ |
| | | 60 seconds | | | |
| Example 18 | M18 | 400° C./ | SiON | ◯ | ◯ |
| | | 60 seconds | | | |
| Example 19 | M19 | 350° C./ | SiON | ◯ | ◯ |
| | | 60 seconds | | | |
| Example 20 | M20 | 350° C./ | SiON | ◯ | ◯ |
| | | 60 seconds | | | |
| Example 21 | M21 | 350° C./ | SiON | ◯ | ◯ |
| | | 60 seconds | | | |
| Comparative | Comparative | 240° C./ | SiON | X | X |
| Example 1 | M1 | 60 seconds | | | |
| Comparative | No material | No baking | SiON | X | X |
| Example 2 | | | | | |
| Comparative | No material | No baking | SiN | X | X |
| Example 3 | | | | | |
| Comparative | No material | No baking | TiN | X | X |
| Example 4 | | | | | |

As above, the novolac resin having the phenol-derived unit structure and the novolac resin having the carbazole-derived unit structure exhibit extremely good curability in a film thickness of less than 10 nm in both the air atmosphere and the nitrogen atmosphere, and are usable as the resist underlayer film in the ultrathin film state. Even in the case where a triple bond is introduced at the OH group in the phenol/phenoxy skeleton or the NH group in the carbazole skeleton, the above effect is not impaired. Furthermore, even when the film thickness is less than 10 nm, good coatability is exhibited and the in-plane uniformity of the film thickness is high on various types of vapor-deposited film regardless of the substrate having a step or the substrate having no step. The structure in Examples can block the amine component diffused from an amine-containing base substrate such as SiON, SiN, and TiN, and thus the size and shape of the resist can be retained even when exposure and development are performed a long time after the resist film formation, similar to the case where exposure and development are performed immediately after the resist film formation. Therefore, the coating composition for a nitrogen-atom-containing substrate is promising as a material that can be widely used for coating of the nitrogen-atom-containing substrate for the diversified semiconductor manufacturing processes.

1. A coating composition for a nitrogen-atom-containing substrate comprising:
a novolac resin and a solvent,
the novolac resin has a unit structure A, the unit structure A has a carbazole skeleton or a phenol/phenoxy skeleton at least as a partial structure, and
the nitrogen-atom-containing substrate is: a substrate formed of a compound having a bond between a metal atom or a semimetal atom and a nitrogen atom; or a substrate having a nitrogen-atom-containing film formed of a compound having a bond between a metal atom or a semimetal atom and a nitrogen atom.

2. The coating composition for a nitrogen-atom-containing substrate according to claim 1, wherein the composition is for forming a resist underlayer film.

3. The coating composition for a nitrogen-atom-containing substrate according to claim 2, wherein the resist underlayer film is a resist underlayer thin film having a film thickness of less than 10 nm.

4. The coating composition for a nitrogen-atom-containing substrate according to claim 1, wherein the nitrogen-atom-containing film is an outermost layer of the nitrogen-atom-containing substrate.

5. The coating composition for a nitrogen-atom-containing substrate according to claim 1, wherein the metal atom or the semimetal atom is:
(i) silicon;
(ii) titanium; or
(iii) tungsten, hafnium, zirconium, chromium, germanium, copper, silver, gold, aluminum, indium, gallium, arsenic, palladium, iron, tantalum, iridium, cobalt, manganese, molybdenum, or an alloy thereof.

6. The coating composition for a nitrogen-atom-containing substrate according to claim 5, wherein the compound having the bond between the metal atom or the semimetal atom and the nitrogen atom is SiON, SiN, TiON, or TiN.

7. The coating composition for a nitrogen-atom-containing substrate according to claim 1, wherein the unit structure A having the carbazole skeleton or the phenol/phenoxy skeleton at least as a partial structure is a structural unit derived from one or more compounds selected from the following structural formulae (A-1) to (A-9): 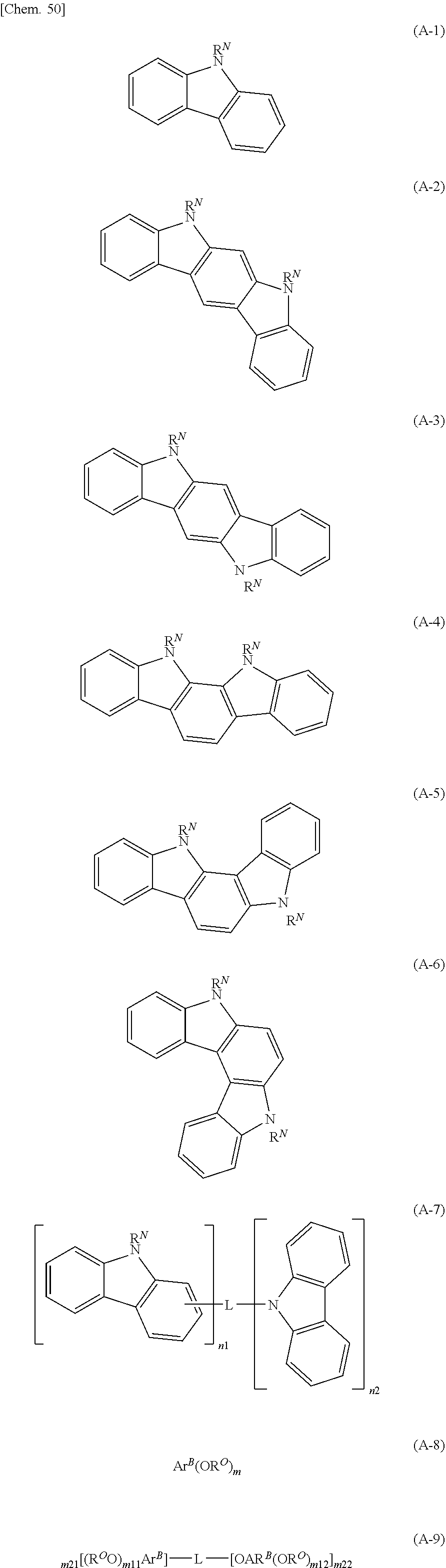
in the formulae (A-1) to (A-9),
R^{N} and R^{O} each independently represent:
(i) a hydrogen atom or a methylol group;
(ii) an aryl group having 6 to 30 carbon atoms; or
(iii) a linear, branched, or cyclic alkoxymethyl group having 2 to 20 carbon atoms; a linear, branched, or cyclic alkyl group having 1 to 20 carbon atoms; an alkenyl group having 2 to 10 carbon atoms; or an alkynyl group having 2 to 10 carbon atoms,
provided that R^{N} is bonded to a nitrogen atom on the carbazole skeleton, and R^{O} is bonded to an aryloxy oxygen atom in the Ar^{B} ring,
in the (ii) and (iii), a hydrogen atom in these groups is optionally further substituted with an oxygen-atom-containing substituent, a sulfur-atom-containing substituent, a nitrogen-atom-containing substituent, an aryl group, or a halo group, and in the (iii), a hydrocarbon chain moiety is optionally further interrupted by an oxygen-atom-containing substituent, a sulfur-atom-containing substituent, a nitrogen-atom-containing substituent, or an arylene group,
in the formula (A-8) to (A-9),
Ar^{B} each independently represents a benzene ring, a naphthalene ring, or a condensed ring having one or more benzene rings,
in the formula (A-8), “m” represents a number of ROO groups and is 1 or more,
in the formulae (A-7) and (A-9),
L represents a single bond or a polyvalent linking group, wherein the polyvalent linking group is a divalent to octavalent linking group,
in the formula (A-7),
n1 represents a number of carbazole skeletons in which a carbon atom on an aromatic ring of the carbazole skeleton is bonded to L, n2 represents a number of carbazole skeletons in which a nitrogen atom on the carbazole skeleton is bonded to L, and n1 and n2 each are 0 or more; provided that a sum of n1 and n2 is an integer of 2 to 8, and the sum of n1 and n2 is 2 when L represents a single bond,
in the formula (A-9),
m21 represents a number of (R^{O}O)ₘ₁₁Ar^{B} groups, in which a carbon atom on the Ar^{B} ring is bonded to L, and m11 each independently represents a number of R^{O}O groups,
m22 represents a number of OAr^{B}(OR^{O})ₘ₁₂ groups, in which an aryloxy oxygen atom in the Ar^{B} ring is bonded to L, m12 each independently represents a number of R^{O}O groups, and m11, m21, m12, and m22 each represent 0 or more; provided that a sum of the number “m21” of m1 is and m22 is 1 or more, a sum of m21 and m22 is 2 to 8, and the sum of m21 and m22 is 2 when L represents a single bond, and
each aromatic ring in these formulae (A-1) to (A-9) optionally further has a substituent.

8. The coating composition for a nitrogen-atom-containing substrate according to claim 7, wherein
the L is selected from the group consisting of a single bond, —O—, —S—, —SO₂—, —CO—, —CONH—, —COO—, —NH—, —(CR₁R²)ₘ₁—, —(Ar)ₘ₂—, —CH₂—(Ar)ₘ₂—CH₂—, and -(cyclo-R)—,
R¹ and R² are the same or different from each other and each independently represent a hydrogen atom, a hydrocarbon group having 1 to 5 carbon atoms, or an aryl group having 6 to 30 carbon atoms, and m1 represents an integer of 1 to 10,
Ar represents an arylene group having 6 to 30 carbon atoms, and m2 is an integer of 1 to 3 and represents a number of aromatic rings bonded to each other with a single bond, and
cyclo-R represents a five to eight-membered divalent alicyclic hydrocarbon group optionally forming a condensed ring with one or two benzene rings or naphthalene rings.

9. The coating composition for a nitrogen-atom-containing substrate according to claim 7, wherein the R^{N} or R^{O} has as at least part a substituent: 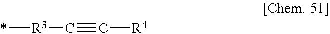
wherein “*” represents a bonding site,
R³ represents a single bond or a divalent organic group having 1 to 20 carbon atoms, and
R⁴ represents a hydrogen atom or a monovalent organic group having 1 to 20 carbon atoms.

10. The coating composition for a nitrogen-atom-containing substrate according to claim 1, wherein the novolac resin has a composite unit structure A-B represented by the following formula (AB): 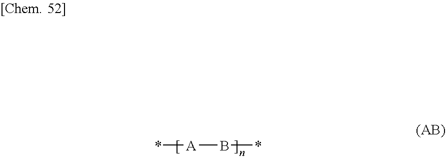
in the formula (AB),
“n” represents a number of the composite unit structure A-B,
a unit structure A is as defined for the unit structure A in claim 1,
a unit structure B represents one or more unit structures having a structure represented by the following formula (B1), (B2), or (B3), and
“*” represents a bonding site, 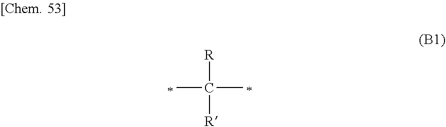
in the formula (B1),
R and R′ each independently represent a hydrogen atom, an aromatic ring residue having 6 to 30 carbon atoms and optionally having a substituent; a heteroring residue having 3 to 30 carbon atoms and optionally having a substituent; a linear, branched, or cyclic alkyl group having 10 or less carbon atoms and optionally having a substituent; or a formyl group, and
“*” represents a bonding site, 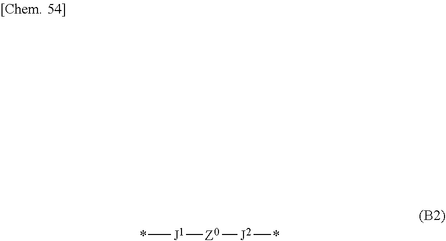
in the formula (B2),
Z⁰ represents an aromatic ring residue or an aliphatic ring residue having 6 to 30 carbon atoms and optionally having a substituent; or an organic group in which two aromatic ring residues or aliphatic ring residues are linked via a single bond,
J¹ and J² each independently represent a direct bond or a divalent organic group optionally having a substituent, and
“*” represents a bonding site, 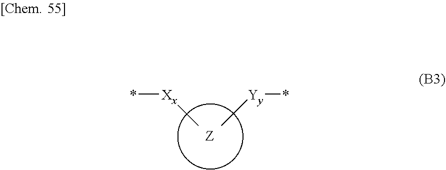
in the formula (B3),
Z represents a single ring or a bicyclic, tricyclic, or tetracyclic condensed ring having 4 to 25 carbon atoms and optionally having a substituent, the single ring being a non-aromatic single ring; at least one single ring constituting the bicyclic, tricyclic, or tetracyclic rings is a non-aromatic single ring while the other single ring or rings may be an aromatic single ring or a non-aromatic single ring; the single ring or the bicyclic, tricyclic, or tetracyclic condensed ring may further form a condensed ring with one or more aromatic rings to form a penta- or higher-cyclic condensed ring,
X and Y are the same or different from each other and represent a —CR³¹R³²— group, R³¹ and R³² are the same or different from each other and represent a hydrogen atom or a hydrocarbon group having 1 to 6 carbon atoms, and
“x” and “y” respectively represent numbers of X and Y, and each independently represent 0 or 1, 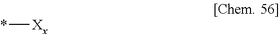
is bonded to any one carbon atom of the non-aromatic single ring of Z (when x=1), which is referred to as a “carbon atom 1”, or extends from the carbon atom 1 (when x=0), 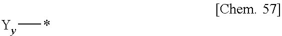
is bonded to any one carbon atom of the non-aromatic single ring of Z (when y=1), which is referred to as a “carbon atom 2”, or extends from the carbon atom 2 (when y=0),
the carbon atom 1 and the carbon atom 2 may be identical or different from each other, and when the carbon atom 1 and the carbon atom 2 are different, the carbon atom 1 and the carbon atom 2 may be contained in an identical non-aromatic single ring or may be contained in different non-aromatic single rings, and
“*” represents a bonding site.

11. The coating composition for a nitrogen-atom-containing substrate according to claim 1, wherein the solvent contains a solvent having a boiling point of 160° C. or higher.

12. The coating composition for a nitrogen-atom-containing substrate according to claim 1, further comprising an acid and/or a salt thereof, and/or an acid generator.

13. The coating composition for a nitrogen-atom-containing substrate according to claim 1, further comprising a crosslinker.

14. The coating composition for a nitrogen-atom-containing substrate according to claim 13, wherein the crosslinker is an aminoplast crosslinker or a phenoplast crosslinker.

15. The coating composition for a nitrogen-atom-containing substrate according to claim 1, further comprising a surfactant.

16. A resist underlayer film on a nitrogen-atom-containing substrate, wherein the resist underlayer film is a baked product of a coating film comprising the coating composition for a nitrogen-atom-containing substrate according to claim 1.

17. The resist underlayer film on the nitrogen-atom-containing substrate according to claim 16, having a film thickness of less than 10 nm.

18. A method for forming a resist pattern used for manufacturing a semiconductor, the method comprising: a step of applying the coating composition for a nitrogen-atom-containing substrate according to claim 1 to a nitrogen-atom-containing semiconductor substrate; and a step of then baking the composition to form a resist underlayer film.

19. A method for manufacturing a semiconductor device, the method comprising:
a step of forming a resist underlayer film from the coating composition for a nitrogen-atom-containing substrate according to claim 1 on a nitrogen-atom-containing semiconductor substrate;
a step of forming a resist film on the resist underlayer film; and
a step of forming a resist pattern in the resist film by irradiation with light or electron beam and development.

20. The method for manufacturing a semiconductor device according to claim 19, further comprising a step of etching the resist underlayer film through the resist pattern.

21. The method for manufacturing a semiconductor device according to claim 20, further comprising a step of processing a semiconductor substrate with the patterned resist underlayer film.

22. The method for manufacturing a semiconductor device according to claim 19, wherein the step of forming a resist pattern in the resist film is performed by a nanoimprinting method or a directed self-assembly method.

23. A composition for forming a resist underlayer thin film, the composition comprising: a novolac resin and a solvent,
the novolac resin has a repeating unit structure A, the unit structure A has a carbazole skeleton or a phenol/phenoxy skeleton at least as a partial structure, and
a film thickness of the resist underlayer thin film is less than 10 nm.
